(19) United States
(12) Patent Application Publication
(10) Pub. No.: US 2024/0186310 A1
(43) Pub. Date: Jun. 6, 2024

(54) SIGNAL TRANSMISSION DEVICE AND INSULATION CHIP

(71) Applicant: ROHM CO., LTD., Kyoto (JP)

(72) Inventor: Bungo TANAKA, Kyoto-shi (JP)

(73) Assignee: ROHM CO., LTD., Kyoto (JP)

(21) Appl. No.: 18/443,036

(22) Filed: Feb. 15, 2024

Related U.S. Application Data
(63) Continuation of application No. PCT/JP2022/030341, filed on Aug. 8, 2022.

(30) Foreign Application Priority Data
Aug. 30, 2021 (JP) 2021-140076

(51) Int. Cl. H01L 25/18; H01L 23/00; H01L 23/31; H01L 27/01

(52) U.S. Cl. CPC H01L 25/18; H01L 24/29; H01L 24/32; H01L 27/016; H01L 23/3171; H01L 24/05; H01L 24/45; H01L 24/48; H01L 24/49; H01L 24/73; H01L 2224/05554; H01L 2224/05567; H01L 2224/29139; H01L 2224/2919; H01L 2224/32245; H01L 2224/45124; H01L 2224/45144; H01L 2224/45147; H01L 2224/48091; H01L 2224/48106; H01L 2224/48137; H01L 2224/49175; H01L 2224/73265; H01L 2924/0665

(57) ABSTRACT

A transformer chip of this signal transmission device comprises a substrate, an element insulation layer, and a first transformer and a second transformer provided within the element insulation layer. The first transformer is provided with a first coil, and a second coil which is disposed facing the first coil in a z direction. The second transformer is provided with a first coil, and a second coil which is disposed facing the first coil in the z direction. The second coil of the first transformer and the second coil of the second transformer are electrically connected. The substrate includes a body part, and a substrate insulation layer formed on the surface of the body part. The element insulation layer is layered on the surface of the substrate insulation layer.

### BACKGROUND

### 1. Field

The present disclosure relates to a signal transmission device and an insulation chip.

### 2. Description of Related Art

A known example of a signal transmission device is an insulated gate driver that applies a gate voltage to the gate of a switching element such as a transistor. Japanese Laid-Open Patent Publication No. 2013-51547 describes an example of a semiconductor integrated circuit used as an insulated gate driver that includes a transformer. The transformer includes a first coil at the primary side and a second coil at the secondary side.

### BRIEF DESCRIPTION OF DRAWINGS

FIG. 1 is a schematic circuit diagram showing the circuit configuration of a first embodiment of a signal transmission device.

FIG. 2 is a schematic cross-sectional view showing a cross-sectional structure of the signal transmission device shown in FIG. 1.

FIG. 3 is a schematic plan view showing a planar structure of a transformer chip of the signal transmission device shown in FIG. 2.

FIG. 4 is a schematic cross-sectional view showing a cross-sectional structure of the transformer chip of FIG. 3 taken along a plane orthogonal to a thickness-wise direction of the transformer chip.

FIG. 5 is a schematic cross-sectional view showing a cross-sectional structure of the transformer chip taken in line 5-5 in FIG. 3.

FIG. 6 is a schematic cross-sectional view showing a cross-sectional structure of the transformer chip taken in line 6-6 in FIG. 3.

FIG. 7 is a schematic cross-sectional view showing a cross-sectional structure of the transformer chip taken in line 7-7 in FIG. 3.

FIG. 8 is a schematic cross-sectional view showing a cross-sectional structure of the transformer chip taken in line 8-8 in FIG. 3.

FIG. 9 is a diagram illustrating an example of a step for manufacturing a transformer chip.

FIG. 10 is a diagram illustrating an example of a step for manufacturing a transformer chip.

FIG. 11 is a diagram illustrating an example of a step for manufacturing a transformer chip.

FIG. 12 is a schematic circuit diagram showing the circuit configuration of a second embodiment of a signal transmission device.

FIG. 13 is a schematic cross-sectional view showing a cross-sectional structure of the signal transmission device shown in FIG. 12.

FIG. 14 is a schematic plan view showing a planar structure of a capacitor chip of the signal transmission device shown in FIG. 13.

FIG. 15 is a schematic cross-sectional view showing a cross-sectional structure of the capacitor chip of FIG. 14 taken along a plane orthogonal to a thickness-wise direction of the capacitor chip.

FIG. 16 is a schematic cross-sectional view showing a cross-sectional structure of the capacitor chip taken along line 16-16 in FIG. 14.

FIG. 17 is a schematic cross-sectional view showing a cross-sectional structure of the capacitor chip taken along line 17-17 in FIG. 14.

FIG. 18 is a schematic cross-sectional view showing a cross-sectional structure of the capacitor chip taken along line 18-18 in FIG. 14.

FIG. 19 is a schematic cross-sectional view showing a cross-sectional structure of the capacitor chip taken along line 19-19 in FIG. 14.

FIG. 20 is a schematic cross-sectional view showing a cross-sectional structure of a transformer chip in a modified example of a signal transmission device.

FIG. 21 is a schematic cross-sectional view showing a cross-sectional structure of a transformer chip in a modified example of a signal transmission device.

FIG. 22 is a schematic cross-sectional view showing a cross-sectional structure of a modified example of a signal transmission device taken along a plane orthogonal to a thickness-wise direction of a transformer chip.

FIG. 23 is a schematic plan view showing a planar structure of a transformer chip in the signal transmission device shown in FIG. 22.

FIG. 24 is a schematic cross-sectional view showing a cross-sectional structure of a modified example of a signal transmission device taken along a plane orthogonal to a thickness-wise direction of a transformer chip.

### DETAILED DESCRIPTION

Embodiments of a signal transmission device and an insulation chip will be described below with reference to the drawings. The embodiments described below exemplify configurations and methods for embodying a technical concept and are not intended to limit the material, shape, structure, layout, dimensions, and the like of each component to those described below. In the drawings, elements may not be drawn to scale for simplicity and clarity of illustration. In a cross-sectional view, hatching may be omitted to facilitate understanding. The accompanying drawings only illustrate embodiments of the present disclosure and are not intended to limit the present disclosure.

### First Embodiment

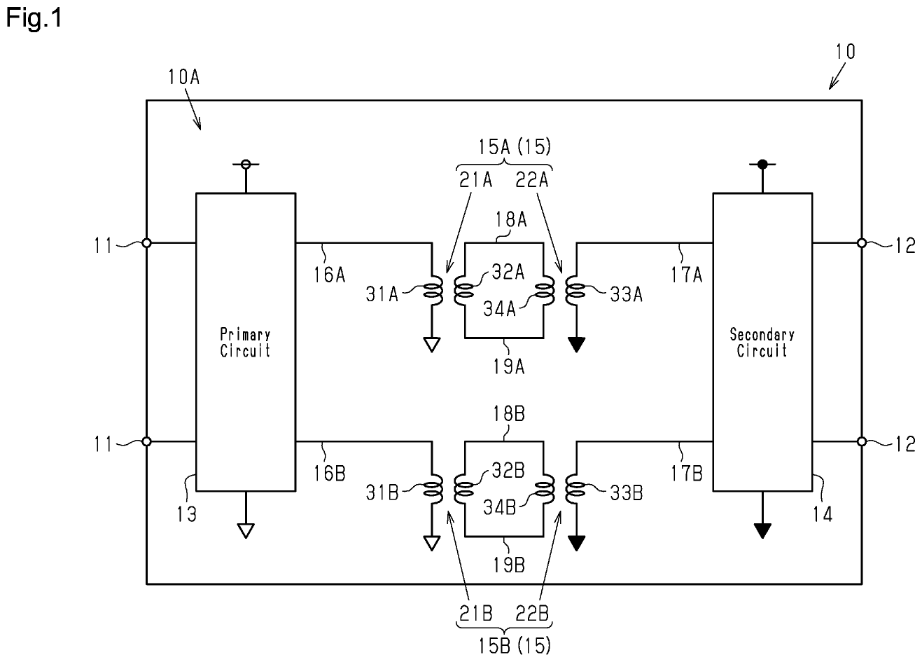

A first embodiment of a signal transmission device 10 will now be described with reference to FIGS. 1 to 11. FIG. 1 schematically shows an example of a circuit configuration of the signal transmission device 10.

As shown in FIG. 1, the signal transmission device 10 transmits a pulse signal while electrically insulating primary terminals 11 from secondary terminals 12. The signal transmission device 10 is a digital isolator and is, for example, a DC/DC converter. The signal transmission device 10 includes a signal transmitting circuit 10A that includes a primary circuit 13 electrically connected to the primary terminals 11, a secondary circuit 14 electrically connected to the secondary terminals 12, and a transformer 15 electrically connecting the primary circuit 13 and the secondary circuit 14. In the present embodiment, the primary circuit 13 corresponds to a “first circuit,” and the secondary circuit 14 corresponds to a “second circuit.”

The primary circuit 13 is configured to be actuated by application of a first voltage. In an example, the primary circuit 13 is electrically connected to an external controller (not shown).

The secondary circuit 14 is configured to be actuated by application of a second voltage that differs from the first voltage. In an example, the second voltage is higher than the first voltage. The first voltage and the second voltage are direct current voltages. In an example, the secondary circuit 14 is electrically connected to a drive circuit that is a subject controlled by the controller. An example of the drive circuit is a switching circuit.

The signal transmission device 10 is configured so that when a control signal from the controller is input to the primary circuit 13 through the primary terminals 11, the signal is transmitted from the primary circuit 13 to the secondary circuit 14 through the transformer 15, and the secondary circuit 14 outputs the signal to the drive circuit through the secondary terminals 12.

As described above, in the signal transmitting circuit 10A, the primary circuit 13 and the secondary circuit 14 are electrically insulated by the transformer 15. More specifically, while restricting transmission of a direct current voltage between the primary circuit 13 and the secondary circuit 14, the transformer 15 allows transmission of a pulse signal.

That is, the state in which the primary circuit 13 and the secondary circuit 14 are insulated refers to a state in which transmission of a direct current voltage between the primary circuit 13 and the secondary circuit 14 is blocked, whereas transmission of a pulse signal from the primary circuit 13 to the secondary circuit 14 is allowed. Thus, the secondary circuit 14 is configured to receive a signal from the primary circuit 13.

The insulation voltage of the signal transmission device 10 is, for example, in a range of 2500 Vrms to 7500 Vrms. In the present embodiment, the insulation voltage of the signal transmission device 10 is approximately 5700 Vrms. However, the insulation voltage of the signal transmission device 10 is not limited to these values and may be any specific numerical value. In the present embodiment, the primary circuit 13 and the secondary circuit 14 are individually provided with ground.

The structure of the signal transmission device 10 will now be described in detail.

In the present embodiment, the signal transmission device 10 includes two transformers 15 corresponding to two types of signals transmitted from the primary circuit 13 toward the secondary circuit 14. More specifically, the signal transmission device 10 includes a transformer 15 that is used to transmit a first signal from the primary circuit 13 to the secondary circuit 14 and a transformer 15 that is used to transmit a second signal from the primary circuit 13 to the secondary circuit 14. In the present embodiment, the first signal includes rising information of an external signal that is input to the signal transmission device 10. The second signal includes falling information of the external signal. The first signal and the second signal generate a pulse signal.

Hereinafter, for the sake of brevity, the transformer 15 used to transmit the first signal is referred to as a “transformer 15A.” The transformer 15 used to transmit the second signal is referred to as a “transformer 15B.” In the present embodiment, the transformer 15A corresponds to a “first signal transformer.” The transformer 15B corresponds to a “second signal transformer.”

The signal transmission device 10 includes a primary signal line 16A connecting the primary circuit 13 to the transformer 15A, a primary signal line 16B connecting the primary circuit 13 to the transformer 15B, a secondary signal line 17A connecting the transformer 15A to the secondary circuit 14, and a secondary signal line 17B connecting the transformer 15B to the secondary circuit 14. The primary signal line 16A transmits the first signal from the primary circuit 13 to the transformer 15A. The primary signal line 16B transmits the second signal from the primary circuit 13 to the transformer 15B. The secondary signal line 17A transmits the first signal from the transformer 15A to the secondary circuit 14. The secondary signal line 17B transmits the second signal from the transformer 15B to the secondary circuit 14. As described above, the first signal is transmitted from the primary circuit 13 to the secondary circuit 14 sequentially through the primary signal line 16A, the transformer 15A, and the secondary signal line 17A. The second signal is transmitted from the primary circuit 13 to the secondary circuit 14 sequentially through the primary signal line 16B, the transformer 15B, and the secondary signal line 17B.

While transmitting the first signal from the primary circuit 13 to the secondary circuit 14, the transformer 15A electrically insulates the primary circuit 13 from the secondary circuit 14. The transformer 15A includes a first transformer 21A and a second transformer 22A connected in series. In the present embodiment, the first transformer 21A corresponds to a “first isolation element.” The second transformer 22A corresponds to a “second isolation element.”

The signal transmission device 10 includes two connection signal lines 18A and 19A that connect the first transformer 21A and the second transformer 22A. The first signal is transmitted through the two connection signal lines 18A and 19A.

In the present embodiment, the insulation voltage of each of the transformers 21A and 22A is, for example, in a range of 2500 Vrms to 7500 Vrms. The insulation voltage of each of the transformers 21A and 22A may be in a range of 2500 Vrms to 5700 Vrms. However, the insulation voltage of the transformers 21A and 22A is not limited to those values and may be any specific numerical value.

The first transformer 21A includes a first coil 31A and a second coil 32A electrically insulated from the first coil 31A. The second coil 32A is configured to be magnetically coupled to the first coil 31A. The second transformer 22A includes a first coil 33A and a second coil 34A electrically insulated from the first coil 33A. The second coil 34A is configured to be magnetically coupled to the first coil 33A.

The first coil 31A is connected to the primary circuit 13 by the primary signal line 16A and is also connected to the ground of the primary circuit 13. More specifically, the first coil 31A includes a first end electrically connected to the primary circuit 13 and a second end electrically connected to the ground of the primary circuit 13.

The second coil 32A is connected to the second coil 34A by the two connection signal lines 18A and 19A. In an example, the second coil 32A and the second coil 34A are connected to each other so as to be electrically floating. The connection signal line 18A connects a first end of the second coil 32A and a first end of the second coil 34A. The connection signal line 19A connects a second end of the second coil 32A and a second end of the second coil 34A. Thus, the second coil 32A and the second coil 34A serve as relay coils that relay the first signal transmitted between the first coil 31A and the first coil 33A.

The first coil 33A is connected to the secondary circuit 14 by the secondary signal line 17A and is also connected to the ground of the secondary circuit 14. More specifically, the first coil 33A includes a first end electrically connected to the secondary circuit 14 and a second end electrically connected to the ground of the secondary circuit 14.

While transmitting the second signal from the primary circuit 13 to the secondary circuit 14, the transformer 15B electrically insulates the primary circuit 13 from the secondary circuit 14. The transformer 15B includes a first transformer 21B and a second transformer 22B connected in series. In the present embodiment, the first transformer 21B corresponds to a “first isolation element.” The second transformer 22B corresponds to a “second isolation element.”

The signal transmission device 10 includes two connection signal lines 18B and 19B that connect the first transformer 21B and the second transformer 22B. The two connection signal lines 18B and 19B transmit the second signal.

The first transformer 21B includes a first coil 31B and a second coil 32B that is electrically insulated from the first coil 31B. The second coil 32B is configured to be magnetically coupled to the first coil 31B. The second transformer 22B includes a first coil 33B and a second coil 34B that is electrically insulated from the first coil 33B. The second coil 34B is configured to be magnetically coupled to the first coil 33B. The insulation voltage of the first transformer 21B is equal to the insulation voltage of the first transformer 21A. The insulation voltage of the second transformer 22B is equal to the insulation voltage of the second transformer 22A. The connection configuration of the first transformer 21B and the second transformer 22B is the same as the connection configuration of the first transformer 21A and the second transformer 22A and thus will not be described in detail.

In the signal transmission device 10 having the configuration described above, the first signal output from the primary circuit 13 is transmitted through the first transformer 21A and the second transformer 22A to the secondary circuit 14. The second signal output from the primary circuit 13 is transmitted through the first transformer 21B and the second transformer 22B to the secondary circuit 14.

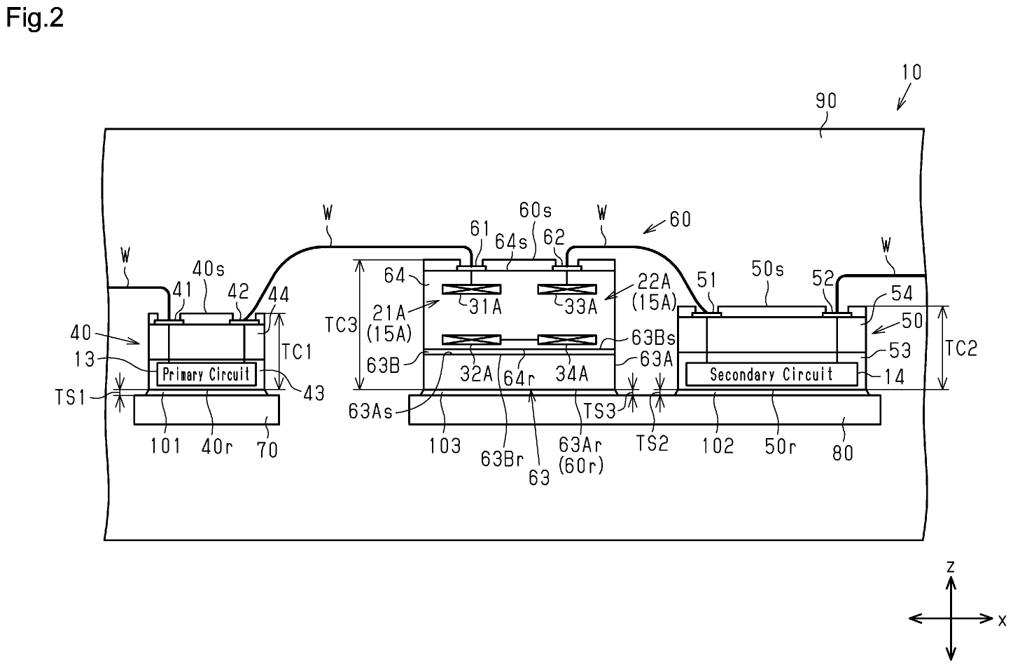

FIG. 2 shows an example of a schematic cross-sectional structure showing the internal structure of a portion of the signal transmission device 10. As shown in FIG. 2, the signal transmission device 10 is a semiconductor device including multiple semiconductor chips arranged in a single package. Although not shown, the package type of the signal transmission device 10 is, for example, small outline (SO). In the present embodiment, the package type of the signal transmission device 10 is a small outline package (SOP). The package type of the signal transmission device 10 may be changed in any manner.

The signal transmission device 10 includes a first chip 40, a second chip 50, and a transformer chip 60, which are semiconductor chips. The signal transmission device 10 further includes a primary die pad 70 on which the first chip 40 is mounted, a secondary die pad 80 on which the second chip 50 is mounted, and an encapsulation resin 90 encapsulating the die pads 70 and 80 and the chips 40, 50, and 60. In the present embodiment, the transformer chip 60 corresponds to an “insulation chip.” The primary die pad 70 corresponds to a “first die pad.” The secondary die pad 80 corresponds to a “second die pad.”

The encapsulation resin 90 is formed from an electrically-insulative material and is formed from, for example, a black epoxy resin. The encapsulation resin 90 has the form of a rectangular plate having a thickness-wise direction conforming to the z-direction.

The primary die pad 70 and the secondary die pad 80 are each formed from a conductive material. In the present embodiment, the die pads 70 and 80 are formed from a material including copper (Cu). Alternatively, the die pads 70 and 80 may be formed from a material including other metal such as aluminum (Al). Furthermore, the material of the die pads 70 and 80 is not limited to a conductive material. In an example, the die pads 70 and 80 may be formed from ceramics such as alumina. That is, the die pads 70 and 80 may be formed from an electrically-insulative material.

As viewed in the z-direction, the primary die pad 70 and the secondary die pad 80 are arranged next to each other and separated from each other. As viewed in the z-direction, the arrangement direction of the primary die pad 70 and the secondary die pad 80 is referred to as an x-direction. As viewed in the z-direction, a direction orthogonal to the x-direction is referred to as a y-direction. The x-direction corresponds to a “first direction.” The y-direction corresponds to a “second direction.”

The primary die pad 70 and the secondary die pad 80 are each flat. In the present embodiment, as viewed in the z-direction, the die pads 70 and 80 are each rectangular so that the short sides extend in the x-direction and the long sides extend in the y-direction. In the present embodiment, as viewed in the z-direction, the secondary die pad 80 is greater in area than the primary die pad 70. The shape of the die pads 70 and 80 as viewed in the z-direction may be changed in any manner. In an example, as viewed in the z-direction, the die pads 70 and 80 are each rectangular so that the long sides extend in the x-direction and the short sides extend in the y-direction.

In the present embodiment, the transformer chip 60 is mounted on the secondary die pad 80. Thus, the transformer chip 60 and the second chip 50 are mounted on the secondary die pad 80. The transformer chip 60 and the second chip 50 are separated from each other in the x-direction on the secondary die pad 80. Thus, the chips 40, 50, and 60 are separated from each other in the x-direction. In the present embodiment, the chips 40, 50, and 60 are arranged in the x-direction from the primary die pad 70 toward the secondary die pad 80 in the order of the first chip 40, the transformer chip 60, and the second chip 50. In other words, the transformer chip 60 is located between the first chip 40 and the second chip 50 in the x-direction. In the present embodiment, the die pads 70 and 80 are not exposed from the encapsulation resin 90.

The die pads 70 and 80 need to be separated from each other so that the insulation voltage of the signal transmission device 10 is set to a predetermined insulation voltage. In the present embodiment, as viewed in the z-direction, the distance between the primary die pad 70 and the secondary die pad 80 in the x-direction is greater than the distance between the second chip 50 and the transformer chip 60 in the x-direction. Accordingly, as viewed in the z-direction, the distance between the first chip 40 and the transformer chip 60 in the x-direction is greater than the distance between the second chip 50 and the transformer chip 60 in the x-direction. In other words, the transformer chip 60 is located closer to the second chip 50 than to the first chip 40.

As viewed in the z-direction, the first chip 40 is rectangular and has short sides and long sides. As viewed in the z-direction, the first chip 40 is mounted on the primary die pad 70 so that the short sides extend in the x-direction and the long sides extend in the y-direction.

The first chip 40 includes a first substrate 43 that includes the primary circuit 13. The first substrate 43 is, for example, a semiconductor substrate. An example of the semiconductor substrate is a substrate formed from a material including silicon (Si). A wiring layer 44 is formed on the first substrate 43. The wiring layer 44 includes insulation films stacked in the z-direction and metal layers arranged between ones of the insulation films that are adjacent to each other in the z-direction. The metal layers form a wiring pattern of the first chip 40. The metal layers are, for example, electrically connected to the primary circuit 13.

The first chip 40 includes a chip main surface 40s and a chip back surface 40r facing opposite directions in the z-direction. The first substrate 43 includes the chip back surface 40r. The wiring layer 44 includes the chip main surface 40s. The chip back surface 40r faces the primary die pad 70. First electrode pads 41 and second electrode pads 42 are arranged on the first chip 40 at the side of the chip main surface 40s. More specifically, the electrode pads 41 and 42 are exposed from the chip main surface 40s. The electrode pads 41 and 42 are, for example, electrically connected to the primary circuit 13 by the wiring layer 44.

The first electrode pads 41 are arranged on the chip main surface 40s at a side opposite to the transformer chip 60 with respect to the center of the chip main surface 40s in the x-direction. Although not shown, the first electrode pads 41 are separated from each other in the y-direction. As shown in FIG. 2, the second electrode pads 42 are arranged on the chip main surface 40s at a position closer to the transformer chip 60 than the center of the chip main surface 40s in the x-direction is. Although not shown, the second electrode pads 42 are separated from each other in the y-direction.

As shown in FIG. 2, the first chip 40 is bonded to the primary die pad 70 by a first bonding material 101. More specifically, the first bonding material 101 is located between the chip back surface 40r and the primary die pad 70. The first bonding material 101 bonds the chip back surface 40r and the primary die pad 70. The first bonding material 101 is a conductive bonding material such as solder or silver (Ag) paste. In the present embodiment, the first bonding material 101 corresponds to “first conductive bonding material.”

The first bonding material 101 bonds the first substrate 43 of the first chip 40 and the primary die pad 70. This electrically connects the first substrate 43 to the primary die pad 70. Thus, the primary circuit 13 is electrically connected to the primary die pad 70 by the first bonding material 101. The primary die pad 70 forms ground. Thus, the primary circuit 13 is electrically connected to the ground.

As viewed in the z-direction, the second chip 50 is rectangular and has short sides and long sides. As viewed in the z-direction, the second chip 50 is mounted on the secondary die pad 80 so that the short sides extend in the x-direction and the long sides extend in the y-direction.

As shown in FIG. 2, the second chip 50 includes a second substrate 53 that includes the secondary circuit 14. The second substrate 53 is, for example, a semiconductor substrate. An example of the semiconductor substrate is a Si substrate. A wiring layer 54 is formed on the second substrate 53. The wiring layer 54 includes insulation films stacked in the z-direction and metal layers arranged between ones of the insulation films that are adjacent to each other in the z-direction. The metal layers form a wiring pattern of the second chip 50. The metal layers are, for example, electrically connected to the secondary circuit 14.

The second chip 50 includes a chip main surface 50s and a chip back surface 50r facing opposite directions in the z-direction. The second substrate 53 includes the chip back surface 50r. The wiring layer 54 includes the chip main surface 50s. The chip back surface 50r faces the secondary die pad 80. The chip back surface 50r and the chip back surface 40r of the first chip 40 face in the same direction. The chip main surface 50s and the chip main surface 40s of the first chip 40 face in the same direction. First electrode pads 51 and second electrode pads 52 are arranged on the second chip 50 at the side of the chip main surface 50s. More specifically, the electrode pads 51 and 52 are exposed from the chip main surface 50s. The electrode pads 51 and 52 are, for example, electrically connected to the secondary circuit 14 by the wiring layer 54.

The first electrode pads 51 are arranged on the chip main surface 50s at a position closer to the transformer chip 60 than the center of the chip main surface 50s in the x-direction is. Although not shown, the first electrode pads 51 are separated from each other in the y-direction. The second electrode pads 52 are arranged on the chip main surface 50s at a side opposite to the transformer chip 60 with respect to the center of the chip main surface 50s in the x-direction. Although not shown, the second electrode pads 52 are separated from each other in the y-direction.

As shown in FIG. 2, the second chip 50 is bonded to the secondary die pad 80 by a second bonding material 102. More specifically, the second bonding material 102 is located between the chip back surface 50r and the secondary die pad 80. The second bonding material 102 bonds the chip back surface 50r and the secondary die pad 80. The second bonding material 102 is a conductive bonding material such as solder or Ag paste. In the present embodiment, the second bonding material 102 is, for example, the same material as the first bonding material 101. In the present embodiment, the second bonding material 102 corresponds to a “second conductive bonding material.”

The second bonding material 102 bonds the second substrate 53 of the second chip 50 and the secondary die pad 80. This electrically connects the second substrate 53 to the secondary die pad 80. Thus, the secondary circuit 14 is electrically connected to the secondary die pad 80 by the second bonding material 102. The secondary die pad 80 forms ground. Thus, the secondary circuit 14 is electrically connected to the ground.

The transformer chip 60 includes the two transformers 15A and 15B (refer to FIG. 1). As viewed in the z-direction, the transformer chip 60 is rectangular and has short sides and long sides. In the present embodiment, as viewed in the z-direction, the transformer chip 60 is mounted on the secondary die pad 80 so that the long sides extend in the y-direction and the short sides extend in the x-direction.

The transformer chip 60 includes a chip main surface 60s and a chip back surface 60r facing opposite directions in the z-direction. The chip back surface 60r faces the secondary die pad 80. More specifically, the chip back surface 60r and the chip back surface 50r of the second chip 50 face in the same direction. The chip main surface 60s and the chip main surface 50s of the second chip 50 face in the same direction.

The transformer chip 60 includes first electrode pads 61 and second electrode pads 62. The first electrode pads 61 and the second electrode pads 62 are arranged at the side of the chip main surface 60s. More specifically, as viewed in the z-direction, the electrode pads 61 and 62 are exposed from the chip main surface 60s.

The first electrode pads 61 are arranged on the chip main surface 60s at a position closer to the first chip 40 than the center, in the x-direction, of the chip main surface 60s is. The second electrode pads 62 are arranged on the chip main surface 60s at a position closer to the second chip 50 than the center, in the x-direction, of the chip main surface 60s is.

Wires W are connected to each of the first chip 40, the transformer chip 60, and the second chip 50. Each wire W is a bonding wire formed by a wire bonder and is, for example, formed from a conductor such as gold (Au), Al, Cu, or the like.

The first electrode pads 41 of the first chip 40 are separately connected to primary leads, which are not shown, by wires W. The primary leads are parts forming the primary terminals 11 shown in FIG. 1. Thus, the primary circuit 13 is electrically connected to the primary terminals 11.

In the present embodiment, the primary leads and the primary die pad 70 are formed from the same material. The primary leads and the primary die pad 70 may be formed integrally. The primary leads are arranged separately from the primary die pad 70 at a side of the primary die pad 70 opposite from the secondary die pad 80. The primary leads extend over the encapsulation resin 90. More specifically, the primary leads include portions projecting out from the encapsulation resin 90. The portions of the primary leads projecting out from the encapsulation resin 90 form external terminals of the signal transmission device 10.

The second electrode pads 42 of the first chip 40 are separately connected to the first electrode pads 61 of the transformer chip 60 by wires W. Thus, the primary circuit 13 is electrically connected to the transformers 21A and 21B (refer to FIG. 1). In other words, the wiring layer 44 of the first chip 40, the second electrode pads 42, the wires W, and the first electrode pads 61 each form a portion of the primary signal lines 16A and 16B (refer to FIG. 1).

The second electrode pads 62 of the transformer chip 60 are separately connected to the first electrode pads 51 of the second chip 50 by wires W. Thus, the transformers 22A and 22B are electrically connected to the secondary circuit 14 (refer to FIG. 1). In other words, the second electrode pads 62, the wires W, and the first electrode pads 51 of the second chip 50 each form a portion of the secondary signal lines 17A and 17B (refer to FIG. 1).

The second electrode pads 52 of the second chip 50 are separately connected to secondary leads, which are not shown, by wires W. The secondary leads are parts forming the secondary terminals 12 shown in FIG. 1. Thus, the secondary circuit 14 is electrically connected to the secondary terminals 12.

In the present embodiment, the secondary leads and the secondary die pad 80 are formed from the same material. The secondary leads and the secondary die pad 80 may be formed integrally. The secondary leads are arranged separately from the secondary die pad 80 at a side of the secondary die pad 80 opposite from the primary die pad 70. The secondary leads extend over the encapsulation resin 90. More specifically, the secondary leads include portions projecting out from the encapsulation resin 90. The portions of the secondary leads projecting out from the encapsulation resin 90 form external terminals of the signal transmission device 10.

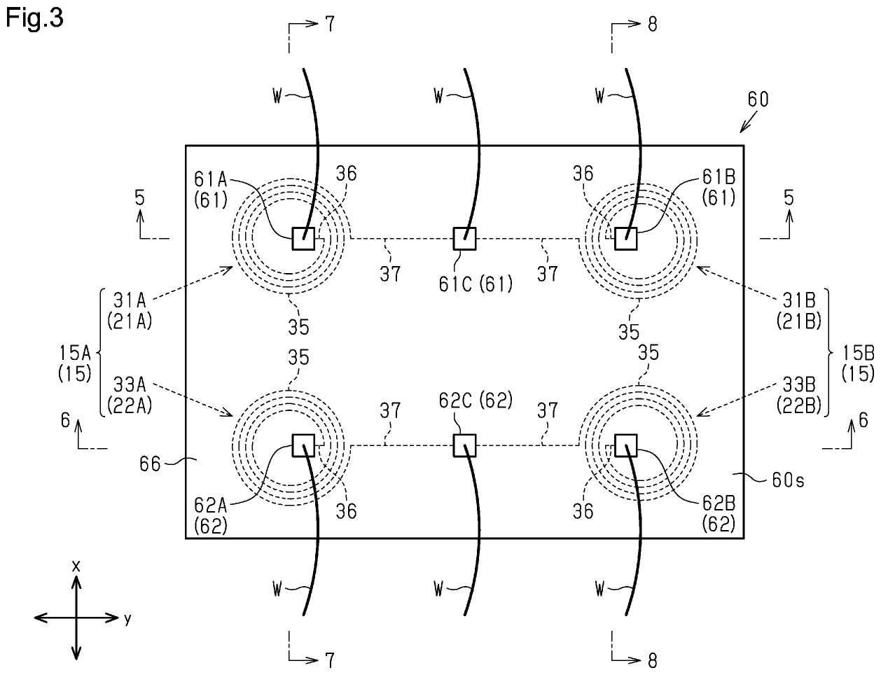

An example of the internal structure of the transformer chip 60 will now be described with reference to FIGS. 3 to 8.

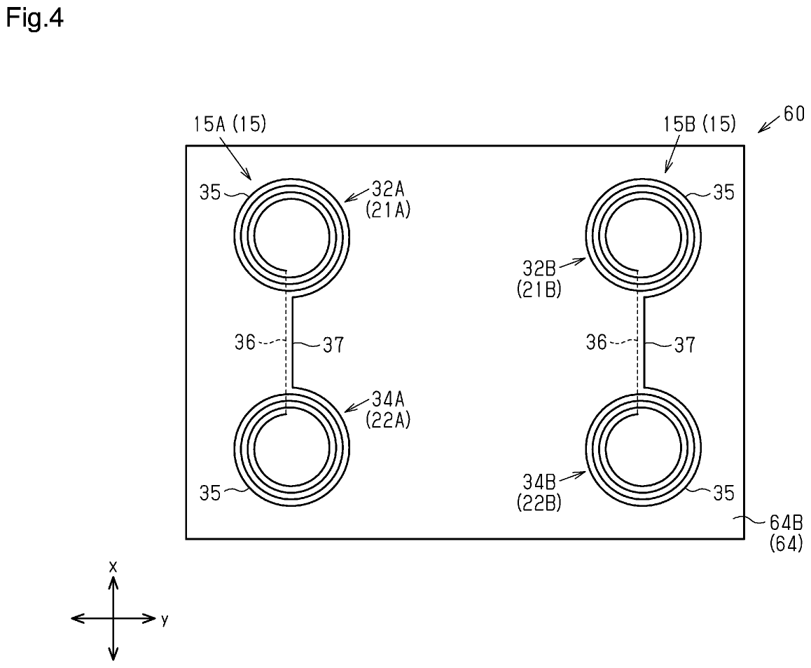

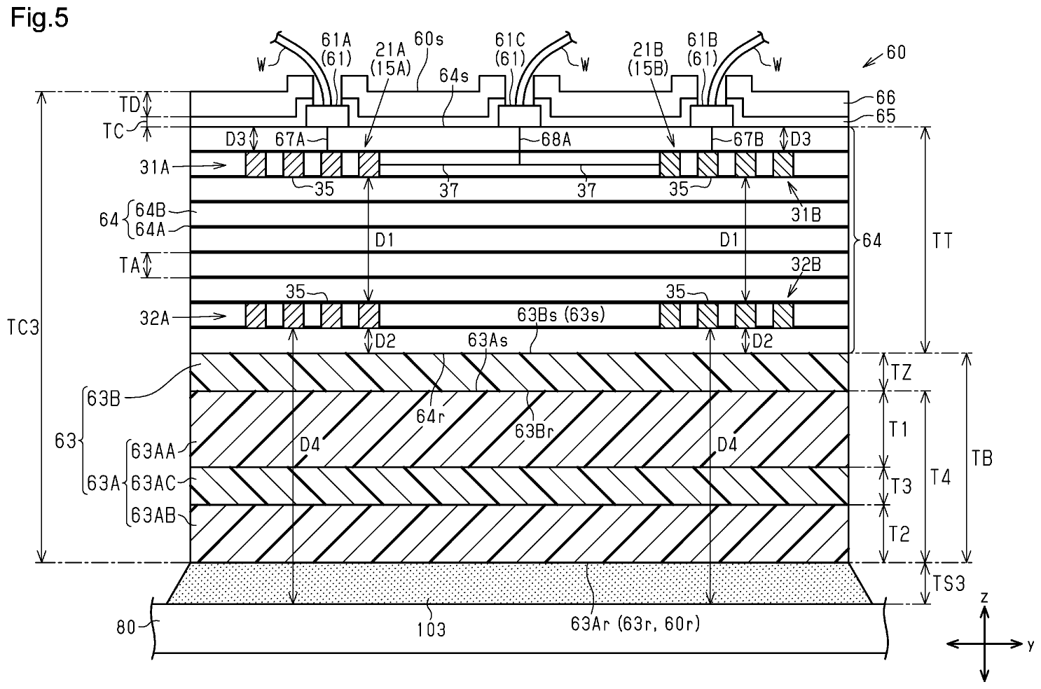

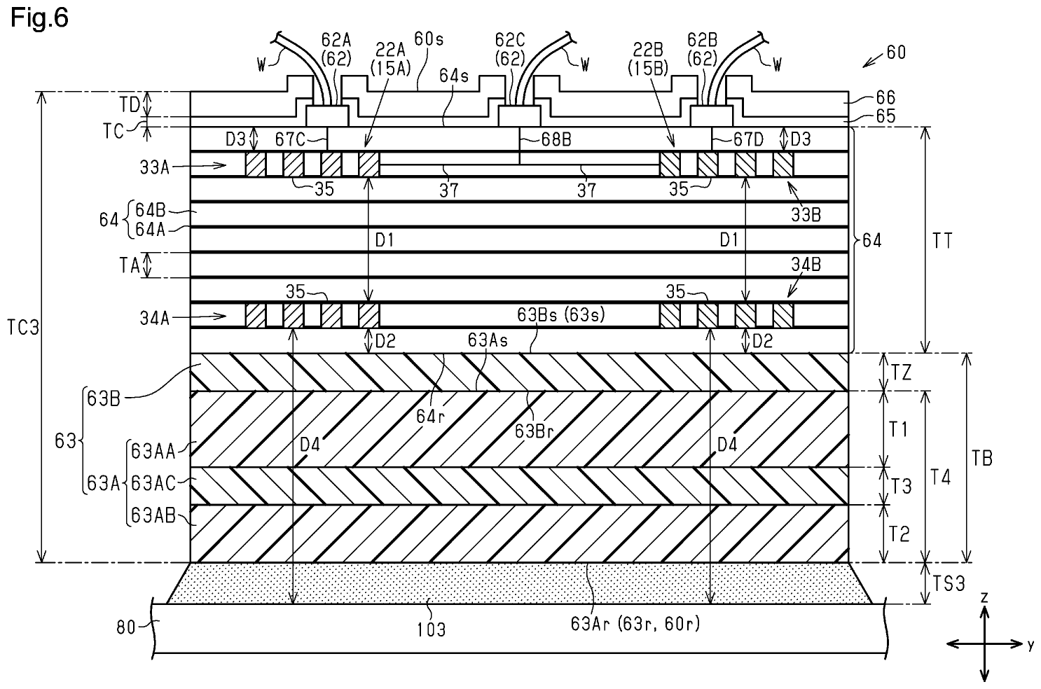

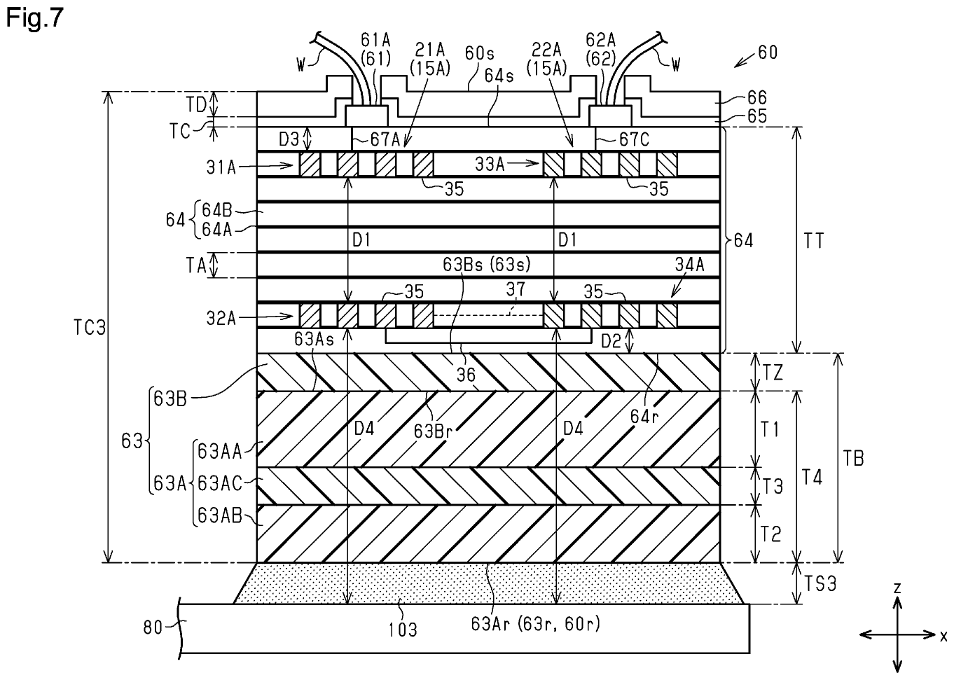

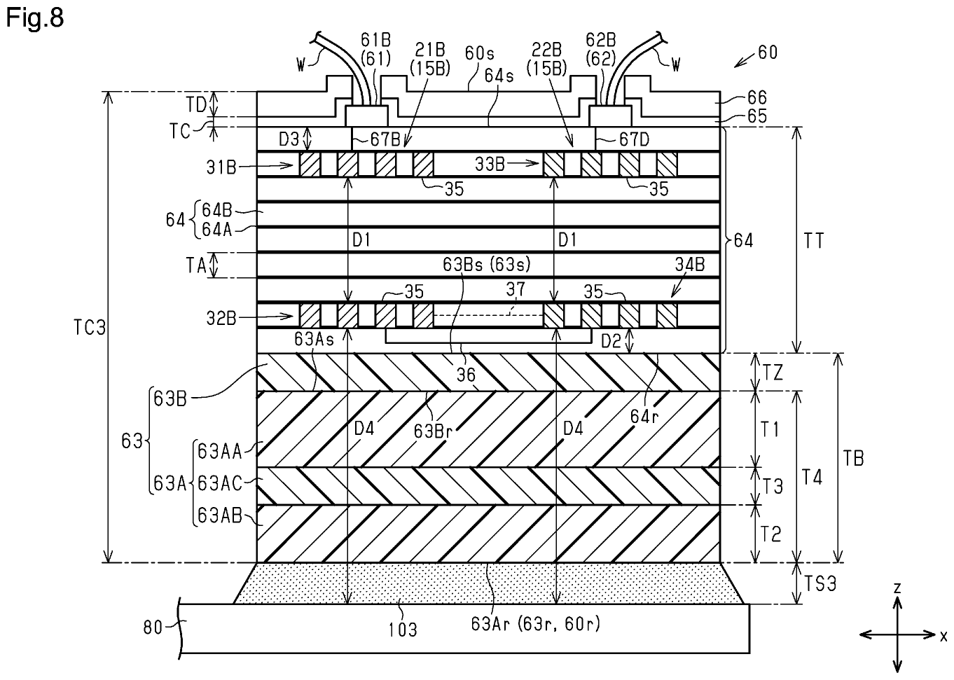

FIG. 3 is a schematic plan view showing a planar structure of the transformer chip 60. FIG. 4 is a schematic cross-sectional view showing a cross-sectional internal structure of the transformer chip 60 taken along the xy-plane. FIG. 4 does not show hatching for simplicity and clarity. FIGS. 5 and 6 are each a schematic cross-sectional view showing a cross-sectional structure of the transformer chip 60 mounted on the secondary die pad 80 taken along the yz-plane. FIGS. 7 and 8 are each a schematic cross-sectional view showing a cross-sectional structure of the transformer chip 60 mounted on the secondary die pad 80 taken along the yz-plane. FIGS. 5 to 8 each show a schematic cross-sectional structure of the transformer chip 60. The number of element insulation layers 64 that are stacked, which will be described later, is not limited to those of the element insulation layers 64 shown in FIGS. 5 to 8. The coils 31A, 31B, 32A, 32B, 33A, 33B, 34A, and 34B are schematically shown in FIGS. 5 to 8 and thus do not match the coils 31A, 31B, 32A, 32B, 33A, 33B, 34A, and 34B shown in FIG. 3. FIGS. 5 to 8 do not show first ends 36, which will be described later.

In the following description, a direction from the chip back surface 60r of the transformer chip 60 toward the chip main surface 60s is referred to as an upward direction, and a direction from the chip main surface 60s toward the chip back surface 60r is referred to as a downward direction.

As shown in FIGS. 3 and 4, the two transformers 15A and 15B are integrated in a single chip, that is, the transformer chip 60. More specifically, the transformer chip 60 is separate from the first chip 40 and the second chip 50 and is dedicated to the two transformers 15A and 15B.

As shown in FIGS. 3 and 4, as viewed in the z-direction, the two transformers 15A and 15B are separated from each other in the y-direction. As viewed in the z-direction, the first transformer 21A of the transformer 15A and the first transformer 21B of the transformer 15B are located closer to the first chip 40 (refer to FIG. 2) than the center of the transformer chip 60 in the x-direction is. As viewed in the z-direction, the second transformer 22A of the transformer 15A and the second transformer 22B of the transformer 15B are located closer to the second chip 50 (refer to FIG. 2) than the center, in the x-direction, of the transformer chip 60 is. The first transformers 21A and 21B are aligned with each other in the x-direction and separated from each other in the y-direction. The second transformers 22A and 22B are aligned with each other in the x-direction and separated from each other in the y-direction. The first transformer 21A and the second transformer 22A are aligned with each other in the y-direction and separated from each other in the x-direction. The first transformer 21B and the second transformer 22B are aligned with each other in the y-direction and separated from each other in the x-direction. In other words, the first transformer 21A (21B) and the second transformer 22A (22B) are separated from each other in the arrangement direction of the two die pads 70 and 80.

In accordance with the arrangement relationship of the transformers 21A, 21B, 22A, and 22B described above, the first coil 31A of the first transformer 21A and the first coil 33A of the second transformer 22A are spaced apart from each other in the x-direction. In the same manner, the first coil 31B of the first transformer 21B and the first coil 33B of the second transformer 22B are spaced apart from each other in the x-direction. In other words, the first coil 31A (31B) of the first transformer 21A (21B) and the first coil 33A (33B) of the second transformer 22A (22B) are spaced apart from each other in the arrangement direction of the two die pads 70 and 80.

Also, the first coil 31A of the first transformer 21A and the first coil 31B of the first transformer 21B are spaced apart from each other in the y-direction. The first coil 33A of the second transformer 22A and the first coil 33B of the second transformer 22B are spaced apart from each other in the y-direction. In other words, as viewed in the z-direction, the first coil 31A of the first transformer 21A and the first coil 31B of the first transformer 21B are spaced apart from each other in a direction orthogonal to the arrangement direction of the two die pads 70 and 80. Also, as viewed in the z-direction, the first coil 33A of the second transformer 22A and the first coil 33B of the second transformer 22B are spaced apart from each other in the direction orthogonal to the arrangement direction of the two die pads 70 and 80.

As shown in FIGS. 3, 5, and 6, the first coils 31A, 31B, 33A, and 33B are aligned with each other in the z-direction. The coils 31A, 31B, 33A, and 33B are formed from one or more selected from titanium (Ti), titanium nitride (TiN), tantalum (Ta), tantalum nitride (TaN), Au, Ag, Cu, Al, and tungsten (W). In the present embodiment, the coils 31A, 31B, 33A, and 33B are formed from a material including Cu.

As shown in FIG. 3, in the present embodiment, the coils 31A, 31B, 33A, and 33B are identical in shape. Each of the coils 31A, 31B, 33A, and 33B includes a spiral coil portion 35, a first end 36 leading inward from the inner circumference of the coil portion 35, and a second end 37 leading outward from the outer circumference of the coil portion 35. The first ends 36 of the coils 31A and 31B are configured to be electrically connected to the primary circuit 13 (refer to FIG. 1). The second ends 37 of the coils 31A and 31B are configured to be electrically connected to the ground of the primary circuit 13. The first ends 36 of the coils 33A and 33B are configured to be electrically connected to the secondary circuit 14 (refer to FIG. 1). The second ends 37 of the coils 33A and 33B are configured to be electrically connected to the ground of the secondary circuit 14.

As shown in FIG. 3, the multiple (in the present embodiment, three) first electrode pads 61 are separately electrically connected to the first coils 31A and 31B. The first electrode pads 61 are separated from each other in the y-direction. As viewed in the y-direction, the first electrode pads 61 overlap with the coil portions 35 of the first coils 31A and 31B. In the following description, for the sake of convenience, the three first electrode pads 61 are referred to as the first electrode pads 61A, 61B, 61C. In the present embodiment, the first electrode pads 61A and 61B each correspond to a “first pad.” The first electrode pad 61C corresponds to a “third pad.”

As viewed in the z-direction, the first electrode pad 61A is located inside the coil portion 35 of the first coil 31A. More specifically, the first electrode pad 61A is inwardly spaced apart from the inner circumference of the coil portion 35 of the first coil 31A. In other words, the coil portion 35 of the first coil 31A encompasses the first electrode pad 61A. In other words, the first electrode pad 61A is located at an inner side of the first coil 31A. The first electrode pad 61A is electrically connected to the first end 36 of the first coil 31A.

As viewed in the y-direction, the first electrode pad 61A overlaps the first end 36 of the first coil 31A. As viewed in the z-direction, the first electrode pad 61A is shifted from the center of the first coil 31A. In other words, as viewed in the z-direction, the first electrode pad 61A does not overlap the center of the first coil 31A. The center of the first coil 31A is the center of the coil portion 35 of the first coil 31A. In other words, the center of the first coil 31A is the winding center of the coil portion 35 of the first coil 31A. In the present embodiment, the first electrode pad 61A is shifted from the center of the coil portion 35 of the first coil 31A in the y-direction. More specifically, the first electrode pad 61A is shifted from the center of the coil portion 35 of the first coil 31A toward the first coil 31B in the y-direction. Such arrangement of the first electrode pad 61A reduces eddy current that is formed on the first electrode pad 61A by a magnetic flux generated from the first coil 31A.

As viewed in the z-direction, the first electrode pad 61B is located inside the coil portion 35 of the first coil 31B. More specifically, the first electrode pad 61B is inwardly spaced apart from the inner circumference of the coil portion 35 of the first coil 31B. In other words, the coil portion 35 of the first coil 31B encompasses the first electrode pad 61B. In other words, the first electrode pad 61B is located at an inner side of the first coil 31B. The first electrode pad 61B is electrically connected to the first end 36 of the first coil 31B.

As viewed in the y-direction, the first electrode pad 61B overlaps the first end 36 of the first coil 31B. As viewed in the z-direction, the first electrode pad 61B is shifted from the center of the first coil 31B. In other words, as viewed in the z-direction, the first electrode pad 61B does not overlap the center of the first coil 31B. The center of the first coil 31B is the center of the coil portion 35 of the first coil 31B. In other words, the center of the first coil 31B is the winding center of the coil portion 35 of the first coil 31B. In the present embodiment, the first electrode pad 61B is shifted from the center of the coil portion 35 of the first coil 31B in the y-direction. More specifically, the first electrode pad 61B is shifted from the center of the coil portion 35 of the first coil 31B toward the first coil 31A in the y-direction. Such arrangement of the first electrode pad 61B reduces eddy current that is formed on the first electrode pad 61B by a magnetic flux generated from the first coil 31B.

As viewed in the z-direction, the first electrode pad 61C is located between the coil portion 35 of the first coil 31A and the coil portion 35 of the first coil 31B in the y-direction. That is, as viewed in the z-direction, the first electrode pad 61C is located outside the coil portion 35 of each of the first coils 31A and 31B. In other words, as viewed in the z-direction, the first electrode pad 61C is located between the first electrode pad 61A and the first electrode pad 61B in the y-direction. The first electrode pad 61C is electrically connected to the second end 37 of the first coil 31A and the second end 37 of the first coil 31B.

The multiple (in the present embodiment, three) second electrode pads 62 are separately electrically connected to the first coils 33A and 33B. As viewed in the y-direction, the second electrode pads 62 overlap with the coil portions 35 of the first coils 33A and 33B. The electrode pads 61 and 62 are formed from a material including, for example, Al. In the following description, for the sake of convenience, the three second electrode pads 62 are referred to as the second electrode pads 62A, 62B, and 62C. In the present embodiment, the second electrode pads 62A and 62B each correspond to a “second pad.” The second electrode pad 62C corresponds to a “fourth pad.”

As viewed in the z-direction, the second electrode pad 62A is located inside the coil portion 35 of the first coil 33A. More specifically, the second electrode pad 62A is inwardly spaced apart from the inner circumference of the coil portion 35 of the first coil 33A. In other words, the coil portion 35 of the first coil 33A encompasses the second electrode pad 62A. In other words, the second electrode pad 62A is located at an inner side of the first coil 33A. The second electrode pad 62A is electrically connected to the first end 36 of the first coil 33A.

As viewed in the y-direction, the second electrode pad 62A overlaps the first end 36 of the first coil 33A. As viewed in the z-direction, the second electrode pad 62A is shifted from the center of the first coil 33A. In other words, as viewed in the z-direction, the second electrode pad 62A does not overlap the center of the first coil 33A. The center of the first coil 33A is the center of the coil portion 35 of the first coil 33A. In other words, the center of the first coil 33A is the winding center of the coil portion 35 of the first coil 33A. In the present embodiment, the second electrode pad 62A is shifted from the center of the coil portion 35 of the first coil 33A in the y-direction. More specifically, the second electrode pad 62A is shifted from the center of the coil portion 35 of the first coil 33A toward the first coil 33B in the y-direction. Such arrangement of the second electrode pad 62A reduces eddy current that is formed on the second electrode pad 62A by a magnetic flux generated from the first coil 33A.

As viewed in the z-direction, the second electrode pad 62B is located inside the coil portion 35 of the first coil 33B. More specifically, the second electrode pad 62B is inwardly spaced apart from the inner circumference of the coil portion 35 of the first coil 33B. In other words, the coil portion 35 of the first coil 33B encompasses the second electrode pad 62B. In other words, the second electrode pad 62B is located at an inner side of the first coil 33B. The second electrode pad 62B is electrically connected to the first end 36 of the first coil 33B.

As viewed in the y-direction, the second electrode pad 62B overlaps the first end 36 of the first coil 33B. As viewed in the z-direction, the second electrode pad 62B is shifted from the center of the first coil 33B. In other words, as viewed in the z-direction, the second electrode pad 62B does not overlap the center of the first coil 33B. The center of the first coil 33B is the center of the coil portion 35 of the first coil 33B. In other words, the center of the first coil 33B is the winding center of the coil portion 35 of the first coil 33B. In the present embodiment, the second electrode pad 62B is shifted from the center of the coil portion 35 of the first coil 33B in the y-direction. More specifically, the second electrode pad 62B is shifted from the center of the coil portion 35 of the first coil 33B toward the first coil 33A in the y-direction. Such arrangement of the second electrode pad 62B reduces eddy current that is formed on the second electrode pad 62B by a magnetic flux generated from the first coil 33B.

As viewed in the z-direction, the second electrode pad 62C is located between the coil portion 35 of the first coil 33A and the coil portion 35 of the first coil 33B in the y-direction. That is, as viewed in the z-direction, the second electrode pad 62C is located outside the coil portion 35 of each of the first coils 33A and 33B. In other words, as viewed in the z-direction, the second electrode pad 62C is located between the second electrode pad 62A and the second electrode pad 62B in the y-direction. The second electrode pad 62C is electrically connected to the second end 37 of the first coil 33A and the second end 37 of the first coil 33B.

The layout of the first electrode pads 61A to 61C and the second electrode pads 62A to 62C is not limited to the layout of the first electrode pads 61A to 61C and the second electrode pads 62A to 62C shown in FIG. 3 and may be changed in any manner. In an example, as viewed in the z-direction, the first electrode pad 61A may be shifted from the center of the coil portion 35 of the first coil 31A in the x-direction. The first electrode pad 61B and the second electrode pads 62A and 62B may be changed in the same manner. In an example, as viewed in the z-direction, the first electrode pad 61A may overlap the coil portion 35 of the first coil 31A. The first electrode pad 61B and the second electrode pads 62A and 62B may be changed in the same manner.

As shown in FIGS. 3 and 4, the second coil 32A of the first transformer 21A overlaps the first coil 31A of the first transformer 21A as viewed in the z-direction. The second coil 32B of the first transformer 21B overlaps the first coil 31B of the first transformer 21B as viewed in the z-direction. The second coil 34A of the second transformer 22A overlaps the first coil 33A of the second transformer 22A as viewed in the z-direction. The second coil 34B of the second transformer 22B overlaps the first coil 33B of the second transformer 22B as viewed in the z-direction.

In accordance with the arrangement relationship of the coils 31A to 34A and 31B to 34B described above, the second coil 32A and the second coil 34A are spaced apart from each other in the x-direction. Also, the second coil 32B and the second coil 34B are spaced apart from each other in the x-direction. In other words, the second coil 32A (32B) of the first transformer 21A (21B) and the second coil 34A (34B) of the second transformer 22A (22B) are spaced apart from each other in the arrangement direction of the two die pads 70 and 80.

The second coil 32A and the second coil 32B are spaced apart from each other in the y-direction. The second coil 34A and the second coil 34B are spaced apart from each other in the y-direction. In other words, as viewed in the z-direction, the second coil 32A of the first transformer 21A and the second coil 32B of the first transformer 21B are spaced apart from each other in the direction orthogonal to the arrangement direction of the two die pads 70 and 80. Also, as viewed in the z-direction, the second coil 34A of the second transformer 22A and the second coil 34B of the second transformer 22B are spaced apart from each other in the direction orthogonal to the arrangement direction of the two die pads 70 and 80.

The first end 36 of the second coil 32A is connected to the first end 36 of the second coil 34A. The second end 37 of the second coil 32A is connected to the second end 37 of the second coil 34A. The first end 36 of the second coil 32B is connected to the first end 36 of the second coil 34B. The second end 37 of the second coil 32B is connected to the second end 37 of the second coil 34B.

As shown in FIG. 7, the first end 36 of the second coil 32A and the first end 36 of the second coil 34A are arranged in one of the element insulation layers 64 that differs from the element insulation layer 64 in which the coil portions 35 of the second coils 32A and 34A are arranged. In the present embodiment, the first ends 36 of the second coils 32A and 34A are arranged in one of the element insulation layers 64 that is located closer to a substrate 63 than the coil portions 35 of the second coils 32A and 34A are. The second ends 37 of the second coils 32A and 34A and the coil portions 35 of the second coils 32A and 34A are arranged in the same element insulation layer 64 among the element insulation layers 64.

As shown in FIG. 8, the first end 36 of the second coil 32B and the first end 36 of the second coil 34B are arranged in one of the element insulation layers 64 that differs from the element insulation layer 64 in which the coil portions 35 of the second coils 32B and 34B are arranged. The second ends 37 of the second coils 32B and 34B and the coil portions 35 of the second coils 32B and 34B are arranged in the same element insulation layer 64 among the element insulation layers 64. The layout of the first ends 36 and the second ends 37 of the second coils 32B and 34B is the same as the layout of the first ends 36 and the second ends 37 of the second coils 32A and 34A.

In the present embodiment, the number of windings in the first coil 31A is the same as the number of windings in the second coil 32A. In the present embodiment, the outer diameter of the coil portion 35 of the first coil 31A is equal to the outer diameter of the coil portion 35 of the second coil 32A. The relationship of the first coil 31A and the second coil 32A is the same as that of the first coil 31B and the second coil 32B, that of the first coil 33A and the second coil 34A, and that of the first coil 33B and the second coil 34B.

As shown in FIG. 3, in the present embodiment, the winding direction of the coil portion 35 of the first coil 31A is the same as the winding direction of the coil portion 35 of the first coil 31B. The winding direction of the coil portion 35 of the first coil 33A is the same as the winding direction of the coil portion 35 of the first coil 33B. Thus, as shown in FIG. 3, the first coil 31A and the first coil 31B are arranged to have point symmetry about the first electrode pad 61C. The first coil 33A and the first coil 33B are arranged to have point symmetry about the second electrode pad 62C.

As shown in FIGS. 5 to 8, the transformer chip 60 includes the substrate 63 and the element insulation layers 64 formed on the substrate 63.

The substrate 63 is formed of, for example, a semiconductor substrate. In an example, the substrate 63 includes a semiconductor substrate formed from a material including Si. As the semiconductor substrate, a wide-bandgap semiconductor or a compound semiconductor may be used for the substrate 63. The substrate 63 may be an insulating substrate formed from a material including glass or an insulating substrate formed from a material including ceramics such as alumina instead of a semiconductor substrate.

The wide-bandgap semiconductor is a semiconductor substrate having a band gap that is greater than or equal to 2.0 eV. The wide-bandgap semiconductor may be silicon carbide (SiC). The compound semiconductor may be a group III-V compound semiconductor. The compound semiconductor may include at least one of aluminum nitride (AlN), indium nitride (InN), gallium nitride (GaN), and gallium arsenide (GaAs).

The substrate 63 includes a body 63A and a substrate insulation layer 63B. The substrate 63 includes a substrate front surface 63s and a substrate back surface 63r facing opposite directions in the z-direction. The substrate front surface 63s and the front surface 64s of the element insulation layers 64 face in the same direction. The substrate back surface 63r and the back surface 64r of the element insulation layers 64 face in the same direction.

The body 63A includes a front surface 63As and a back surface 63Ar facing opposite directions in the z-direction. The front surface 63As and the front surface 64s of the element insulation layers 64 face in the same direction. The back surface 63Ar and the back surface 64r of the element insulation layers 64 face in the same direction. The back surface 63Ar of the body 63A includes the substrate back surface 63r of the substrate 63.

In the present embodiment, a silicon-on-insulator (SOI) substrate is used as the substrate 63. Thus, the body 63A includes a first semiconductor layer 63AA, a second semiconductor layer 63AB, and an oxide film 63AC. The first semiconductor layer 63AA and the second semiconductor layer 63AB are formed from a material including, for example, Si. The oxide film 63AC is a silicon oxide film. The oxide film 63AC is located between the first semiconductor layer 63AA and the second semiconductor layer 63AB in the z-direction. The first semiconductor layer 63AA includes the front surface 63As of the body 63A. The second semiconductor layer 63AB includes the back surface 63Ar of the body 63A (the substrate back surface 63r of the substrate 63).

The substrate insulation layer 63B includes a front surface 63Bs and a back surface 63Br facing opposite directions in the z-direction. The front surface 63Bs and the front surface 63As of the body 63A face in the same direction. The back surface 63Br and the back surface 63Ar of the body 63A face in the same direction. The substrate insulation layer 63B is formed on the body 63A. In the present embodiment, the substrate insulation layer 63B is formed on the front surface 63As of the body 63A. Thus, the back surface 63Br of the substrate insulation layer 63B is in contact with the front surface 63As of the body 63A. In other words, the substrate insulation layer 63B is formed on the first semiconductor layer 63AA. Thus, the back surface 63Br of the substrate insulation layer 63B is in contact with the first semiconductor layer 63AA. The front surface 63Bs of the substrate insulation layer 63B includes the substrate front surface 63s of the substrate 63.

The substrate insulation layer 63B includes an oxide film. In the present embodiment, the substrate insulation layer 63B is a low pressure (LP)-tetraethyl orthosilicate (TEOS) oxide film. The TEOS oxide film is a silicon oxide film formed by a low pressure chemical vapor deposition (CVD) process in which an organic TEOS gas reacts with an oxygen-based gas.

The element insulation layers 64 are stacked on the front surface 63Bs of the substrate insulation layer 63B in the z-direction. In other words, the z-direction is a thickness-wise direction of the element insulation layers 64. In the present embodiment, the total thickness of the element insulation layers 64 is greater than the thickness of the substrate 63. The number of element insulation layers 64 stacked is set in accordance with the insulation voltage required of the transformer chip 60. Therefore, depending on the number of element insulation layers 64 stacked, the total thickness of the element insulation layers 64 may be smaller than the thickness of the substrate 63. The thickness of the substrate 63 is the distance between the front surface 63Bs of the substrate insulation layer 63B and the back surface 63Ar of the body 63A in the z-direction.

The element insulation layer 64 includes a first insulation film 64A and a second insulation film 64B formed on the first insulation film 64A.

The first insulation film 64A is, for example, an etching stopper film, and is formed from a material including silicon nitride (SiN), SiC, nitrogen-added silicon carbide (SiCN), or the like. The first insulation film 64A has the functionality of, for example, preventing diffusion of Cu. That is, the first insulation film 64A is a Cu diffusion barrier film. In the present embodiment, the first insulation film 64A is formed from a material including SiN. The second insulation film 64B is, for example, an interlayer insulation film and is an oxide film formed from a material including silicon oxide (SiO₂). As shown in FIGS. 5 and 6, the thickness of the second insulation film 64B is greater than the thickness of the first insulation film 64A. The thickness of the first insulation film 64A may be greater than or equal to 50 nm and less than 1000 nm. The thickness of the second insulation film 64B may be in a range of 500 nm to 5000 nm. In the present embodiment, the thickness of the first insulation film 64A is, for example, approximately 300 nm, and the thickness of the second insulation film 64B is, for example, approximately 2000 nm.

The first electrode pads 61 and the second electrode pads 62 are arranged on a front surface 64s of the element insulation layers 64. The front surface 64s of the element insulation layers 64 refers to a front surface of the uppermost one of the element insulation layers 64 stacked in the z-direction.

The element insulation layers 64 include a back surface 64r facing in a direction opposite from the front surface 64s of the element insulation layers 64 and opposed to the substrate front surface 63s of the substrate 63. In the present embodiment, the back surface 64r of the element insulation layers 64 is in contact with the substrate front surface 63s of the substrate 63. The back surface 64r of the element insulation layers 64 refers to a back surface of the lowermost one of the element insulation layers 64 stacked in the z-direction.

The transformer chip 60 further includes a protection film 65 formed on the front surface 64s of the element insulation layers 64 and a passivation film 66 formed on the protection film 65. The protection film 65 protects the element insulation layers 64 and is formed of, for example, a silicon oxide film. The passivation film 66 is a surface protection film of the transformer chip 60 and is formed of, for example, a silicon nitride film. The passivation film 66 includes the chip main surface 60s of the transformer chip 60.

The first electrode pads 61 and the second electrode pads 62 are covered by the protection film 65 and the passivation film 66. The protection film 65 and the passivation film 66 include openings that expose the first electrode pads 61 and the second electrode pads 62. This forms an exposed surface on each of the electrode pads 61 and 62 for connecting a wire W.

As shown in FIG. 5, the first transformers 21A and 21B are arranged in the element insulation layers 64. In other words, the first coil 31A and the second coil 32A of the first transformer 21A and the first coil 31B and the second coil 32B of the first transformer 21B are arranged in the element insulation layers 64.

The first coil 31A and the second coil 32A of the first transformer 21A are opposed to each other in the z-direction. The first coil 31A and the second coil 32A are separated from each other in the z-direction. One or more of the element insulation layers 64 are arranged between the first coil 31A and the second coil 32A in the z-direction. The first coil 31A is located closer to the front surface 64s than to the back surface 64r in the element insulation layers 64. The second coil 32A is located closer to the back surface 64r than to the front surface 64s in the element insulation layers 64. That is, the first coil 31A is located closer to the front surface 64s than the second coil 32A is in the element insulation layers 64. In other words, the second coil 32A is located closer to the back surface 64r than the first coil 31A is in the element insulation layers 64.

The first coil 31B and the second coil 32B of the first transformer 21B are opposed to each other in the z-direction. The first coil 31B and the second coil 32B are separated from each other in the z-direction. One or more of the element insulation layers 64 are arranged between the first coil 31B and the second coil 32B in the z-direction. The first coil 31B is located closer to the front surface 64s than to the back surface 64r in the element insulation layers 64. The second coil 32B is located closer to the back surface 64r than to the front surface 64s in the element insulation layers 64. That is, the first coil 31B is located closer to the front surface 64s than the second coil 32B is in the element insulation layers 64. In other words, the second coil 32B is located closer to the back surface 64r than the first coil 31B is in the element insulation layers 64.

The first coils 31A and 31B are aligned with each other in the z-direction. In other words, the first coils 31A and 31B are arranged in the same element insulation layer 64 among the element insulation layers 64. The second coils 32A and 32B are aligned with each other in the z-direction. In other words, the second coils 32A and 32B are arranged in the same element insulation layer 64 among the element insulation layers 64. The second coils 32A and 32B are separated from the back surface 64r of the element insulation layers 64 in the z-direction. In other words, one or more of the element insulation layers 64 are arranged between the back surface 64r of the element insulation layers 64 and the second coils 32A and 32B.

The first coils 31A and 31B extend through one of the element insulation layers 64 in the z-direction. That is, the first insulation film 64A and the second insulation film 64B of the one of the element insulation layers 64 include openings for formation of the first coils 31A and 31B. The openings are filled with a conductive member formed from a material including Cu. Thus, the first coils 31A and 31B are formed. In the same manner as the first coils 31A and 31B, the second coils 32A and 32B are formed by filling openings with a conductive member formed from a material including Cu.

The material of the second coils 32A and 32B may differ from that of the first coils 31A and 31Bs. In an example, the second coils 32A and 32B may be formed by filling the openings with a conductive member formed from a material including Al.

As shown in FIG. 6, the first coil 33A and the second coil 34A of the second transformer 22A are opposed to each other in the z-direction. The first coil 33A and the second coil 34A are separated from each other in the z-direction. One or more of the element insulation layers 64 are arranged between the first coil 33A and the second coil 34A in the z-direction. The first coil 33A is located closer to the front surface 64s than to the back surface 64r in the element insulation layers 64. The second coil 34A is located closer to the back surface 64r than to the front surface 64s in the element insulation layers 64. That is, the first coil 33A is located closer to the front surface 64s than the second coil 34A is, in the element insulation layers 64. In other words, the second coil 34A is located closer to the back surface 64r than the first coil 33A is, in the element insulation layers 64.

The first coil 33B and the second coil 34B of the second transformer 22B are opposed to each other in the z-direction. The first coil 33B and the second coil 34B are separated from each other in the z-direction. One or more of the element insulation layers 64 are arranged between the first coil 33B and the second coil 34B in the z-direction. The first coil 33B is located closer to the front surface 64s than to the back surface 64r in the element insulation layers 64. The second coil 34B is located closer to the back surface 64r than to the front surface 64s in the element insulation layers 64. That is, the first coil 33B is located closer to the front surface 64s than the second coil 34B is in the element insulation layers 64. In other words, the second coil 34B is located closer to the back surface 64r than the first coil 33B is in the element insulation layers 64.

The first coils 33A and 33B are aligned with each other in the z-direction. In other words, the first coils 33A and 33B are arranged in the same element insulation layer 64 among the element insulation layers 64. The second coils 34A and 34B are aligned with each other in the z-direction. In other words, the second coils 34A and 34B are arranged in the same element insulation layer 64 among the element insulation layers 64. The second coils 34A and 34B are separated from the back surface 64r of the element insulation layers 64 in the z-direction. In other words, one or more of the element insulation layers 64 are arranged between the back surface 64r of the element insulation layers 64 and the second coils 34A and 34B. In the present embodiment, as shown in FIGS. 5 to 8, the first coils 33A and 33B and the first coils 31A and 31B are aligned with each other in the z-direction. The second coils 34A and 34B and the second coils 32A and 32B are aligned with each other in the z-direction.

In the present embodiment, the first coils 31A and 31B correspond to a “first frontward conductor” and a “first frontward coil.” The second coils 32A and 32B correspond to a “first backward conductor” and a “first backward coil.” The first coils 33A and 33B correspond to a “second frontward conductor” and a “second frontward coil.” The second coils 34A and 34B correspond to a “second backward conductor” and a “second backward coil.”

As shown in FIGS. 3 and 5, the first end 36 of the first coil 31A includes a portion opposed to the first electrode pad 61A in the z-direction. The first end 36 of the first coil 31A is connected to the first electrode pad 61A by a connection line 67A. The connection line 67A is a via extending through the element insulation layer 64 in the z-direction and are formed from one or more selected from, for example, Ti, TiN, Ta, TaN, Au, Ag, Cu, Al, and W. Preferably, the connection line 67A is formed from one of W, Ti, and TiN. As viewed in the z-direction, the connection line 67A overlaps with both the first end 36 of the first coil 31A and the first electrode pad 61A and extends in the z-direction to connect the first end 36 and the first electrode pad 61A.

The first end 36 of the first coil 31B includes a portion opposed to the first electrode pad 61B in the z-direction. The first end 36 of the first coil 31B is connected to the first electrode pad 61B by a connection line 67B. As shown in FIG. 5, the connection line 67B and the connection line 67A are formed from the same material and connected in the same manner.

The second end 37 of the first coil 31A and the second end 37 of the first coil 31B each include a portion opposed to the first electrode pad 61C in the z-direction. The second ends 37 of the first coils 31A and 31B are connected to the first electrode pad 61C by a connection line 68A. The connection line 68A is, for example, a via extending through the element insulation layer 64 in the z-direction and is formed from one or more selected from, for example, Ti, TiN, Ta, TaN, Au, Ag, Cu, Al, and W in the same manner as the connection line 67A. In the present embodiment, the connection line 68A and the connection line 67A are formed from the same material. As viewed in the z-direction, the connection line 68A overlaps with all of the second ends 37 of the first coils 31A and 31B and the first electrode pad 61C and extends in the z-direction to connect the second ends 37 and the first electrode pad 61C.

As shown in FIGS. 3 and 6, the first end 36 of the first coil 33A includes a portion opposed to the second electrode pad 62A in the z-direction. The first end 36 of the first coil 33A is connected to the second electrode pad 62A by a connection line 67C. As shown in FIG. 6, the connection line 67C and the connection line 67A (refer to FIG. 5) are formed from the same material and connected in the same manner.

The first end 36 of the first coil 33B includes a portion opposed to the second electrode pad 62B in the z-direction. The first end 36 of the first coil 33B is connected to the second electrode pad 62B by a connection line 67D. As shown in FIG. 6, the connection line 67D and the connection line 67A are formed from the same material and connected in the same manner.

The second end 37 of the first coil 33A and the second end 37 of the first coil 33B each include a portion opposed to the second electrode pad 62C in the z-direction. The second ends 37 of the first coils 33A and 33B are connected to the second electrode pad 62C by a connection line 68B. As shown in FIG. 6, the connection line 68B and the connection line 68A (refer to FIG. 5) are formed from the same material and connected in the same manner.

The transformer chip 60 is bonded to the secondary die pad 80 by a third bonding material 103. More specifically, the third bonding material 103 is located between the back surface 63Ar of the body 63A of the substrate 63 (the chip back surface 60r) and the secondary die pad 80. The third bonding material 103 bonds the back surface 63Ar of the body 63A (the chip back surface 60r) and the secondary die pad 80. In the present embodiment, the third bonding material 103 is in contact with the entirety of the back surface 63Ar of the body 63A (the chip back surface 60r). The third bonding material 103 is an insulative bonding material such as an epoxy resin. Therefore, the third bonding material 103 differs from the first bonding material 101 and the second bonding material 102 (refer to FIG. 2). In the present embodiment, the third bonding material 103 corresponds to a “bonding material.”

An example of the dimensional relationship of the signal transmission device 10 will now be described with reference to FIGS. 2, 5, and 6.

As shown in FIG. 2, the transformer chip 60 has a thickness TC3 that is greater than a thickness TC1 of the first chip 40 and a thickness TC2 of the second chip 50. The thickness TC3 of the transformer chip 60 is the distance between the chip main surface 60s and the chip back surface 60r of the transformer chip 60 in the z-direction. The thickness TC1 of the first chip 40 is the distance between the chip main surface 40s and the chip back surface 40r of the first chip 40 in the z-direction. The thickness TC2 of the second chip 50 is the distance between the chip main surface 50s and the chip back surface 50r of the second chip 50 in the z-direction.

The third bonding material 103 has a thickness TS3 that is equal to a thickness TS1 of the first bonding material 101 and a thickness TS2 of the second bonding material 102. In the present embodiment, the thickness TS3 of the third bonding material 103 corresponds to a “thickness of the bonding material.” The thickness TS3 of the third bonding material 103 is the distance between the secondary die pad 80 and the chip back surface 60r of the transformer chip 60 in the z-direction.

The thickness TS1 of the first bonding material 101 is the distance between the primary die pad 70 and the chip back surface 40r of the first chip 40 in the z-direction. The thickness TS2 of the second bonding material 102 is the distance between the secondary die pad 80 and the chip back surface 50r of the second chip 50 in the z-direction. When the difference between the thickness TS3 of the third bonding material 103 and the thickness TS1 of the first bonding material 101 is, for example, within 20% of the thickness TS3 of the third bonding material 103, it is considered that the thickness TS3 of the third bonding material 103 is equal to the thickness TS1 of the first bonding material 101. When the difference between the thickness TS3 of the third bonding material 103 and the thickness TS2 of the second bonding material 102 is, for example, within 20% of the thickness TS3 of the third bonding material 103, it is considered that the thickness TS3 of the third bonding material 103 is equal to the thickness TS2 of the second bonding material 102.

As described above, the chip main surface 60s of the transformer chip 60 is greater in height-wise position than the chip main surface 40s of the first chip 40 and the chip main surface 50s of the second chip 50.

As shown in FIG. 2, the first substrate 43 of the first chip 40 has a thickness that is equal to the thickness TB of the substrate 63 (refer to FIG. 5). The second substrate 53 of the second chip 50 has a thickness that is equal to the thickness TB of the substrate 63.

As shown in FIGS. 5 and 6, in the present embodiment, the thickness TB of the substrate 63 is smaller than a thickness TT of the element insulation layers 64. In the present embodiment, the thickness TB of the substrate 63 is greater than a distance D1 between the first coil 31A (31B) and the second coil 32A (32B) in the z-direction.

The distance D1 between the first coil 31A (31B) and the second coil 32A (32B) in the z-direction is greater than a distance D2 between the second coil 32A (32B) and the back surface 64r of the element insulation layers 64 in the z-direction. The distance D2 also refers to the distance between the second coil 32A (32B) and the substrate front surface 63s of the substrate 63 in the z-direction.

The distance D1 between the first coil 31A (31B) and the second coil 32A (32B) in the z-direction is greater than a distance D3 between the first coil 31A (31B) and the front surface 64s of the element insulation layers 64 in the z-direction.

The first coil 33A (33B) and the first coil 31A (31B) are located at the same position in the z-direction. The second coil 34A (34B) and the second coil 32A (32B) are located at the same position in the z-direction. Therefore, the distance between the first coil 33A (33B) and the second coil 34A (34B) in the z-direction is equal to the distance D1. Also, the distance between the second coil 34A (34B) and the back surface 64r of the element insulation layers 64 in the z-direction is equal to the distance D2. The distance between the first coil 33A (33B) and the front surface 64s of the element insulation layers 64 in the z-direction is equal to the distance D3.

The substrate insulation layer 63B of the transformer chip 60 has a thickness TZ that is greater than a thickness TA of a single element insulation layer 64 and is smaller than the thickness TT of the element insulation layers 64. The thickness TZ of the substrate insulation layer 63B is the distance between the front surface 63Bs and the back surface 63Br of the substrate insulation layer 63B in the z-direction. The thickness TA of a single element insulation layer 64 is the distance between the back surface of the first insulation film 64A and the front surface of the second insulation film 64B of the single element insulation layer 64 in the z-direction. The thickness TT of the element insulation layers 64 is the distance between the front surface 64s and the back surface 64r of the element insulation layers 64 in the z-direction. The thickness TA of a single element insulation layer 64 is equal to the thickness of each of the coils 31A to 34A and 31B to 34B. Therefore, the thickness TZ of the substrate insulation layer 63B is greater than the thickness of each of the coils 31A to 34A and 31B to 34B.

The thickness TZ of the substrate insulation layer 63B is greater than or equal to the distance D2 between the second coil 32A (32B) and the back surface 64r of the element insulation layers 64 in the z-direction. In an example, the thickness TZ of the substrate insulation layer 63B is in a range of 2 μm to 4 μm. The distance D2 between the second coil 32A (32B) and the back surface 64r of the element insulation layers 64 in the z-direction is in a range of 0.5 μm to 2 μm. In the present embodiment, the thickness TZ of the substrate insulation layer 63B is greater than the distance D2 between the second coil 32A (32B) and the back surface 64r of the element insulation layers 64 in the z-direction. The thickness TZ of the substrate insulation layer 63B is greater than or equal to the distance D3 between the first coil 31A (31B) and the front surface 64s of the element insulation layers 64 in the z-direction. The thickness TZ of the substrate insulation layer 63B is smaller than the distance D1 between the first coil 31A (31B) and the second coil 32A (32B) in the z-direction.

The thickness TZ of the substrate insulation layer 63B is smaller than a thickness T4 of the body 63A. The thickness T4 of the body 63A is the distance between the front surface 63As and the back surface 63Ar of the body 63A in the z-direction. The thickness TZ of the substrate insulation layer 63B is smaller than ½ of the thickness T4 of the body 63A. The thickness TZ of the substrate insulation layer 63B is smaller than ⅓ of the thickness T4 of the body 63A.

In the body 63A, a thickness T1 of the first semiconductor layer 63AA is greater than a thickness T2 of the second semiconductor layer 63AB and a thickness T3 of the oxide film 63AC. The thickness T2 of the second semiconductor layer 63AB is greater than the thickness T3 of the oxide film 63AC. The first semiconductor layer 63AA includes a front surface in contact with the substrate insulation layer 63B and a back surface in contact with the oxide film 63AC. The thickness T1 of the first semiconductor layer 63AA is the distance between the front surface and the back surface of the first semiconductor layer 63AA in the z-direction. The second semiconductor layer 63AB includes a front surface in contact with the oxide film 63AC and a back surface opposite to the front surface in the z-direction. The thickness T2 of the second semiconductor layer 63AB is the distance between the front surface and the back surface of the second semiconductor layer 63AB in the z-direction. The oxide film 63AC includes a front surface in contact with the first semiconductor layer 63AA and a back surface in contact with the second semiconductor layer 63AB. The thickness T3 of the oxide film 63AC is the distance between the front surface and the back surface of the oxide film 63AC in the z-direction.

The thickness TZ of the substrate insulation layer 63B is smaller than the thickness T1 of the first semiconductor layer 63AA. The thickness TZ of the substrate insulation layer 63B is smaller than the thickness T2 of the second semiconductor layer 63AB. The thickness TZ of the substrate insulation layer 63B is equal to the thickness T3 of the oxide film 63AC. When the difference between the thickness TZ of the substrate insulation layer 63B and the thickness T3 of the oxide film 63AC is, for example, within 20% of the thickness TZ of the substrate insulation layer 63B, it is considered that the thickness TZ of the substrate insulation layer 63B is equal to the thickness T3 of the oxide film 63AC.

The thickness TZ of the substrate insulation layer 63B is greater than or equal to a thickness TC of the protection film 65. The thickness TZ of the substrate insulation layer 63B is smaller than or equal to a thickness TD of the passivation film 66. The thickness of the protection film 65 is the distance between a front surface and a back surface of the protection film 65 in the z-direction. The front surface of the protection film 65 is in contact with the passivation film 66. The back surface of the protection film 65 is in contact with the element insulation layer 64. The thickness of the passivation film 66 is the distance between a front surface and a back surface of the passivation film 66 in the z-direction. The front surface of the passivation film 66 includes the chip main surface 60s of the transformer chip 60. The back surface of the passivation film 66 is in contact with the protection film 65.

In the present embodiment, the thickness TZ of the substrate insulation layer 63B is smaller than the thickness TS3 of the third bonding material 103. The thickness TS3 of the third bonding material 103 is less than 10 μm (approximately 5 μm). Since the thickness TS3 of the third bonding material 103 is equal to the thickness TS1 of the first bonding material 101 and the thickness TS2 of the second bonding material 102, the thickness TZ of the substrate insulation layer 63B is smaller than the thickness TS1 of the first bonding material 101, and the thickness TZ of the substrate insulation layer 63B is smaller than the thickness TS2 of the second bonding material 102.

### Manufacturing Method

An example of a method for manufacturing the signal transmission device 10 will now be described briefly.

The method for manufacturing the signal transmission device 10 includes a preparing step of preparing the transformer chip 60, the first chip 40, the second chip 50, the primary die pad 70, and the secondary die pad 80.

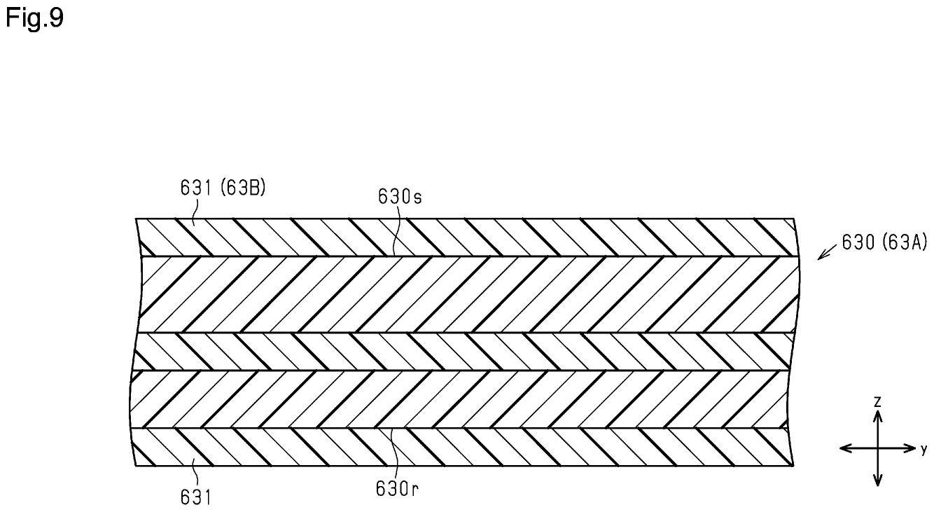

The transformer chip 60 is manufactured, for example, as follows. As shown in FIG. 9, an SOI wafer 630 is prepared as a semiconductor wafer. The SOI wafer 630 includes the body 63A of the substrate 63. The SOI wafer 630 includes a wafer front surface 630s and a wafer back surface 630r that face opposite directions in a thickness-wise direction of the SOI wafer 630. Insulation films 631 are formed on outer surfaces of the SOI wafer 630. The insulation films 631 are formed by, for example, a low pressure CVD process in which an organic TEOS gas reacts with an oxygen-based gas. The insulation film 631 formed on the wafer front surface 630s of the SOI wafer 630 forms the substrate insulation layer 63B. As described above, the method for manufacturing the transformer chip 60 includes a substrate insulation layer forming step. FIG. 9 shows a step of forming a substrate insulation layer (insulation film 631) on opposite surfaces of the semiconductor wafer (the SOI wafer 630) in the substrate insulation layer forming step. As described above, even when the insulation film 631 is formed on the opposite surfaces of the semiconductor wafer (the SOI wafer 630) and thus is increased in thickness, warping of the semiconductor wafer (the SOI wafer 630) is limited.

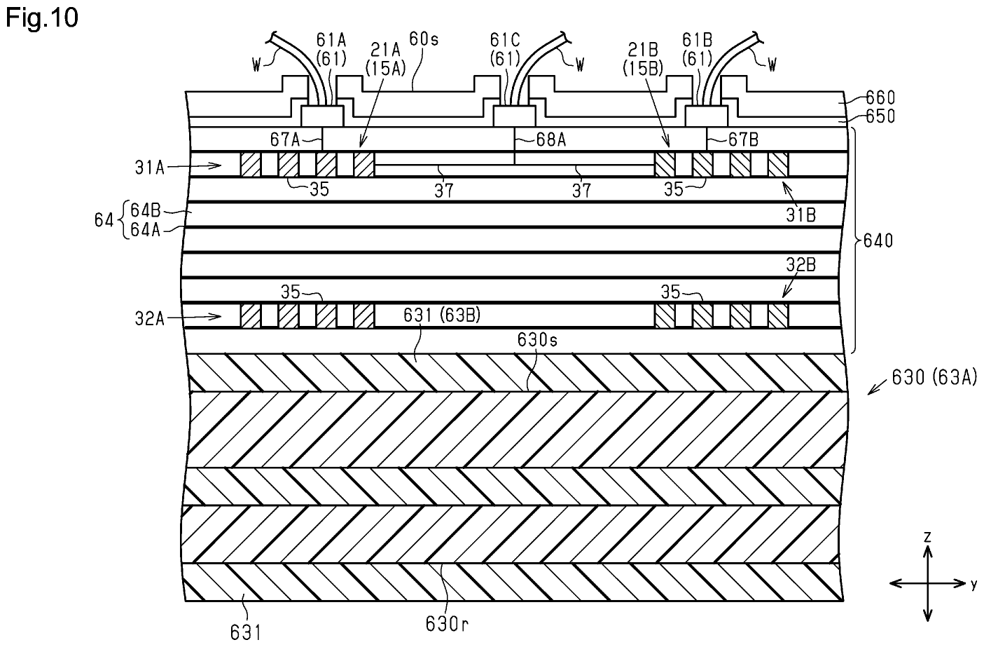

Subsequently, as shown in FIG. 10, an element insulation layer 640, the first transformers 21A and 21B, and the second transformers 22A and 22B are formed on the insulation film 631 that is formed on the wafer front surface 630s of the SOI wafer 630. The element insulation layer 640 forms the element insulation layers 64 of the transformer chip 60 and is formed, for example, on the entirety of the insulation film 631 that is formed on the wafer front surface 630s of the SOI wafer 630. In an example, multiple element insulation layers 640 are stacked on the insulation film 631. Second openings are formed in one of the element insulation layers 640 so that the second coils 32A, 32B, 34A, and 34B of the transformers 21A, 21B, 22A, and 22B are arranged in the element insulation layer 640. The element insulation layers 640 are formed by, for example, plasma CVD. The element insulation layers 640, which are formed by plasma CVD, differ in film properties from the insulation film 631, which is formed by low pressure CVD. The second openings are provided with a second conductive material to form the second coils 32A, 32B, 34A, and 34B. In the present embodiment, Cu is used as the second conductive material. Alternatively, for example, Al may be used as the second conductive material. Subsequently, element insulation layers 640 are again stacked to cover the second coils 32A, 32B, 34A, and 34B. First openings are formed in one of the element insulation layers 640 so that the first coils 31A, 31B, 33A, and 33B are arranged in the element insulation layer 640. The first openings are provided with a first conductive material to form the first coils 31A, 31B, 33A, and 33B. In the present embodiment, Cu is used as the first conductive material. Subsequently, an element insulation layer 640 is stacked to cover the first coils 31A, 31B, 33A, and 33B.

As described above, the method for manufacturing the transformer chip 60 includes a step of stacking the element insulation layers 640 including two isolation elements (transformers 21A, 21B, 22A, 22B) on the front surface of the substrate insulation layer (the insulation film 631).

The first electrode pads 61 and the second electrode pads 62 are formed on the front surface of the element insulation layers 640. Subsequently, a protection film 650 and a passivation film 660 are sequentially stacked on the front surface of the element insulation layers 640. The protection film 650 forms the protection film 65 of the transformer chip 60 and is formed, for example, on the entirety of the front surface of the element insulation layers 640. The passivation film 660 forms the passivation film 66 of the transformer chip 60 and is formed, for example, on the entirety of a front surface of the protection film 650. In this step, the protection film 650 and the passivation film 660 are formed when each of the first electrode pads 61 and the second electrode pads 62 is partially covered by, for example, a mask. Then, the mask is removed. As a result, the electrode pads 61 and 62 are exposed.

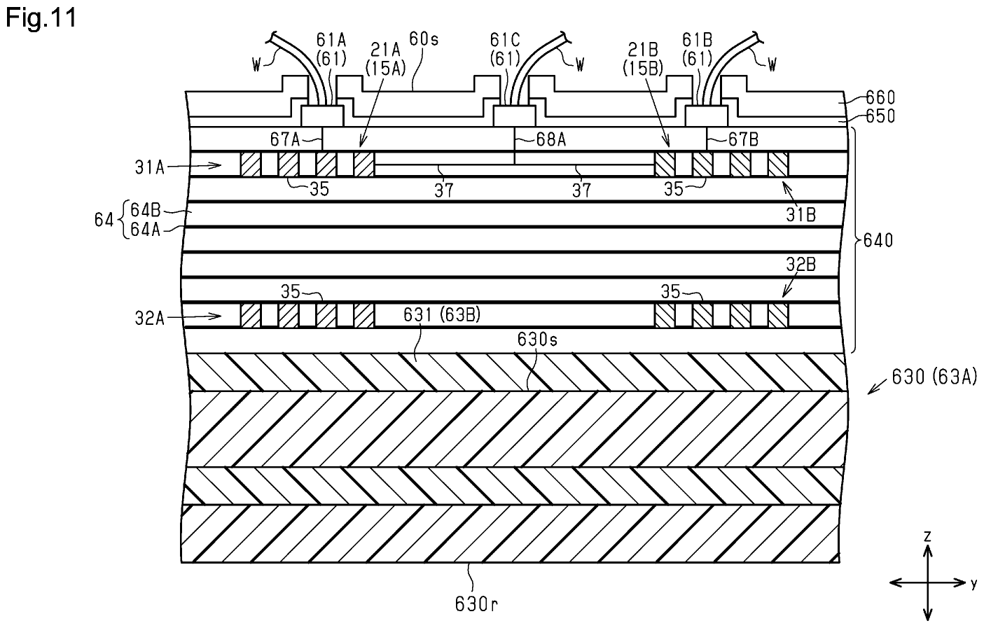

As shown in FIG. 11, the SOI wafer 630 is ground so that the thickness of the SOI wafer 630 falls within a predetermined thickness. The insulation film 631 that is formed on the wafer back surface 630r of the SOI wafer 630 is ground. Consequently, the insulation film 631 is removed from the wafer back surface 630r of the SOI wafer 630. In this step, the wafer back surface 630r of the SOI wafer 630 may also be ground. Consequently, the total of the thickness of the SOI wafer 630 and the thickness of the insulation film 631 equals the thickness TB of the substrate 63. FIG. 11 shows a step of removing the substrate insulation layer (the insulation film 631) from the back surface (the wafer back surface 630r) of the semiconductor wafer (the SOI wafer 630) in the substrate insulation layer forming step. In the present embodiment, the step of removing the substrate insulation layer (the insulation film 631) from the back surface (the wafer back surface 630r) of the semiconductor wafer (the SOI wafer 630) is performed after the element insulation layers 640 are stacked.

The SOI wafer 630 including the element insulation layers 640, the protection film 650, and the passivation film 660 is cut in the z-direction to singulate the transformer chip 60. As a result, the substrate 63, the element insulation layers 64, the protection film 65, and the passivation film 66 are formed. The steps described above manufacture the transformer chip 60.

In the substrate insulation layer forming step, the process of forming the substrate insulation layer may be changed in any manner. In an example, the substrate insulation layer (the insulation film 631) may be formed by thermally oxidizing the semiconductor wafer (the SOI wafer 630). Thermal oxidation also forms the substrate insulation layer (the insulation film 631) on the opposite surfaces of the semiconductor wafer (the SOI wafer 630). Thus, warping of the semiconductor wafer (the SOI wafer 630) is limited. In this case, the insulation film 631 also differs in film properties from the element insulation layer 640.

The step of removing the substrate insulation layer (the insulation film 631) from the back surface (the wafer back surface 630r) of the semiconductor wafer (the SOI wafer 630) may be at any time during the substrate insulation layer forming step.

The method for manufacturing the signal transmission device 10 includes a step of mounting the first chip 40 on the primary die pad 70 and mounting the transformer chip 60 and the second chip 50 on the secondary die pad 80. In an example, the first chip 40 is mounted on the primary die pad 70 by die bonding. The second chip 50 and the transformer chip 60 are mounted on the secondary die pad 80 by die bonding. More specifically, the first bonding material 101 is applied to the primary die pad 70. The second bonding material 102 is applied to a portion of the secondary die pad 80 on which the second chip 50 will be mounted. The third bonding material 103 is applied to a portion of the secondary die pad 80 on which the transformer chip 60 will be mounted. Subsequently, the first chip 40 is mounted on the first bonding material 101. The second chip 50 is mounted on the second bonding material 102. The transformer chip 60 is mounted on the third bonding material 103. The bonding materials 101 to 103 are solidified. The first bonding material 101 and the second bonding material 102 include a conductive bonding material. The third bonding material 103 includes an insulative bonding material. Hence, the first bonding material 101 and the second bonding material 102 are solidified in a manner that differs from that of the third bonding material 103. In an example, when the first bonding material 101 and the second bonding material 102 include solder, the first bonding material 101 and the second bonding material 102 are heated and cooled so that the first bonding material 101 and the second bonding material 102 are solidified. When the third bonding material 103 is formed from a material including an epoxy resin, the epoxy resin is mixed with, for example, a curing agent so that the third bonding material 103 is solidified.

In this step, for example, after the first chip 40 is mounted on the primary die pad 70 and the second chip 50 is mounted on the secondary die pad 80, the transformer chip 60 may be mounted on the secondary die pad 80. In an example, the first bonding material 101 is applied to the primary die pad 70, and the second bonding material 102 is applied to a portion of the secondary die pad 80 on which the second chip 50 will be mounted. The first chip 40 is mounted on the first bonding material 101. The second chip 50 is mounted on the second bonding material 102. The first bonding material 101 and the second bonding material 102 are solidified. Then, the third bonding material 103 is applied to a portion of the secondary die pad 80 on which the transformer chip 60 will be mounted. The transformer chip 60 is mounted on the third bonding material 103. The third bonding material 103 is solidified.

The method for manufacturing the signal transmission device 10 includes a step for forming a wire W. The wire W is formed by a wire bonder. More specifically, wires W are formed to separately connect the first electrode pads 41 of the first chip 40 to the primary leads. Wires W are formed to separately connect the second electrode pads 52 of the second chip 50 to the secondary leads. Wires W are formed to separately connect the second electrode pads 42 of the first chip 40 to the first electrode pads 61 of the transformer chip 60. Wires W are formed to separately connect the second electrode pads 62 of the transformer chip 60 to the first electrode pads 51 of the second chip 50.

The method for manufacturing the signal transmission device 10 includes a step of forming the encapsulation resin 90. The encapsulation resin 90 is formed by, for example, transfer molding. As a result, the chips 40, 50, and 60, the die pads 70 and 80, and the wires W are encapsulated. The primary leads and the secondary leads each include a portion projecting from a side surface of the encapsulation resin 90.

In the method for manufacturing the signal transmission device 10, the portions of the primary leads projecting from the encapsulation resin 90 and the portions of the secondary leads projecting from the encapsulation resin 90 are each bent to form external terminals of the signal transmission device 10. The steps described above manufacture the signal transmission device 10. The method for manufacturing a single signal transmission device 10 is described above. However, there is no limit to such a configuration. Multiple signal transmission devices 10 may be manufactured simultaneously.

### Operation

In order to improve the dielectric strength of the transformer chip, for example, the distance D1 between the first coil 31A (31B) and the second coil 32A (32B) of the transformer 21A (21B) in the z-direction may be increased. This structure increases the thickness TT of the element insulation layers 64, which are arranged on the substrate 63 of the transformer chip 60. When the thickness TT of the element insulation layers 64 is increased, a semiconductor wafer forming the substrate 63 may be warped during the manufacturing of the transformer chip 60. This imposes limitations on the increasing of the thickness TT of the element insulation layers 64.

In this regard, in the present embodiment, the transformer chip 60 includes the first transformer 21A (21B) and the second transformer 22A (22B) that are connected in series. With this structure, the dielectric strength of the transformer chip 60 is improved without overly increasing the distance D1 between the first coil 31A (31B) and the second coil 32A (32B) of the first transformer 21A (21B) in the z-direction and the distance D1 between the first coil 33A (33B) and the second coil 34A (34B) of the second transformer 22A (22B) in the z-direction.

In the transformer chip 60 described above, the first transformer 21A (21B) is electrically connected to the primary circuit 13 by the wires W, and the second transformer 22A (22B) is electrically connected to the secondary circuit 14 by the wires W. When the transformer chip 60 is mounted on the conductive secondary die pad 80, it is necessary to electrically insulate the transformers 21A (21B) and 22A (22B) from the secondary die pad 80.

The insulation voltage of the transformers 21A (21B) and 22A (22B) with the secondary die pad 80 is mainly set in accordance with the distance between the secondary die pad 80 and each of the second coils 32A (32B) and 34A (34B) of the transformers 21A (21B) and 22A (22B) in the z-direction. More specifically, as the distance between the secondary die pad 80 and each of the second coils 32A (32B) and 34A (34B) increases in the z-direction, the insulation voltage of the transformers 21A (21B) and 22A (22B) with the secondary die pad 80 increases.

The distance between the secondary die pad 80 and each of the second coils 32A (32B) and 34A (34B) of the transformers 21A (21B) and 22A (22B) in the z-direction is determined by the distance between the body 63A of the substrate 63 and each of the second coils 32A (32B) and 34A (34B), the thickness of the substrate 63, and the thickness TS3 of the bonding material 103.

The number of element insulation layers 64 stacked on a location close to the substrate 63 under the second coils 32A (32B) and 34A (34B) may be increased in order to, for example, increase the distance between the body 63A of the substrate 63 and each of the second coils 32A (32B) and 34A (34B). That is, the distance D2 between the back surface 64r of the element insulation layers 64 and each of the second coils 32A (32B) and 34A (34B) may be increased. However, the increase in the distance D2 will increase the thickness TT of the element insulation layers 64.

In this regard, in the present embodiment, the substrate 63 of the transformer chip 60 includes the substrate insulation layer 63B formed on the front surface 63As of the body 63A. Thus, both the element insulation layers 64 and the substrate insulation layer 63B are arranged between the body 63A of the substrate 63 and the second coils 32A (32B) and 34A (34B). Therefore, the number of element insulation layers 64 stacked on a location close to the substrate 63 under the second coils 32A (32B) and 34A (34B) does not have to be increased in order to increase the distance between the body 63A of the substrate 63 and each of the second coils 32A (32B) and 34A (34B). That is, the distance between the body 63A and each of the second coils 32A (32B) and 34A (34B) in the z-direction is increased without increasing the distance D2 between the back surface 64r of the element insulation layers 64 and the second coils 32A (32B) and 34A (34B). This increases a distance D4 between the secondary die pad 80 and each of the second coils 32A (32B) and 34A (34B) in the z-direction.

### Advantages

The signal transmission device 10 of the present embodiment has the following advantages.

(1-1) The signal transmission device 10 includes the first chip 40 including the primary circuit 13, the primary die pad 70 on which the first chip 40 is mounted, the transformer chip 60, the second chip 50 including the secondary circuit 14 configured to receive a signal from the primary circuit 13 through the transformer chip 60, and the secondary die pad 80 on which the second chip 50 is mounted. The transformer chip 60 includes the substrate 63, the element insulation layers 64 including the front surface 64s and the back surface 64r, which is opposite to the front surface 64s and located closer to the substrate 63 than the front surface 64s is, and the first transformer 21A (21B) and the second transformer 22A (22B) arranged in the element insulation layers 64 and configured to transmit a signal. The first transformer 21A (21B) includes the first coil 31A (31B), which is located closer to the front surface 64s than to the back surface 64r in the element insulation layers 64, and the second coil 32A (32B), which is located closer to the back surface 64r than to the front surface 64s in the element insulation layers 64. The second transformer 22A (22B) includes the first coil 33A (33B), which is located closer to the front surface 64s than to the back surface 64r in the element insulation layers 64, and the second coil 34A (34B), which is located closer to the back surface 64r than to the front surface 64s in the element insulation layers 64. The second coil 32A (32B) is electrically connected to the second coil 34A (34B). The substrate 63 includes the body 63A and the substrate insulation layer 63B formed on the front surface 63As of the body 63A. The element insulation layers 64 are stacked on the front surface 63Bs of the substrate insulation layer 63B.

In this structure, both the element insulation layers 64 and the substrate insulation layer 63B are arranged between the body 63A and the second coils 32A (32B) and 34A (34B). Therefore, the number of element insulation layers 64 stacked on a location close to the substrate 63 under the second coils 32A (32B) and 34A (34B) does not have to be increased in order to increase the distance between the body 63A of the substrate 63 and each of the second coils 32A (32B) and 34A (34B). That is, the distance between the body 63A and each of the second coils 32A (32B) and 34A (34B) in the z-direction is increased without increasing the distance D2 between the back surface 64r of the element insulation layers 64 and each of the second coils 32A (32B) and 34A (34B). Accordingly, the distance D4 between the secondary die pad 80 and each of the second coils 32A (32B) and 34A (34B) in the z-direction is increased without increasing the distance D2 between the back surface 64r of the element insulation layers 64 and each of the second coils 32A (32B) and 34A (34B). This improves the dielectric strength between the secondary die pad 80 and each of the second coils 32A (32B) and 34A (34B) in the z-direction. Thus, the dielectric strength of the signal transmission device 10 is improved.

(1-2) The thickness TZ of the substrate insulation layer 63B is smaller than a thickness T4 of the body 63A.

In this structure, the substrate insulation layer 63B is readily formed as compared to a structure in which the thickness TZ of the substrate insulation layer 63B is greater than or equal to the thickness T4 of the body 63A. That is, the substrate insulation layer 63B is formed in a shorter amount of time. This reduces the manufacturing cost of the transformer chip 60.

(1-3) The body 63A is an SOI substrate that includes the first semiconductor layer 63AA, the oxide film 63AC, and the second semiconductor layer 63AB. The first semiconductor layer 63AA is in contact with the element insulation layers 64. The oxide film 63AC and the element insulation layers 64 are located at opposite sides of the first semiconductor layer 63AA. The second semiconductor layer 63AB and the first semiconductor layer 63AA are located at opposite sides of the oxide film 63AC.

This structure improves the dielectric strength between the secondary die pad 80 and each of the second coils 32A (32B) and 34A (34B) in the z-direction as compared to a structure in which the body 63A is formed of a single-layer semiconductor substrate. Thus, the dielectric strength of the signal transmission device 10 is improved.

(1-4) The thickness T1 of the first semiconductor layer 63AA is greater than the thickness T3 of the oxide film 63AC and the thickness T2 of the second semiconductor layer 63AB. The thickness TZ of the substrate insulation layer 63B is smaller than the thickness T1 of the first semiconductor layer 63AA.

In this structure, the substrate insulation layer 63B is readily formed as compared to a structure in which the thickness TZ of the substrate insulation layer 63B is greater than or equal to the thickness T1 of the first semiconductor layer 63AA. That is, the substrate insulation layer 63B is formed in a shorter amount of time. This reduces the manufacturing cost of the transformer chip 60.

(1-5) The thickness T2 of the second semiconductor layer 63AB is greater than the thickness T3 of the oxide film 63AC. The thickness TZ of the substrate insulation layer 63B is smaller than the thickness T2 of the second semiconductor layer 63AB.

In this structure, the substrate insulation layer 63B is readily formed as compared to a structure in which the thickness TZ of the substrate insulation layer 63B is greater than or equal to the thickness T2 of the second semiconductor layer 63AB. That is, the substrate insulation layer 63B is formed in a shorter amount of time. This reduces the manufacturing cost of the transformer chip 60.

(1-6) The thickness TZ of the substrate insulation layer 63B is greater than or equal to the distance D2 between the back surface 64r of the element insulation layers 64 and each of the second coils 32A (32B) and 34A (34B) in the z-direction. The substrate insulation layer 63B includes a TEOS oxide film.

In this structure, the distance between the secondary die pad 80 and each of the second coils 32A (32B) and 34A (34B) in the z-direction is increased without increasing the distance D2. The TEOS oxide film is formed on opposite surfaces of the semiconductor wafer (the SOI wafer 630) including the body 63A in the process of manufacturing the transformer chip 60. This limits increases in the thickness TT of the element insulation layers 64 and limits warping of a semiconductor wafer (SOI wafer 630) forming the substrate 63 during the manufacturing of the transformer chip 60.

(1-7) The thickness TZ of the substrate insulation layer 63B is smaller than the thickness TS3 of the third bonding material 103. In this structure, the substrate insulation layer 63B is readily formed as compared to a structure in which the thickness TZ of the substrate insulation layer 63B is greater than or equal to the thickness TS3 of the third bonding material 103. That is, the substrate insulation layer 63B is formed in a shorter amount of time. This reduces the manufacturing cost of the transformer chip 60.

(1-8) If the third bonding material, which bonds the transformer chip 60 to the secondary die pad 80, is conductive, the third bonding material is electrically connected to the secondary die pad 80. Hence, the third bonding material needs to be electrically insulated from the second coils 32A (32B) and 34A (34B).

In this regard, in the present embodiment, the third bonding material 103 is electrically insulative. Thus, the third bonding material 103 is electrically disconnected from the secondary die pad 80. Therefore, in order to improve the dielectric strength of the transformer chip 60, the second coils 32A (32B) and 34A (34B) need to be electrically insulated from the secondary die pad 80 without the need to electrically insulate the second coils 32A (32B) and 34A (34B) from the third bonding material 103. Thus, the dielectric strength of the transformer chip 60 is readily improved.

(1-9) The thickness TZ of the substrate insulation layer 63B is smaller than the thickness TS1 of the first bonding material 101.

In this structure, the substrate insulation layer 63B is readily formed as compared to a structure in which the thickness TZ of the substrate insulation layer 63B is greater than or equal to the thickness TS1 of the first bonding material 101. That is, the substrate insulation layer 63B is formed in a shorter amount of time. This reduces the manufacturing cost of the transformer chip 60.

Also, the thickness TZ of the substrate insulation layer 63B is smaller than the thickness TS2 of the second bonding material 102.

In this structure, the substrate insulation layer 63B is readily formed as compared to a structure in which the thickness TZ of the substrate insulation layer 63B is greater than or equal to the thickness TS2 of the second bonding material 102. That is, the substrate insulation layer 63B is formed in a shorter amount of time. This reduces the manufacturing cost of the transformer chip 60.

(1-10) The thickness TZ of the substrate insulation layer 63B is smaller than the distance D1 between the first coil 31A (31B) and the second coil 32A (32B) in the z-direction. In other words, the distance D1 between the first coil 31A (31B) and the second coil 32A (32B) is greater than the thickness TZ of the substrate insulation layer 63B. The thickness TZ of the substrate insulation layer 63B is smaller than the distance D1 between the first coil 33A (33B) and the second coil 34A (34B) in the z-direction. In other words, the distance D1 between the first coil 33A (33B) and the second coil 34A (34B) in the z-direction is greater than the thickness TZ of the substrate insulation layer 63B.

In this structure, the distance D1 between the first coil 31A (31B) and the second coil 32A (32B) and the distance D1 between the first coil 33A (33B) and the second coil 34A (34B) may be increased to improve the dielectric strength of the transformer chip 60.

(1-11) The distance D1 between the first coil 31A (31B) and the second coil 32A (32B) in the z-direction is equal to the distance D1 between the first coil 33A (33B) and the second coil 34A (34B) in the z-direction.

When the insulation voltage of a first transformer differs from the insulation voltage of a second transformer, the total insulation voltage of the first transformer and the second transformer that are connected in series may be lower than the sum of the insulation voltage of the first transformer and the insulation voltage of the second transformer.

In this regard, in the present embodiment, the insulation voltage of the first transformer 21A (21B) is equal to the insulation voltage of the second transformer 22A (22B). Therefore, the total insulation voltage of the first transformer 21A (21B) and the second transformer 22A (22B) that are connected in series is substantially equal to the sum of the insulation voltage of the first transformer 21A (21B) and the insulation voltage of the second transformer 22A (22B). This improves the insulation voltage of the transformer chip 60 as compared to when the insulation voltage of the first transformer 21A (21B) differs from the insulation voltage of the second transformer 22A (22B).

(1-12) The second coil 32A (32B) and the second coil 34A (34B) are located at the same position in the z-direction.

In this structure, the second coil 32A (32B) and the second coil 34A (34B) are connected to each other and are aligned with each other in the z-direction. This allows the second coil 32A (32B) and the second coil 34A (34B), connected to each other, to be readily formed in the element insulation layers 64.

(1-13) The first coil 31A (31B) and the first coil 33A (33B) are separated from each other in the x-direction. The second coil 32A (32B) and the second coil 34A (34B) are separated from each other in the x-direction. The first coil 31A (33A) and the first coil 31B (33B) are separated from each other in the y-direction. The second coil 32A (34A) and the second coil 32B (34B) are separated from each other in the y-direction. The first coil 31A (31B) electrically connected to the primary circuit 13 is located close to the first chip 40 in the x-direction. The first coil 33A (33B) electrically connected to the secondary circuit 14 is located close to the second chip 50 in the x-direction.

In this structure, the first chip 40 including the primary circuit 13 is readily connected to the first coil 31A (31B) by the wire W. Also, the second chip 50 including the secondary circuit 14 is readily connected to the first coil 33A (33B) by the wire W.

(1-14) As viewed in the z-direction, the first electrode pad 61A is located inward from the coil portion 35 of the first coil 31A, and the first electrode pad 61B is located inward from the coil portion 35 of the first coil 31B. As viewed in the y-direction, the first electrode pad 61C overlaps the first coil 31A (31B) in the x-direction. As viewed in the z-direction, the second electrode pad 62A is located inward from the coil portion 35 of the first coil 33A, and the second electrode pad 62B is located inward from the coil portion 35 of the first coil 33B. As viewed in the y-direction, the second electrode pad 62C overlaps the first coil 33A (33B) in the x-direction.

This structure allows for reduction in the size of the transformer chip 60 in the x-direction as compared to a structure in which, for example, as viewed in the z-direction, the first electrode pads 61A to 61C are located closer to the first chip 40 than the first coil 31A (31B) and the second electrode pads 62A to 62C are located closer to the second chip 50 than the first coil 33A (33B).

(1-15) The transformer chip 60 includes the substrate 63, the element insulation layers 64 including the front surface 64s and the back surface 64r, which is opposite to the front surface 64s and located closer to the substrate 63 than the front surface 64s is, and the first transformer 21A (21B) and the second transformer 22A (22B) arranged in the element insulation layers 64 and configured to transmit a signal. The first transformer 21A (21B) includes the first coil 31A (31B), which is located closer to the front surface 64s than to the back surface 64r in the element insulation layers 64, and the second coil 32A (32B), which is located closer to the back surface 64r than to the front surface 64s in the element insulation layers 64. The second transformer 22A (22B) includes the first coil 33A (33B), which is located closer to the front surface 64s than to the back surface 64r in the element insulation layers 64, and the second coil 34A (34B), which is located closer to the back surface 64r than to the front surface 64s in the element insulation layers 64. The second coil 32A (32B) is electrically connected to the second coil 34A (34B). The substrate 63 includes the body 63A and the substrate insulation layer 63B formed on the front surface 63As of the body 63A. The element insulation layers 64 are stacked on the front surface 63Bs of the substrate insulation layer 63B.

In this structure, the substrate insulation layer 63B is arranged between the body 63A and the second coils 32A (32B) and 34A (34B). Thus, the distance between the body 63A and each of the second coils 32A (32B) and 34A (34B) in the z-direction is increased without increasing the thickness TT of the element insulation layers 64. Accordingly, the distance between the chip back surface 60r of the transformer chip 60 and each of the second coils 32A (32B) and 34A (34B) in the z-direction is increased without increasing the thickness TT of the element insulation layers 64. When the transformer chip 60 is mounted on a metal frame, the distance between the frame and each of the second coils 32A (32B) and 34A (34B) in the z-direction is increased. This improves the dielectric strength of the transformer chip 60.

(1-16) The method for manufacturing the transformer chip 60 includes the substrate insulation layer forming step, which forms the substrate insulation layer (the insulation film 631) on the wafer front surface 630s of the semiconductor wafer (the SOI wafer 630) including the body 63A, and the step of stacking the element insulation layers 640 including the transformers 21A, 21B, 22A, and 22B on the front surface of the insulation film 631. The substrate insulation layer forming step includes a step of forming the insulation films 631 on both the wafer front surface 630s and the wafer back surface 630r of the SOI wafer 630 and a step of removing the insulation film 631 from the wafer back surface 630r of the SOI wafer 630.

In this structure, since the insulation films 631 are formed on both the wafer front surface 630s and the wafer back surface 630r of the SOI wafer 630, warping of the SOI wafer 630 is limited even when the insulation film 631 is increased in thickness. In addition, the insulation film 631 limits increases in the thickness of the element insulation layers 640, thereby limiting warping of the SOI wafer 630 even when the element insulation layers 640 are stacked.

### Second Embodiment

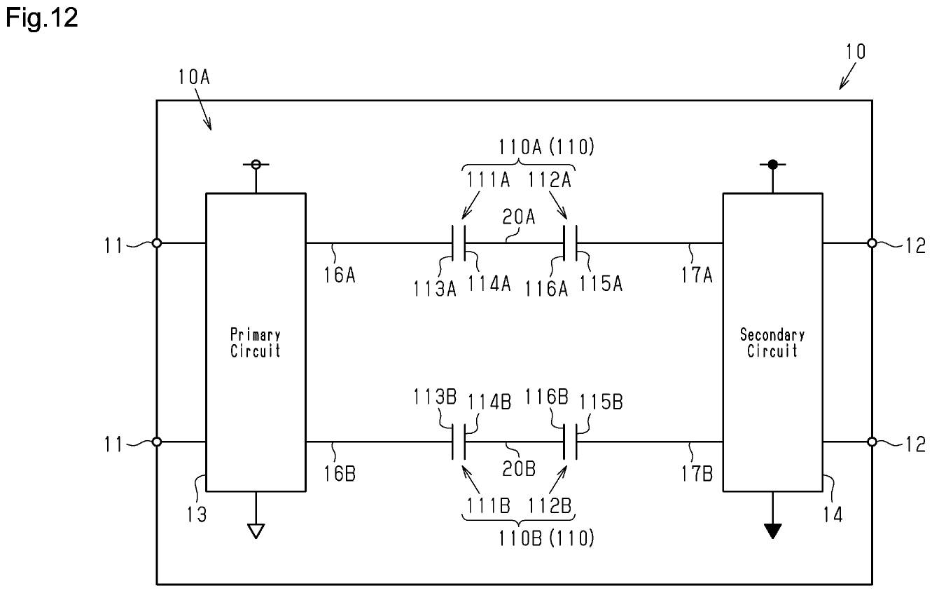

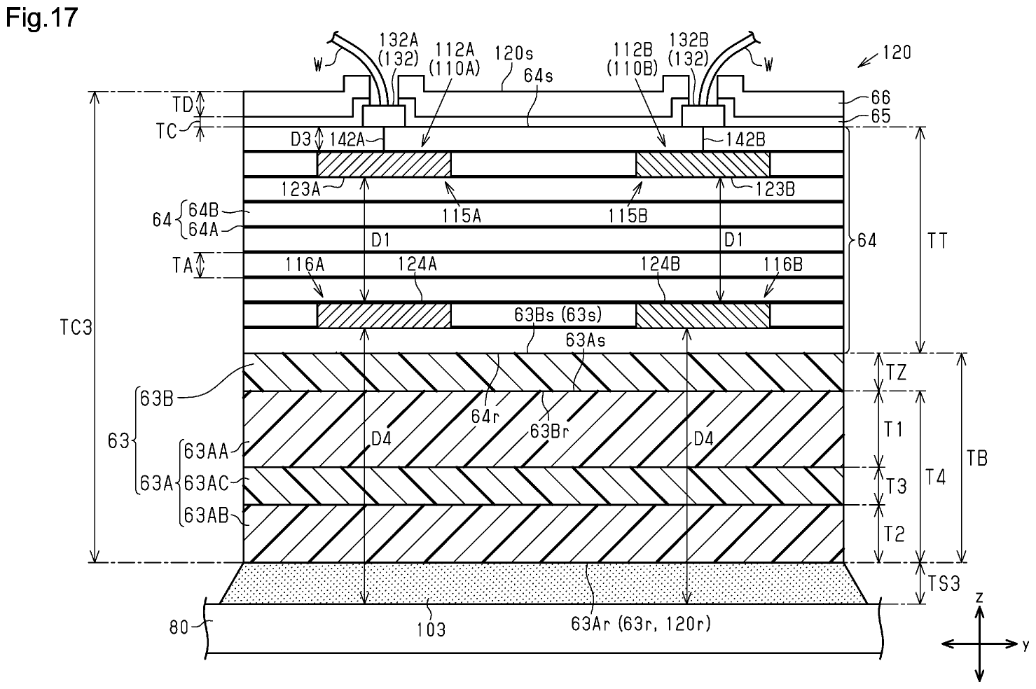

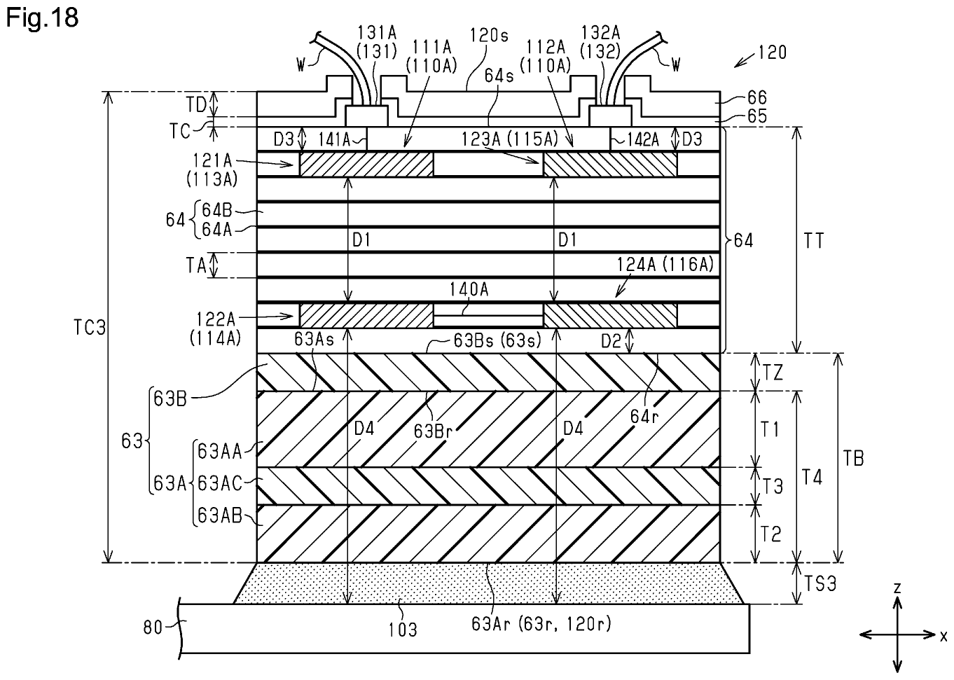

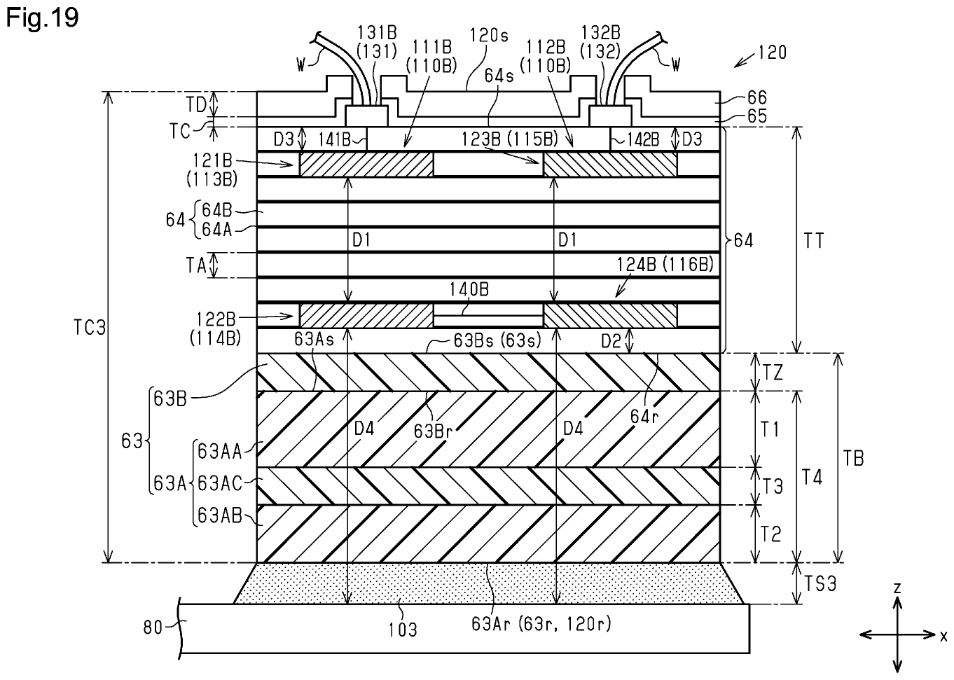

A second embodiment of a signal transmission device 10 will now be described with reference to FIGS. 12 to 19. The signal transmission device 10 of the present embodiment differs from the signal transmission device 10 of the first embodiment in that the transformer chip 60 is replaced with a capacitor chip 120 including a capacitor 110. In the following description, the differences from the first embodiment will be described. The same reference characters are given to those components that are the same as the corresponding components of the first embodiment. Such components will not be described in detail.

FIG. 12 is a schematic circuit diagram showing the signal transmission device 10 of the present embodiment. As shown in FIG. 12, the signal transmitting circuit 10A of the signal transmission device 10 includes the capacitor 110 as an isolation structure that electrically insulates the primary circuit 13 from the secondary circuit 14. The capacitor 110 includes a capacitor 110A connected to a signal line configured to transmit a first signal and a capacitor 110B connected to a signal line configured to transmit a second signal. The capacitors 110A and 110B are arranged between the primary circuit 13 and the secondary circuit 14. The first signal and the second signal are the same as those in the first embodiment. In the present embodiment, the capacitor 110A corresponds to a “first signal capacitor.” The capacitor 110B corresponds to a “second signal capacitor.”

The signal transmitting circuit 10A includes a connection signal line 20A as the signal line configured to transmit the first signal and a connection signal line 20B as the signal line configured to transmit the second signal. The connection signal line 20A is arranged between the primary signal line 16A and the secondary signal line 17A. The connection signal line 20B is arranged between the primary signal line 16B and the secondary signal line 17B. The signal line configured to transmit the first signal includes the primary signal line 16A, the secondary signal line 17A, and the connection signal line 20A. The signal line configured to transmit the second signal includes the primary signal line 16B, the secondary signal line 17B, and the connection signal line 20B.

The capacitor 110A includes a first capacitor 111A and a second capacitor 112A that are connected in series by the connection signal line 20A. The first capacitor 111A is electrically connected to the primary circuit 13. The second capacitor 112A is electrically connected to the secondary circuit 14. More specifically, the first capacitor 111A includes a first electrode 113A and a second electrode 114A. The second capacitor 112A includes a first electrode 115A and a second electrode 116A. The first electrode 113A of the first capacitor 111A is connected to the primary circuit 13 by the primary signal line 16A. The second electrode 114A of the first capacitor 111A is connected to the second electrode 116A of the second capacitor 112A by the connection signal line 20A. The first electrode 115A of the second capacitor 112A is connected to the secondary circuit 14 by the secondary signal line 17A. Thus, the primary circuit 13 and the secondary circuit 14 transmit the first signal through the first capacitor 111A and the second capacitor 112A, which are connected in series.

The capacitor 110B includes a first capacitor 111B and a second capacitor 112B that are connected in series by the connection signal line 20B. The first capacitor 111B includes a first electrode 113B and a second electrode 114B. The second capacitor 112B includes a first electrode 115B and a second electrode 116B. The structure of the capacitor 110B and the connection structure of the capacitor 110B with the primary circuit 13 and the secondary circuit 14 are the same as those of the capacitor 110A and thus will not be described in detail. The primary circuit 13 and the secondary circuit 14 transmit the second signal through the first capacitor 111B and the second capacitor 112B, which are connected in series. In the present embodiment, the first capacitors 111A and 111B correspond to a “first isolation element.” The second capacitors 112A and 112B correspond to a “second isolation element.”

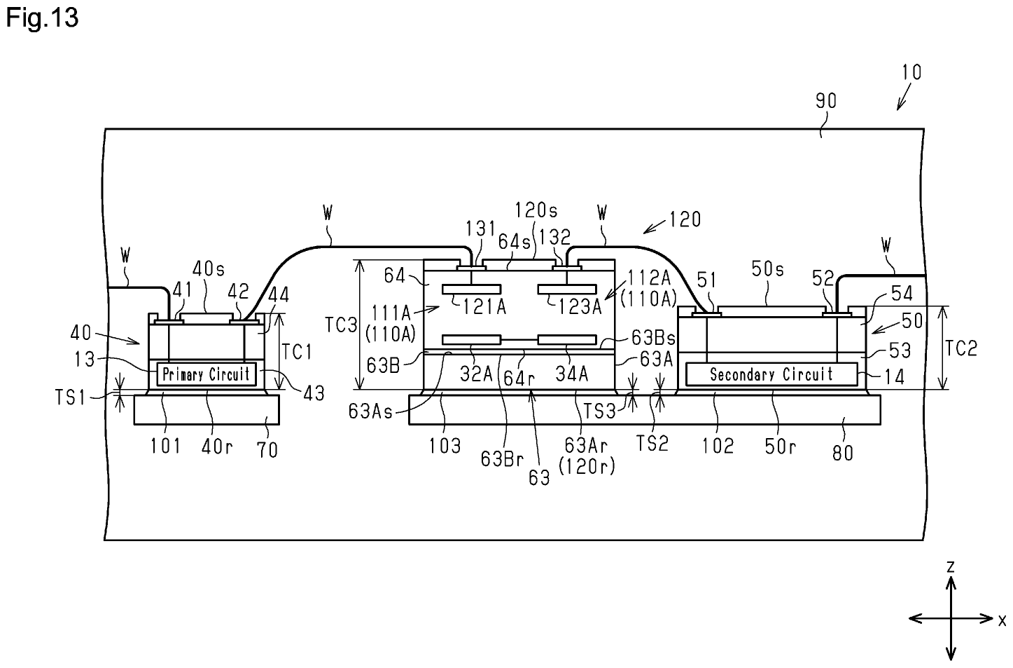

FIG. 13 is a schematic cross-sectional view showing a portion of the signal transmission device 10 of the present embodiment. FIG. 13 does not show hatching for simplicity and clarity.

As shown in FIG. 13, the signal transmission device 10 includes a capacitor chip 120 instead of the transformer chip 60 (refer to FIG. 2) of the first embodiment. In the same manner as the transformer chip 60, the capacitor chip 120 is arranged between the first chip 40 and the second chip 50 in the x-direction. In the same manner as the transformer chip 60 of the first embodiment, in the present embodiment, the distance between the capacitor chip 120 and the second chip 50 in the x-direction is smaller than the distance between the capacitor chip 120 and the first chip 40 in the x-direction.

In the present embodiment, the capacitor chip 120 is mounted on the secondary die pad 80. In the same manner as the first embodiment, the capacitor chip 120 is bonded to the secondary die pad 80 by the third bonding material 103. In the same manner as the first embodiment, the third bonding material 103 is electrically insulative. In the present embodiment, the capacitor chip 120 corresponds to an “insulation chip.”

An example of the internal structure of the capacitor chip 120 will now be described with reference to FIGS. 13 to 19.

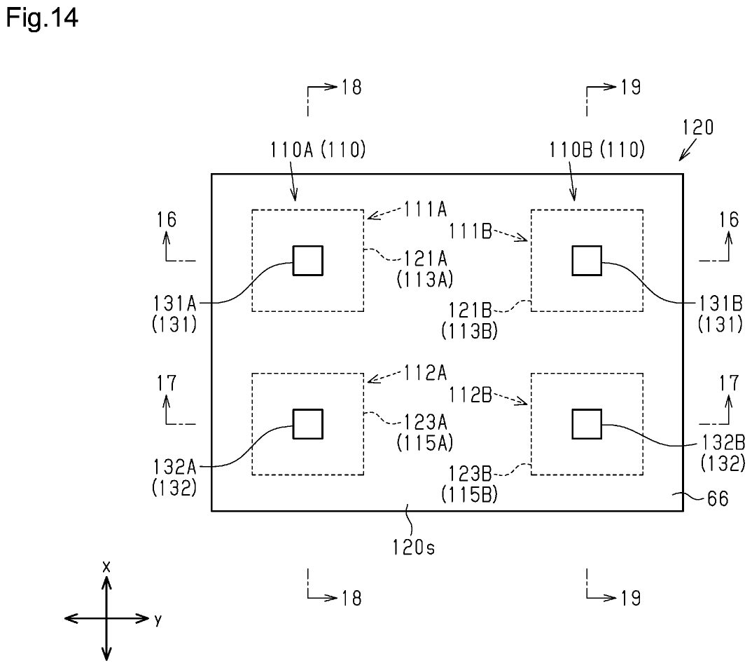

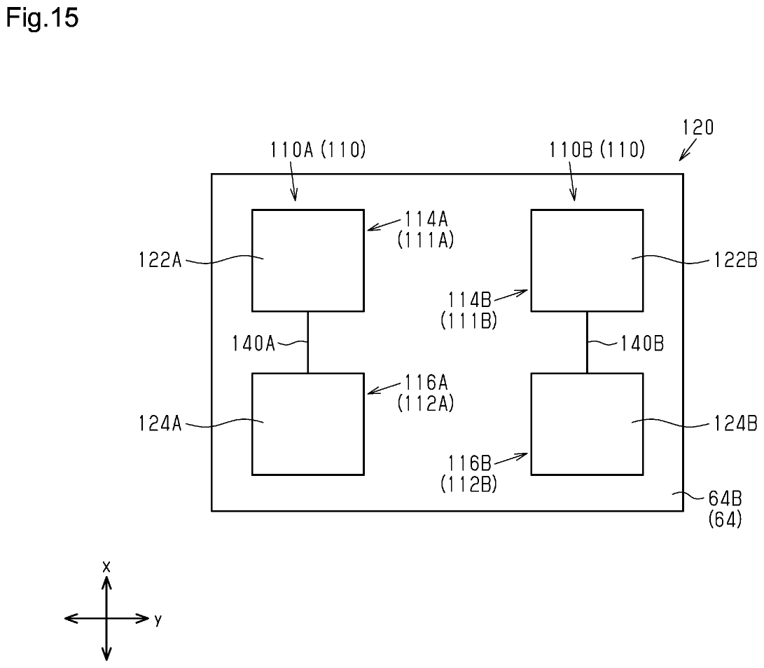

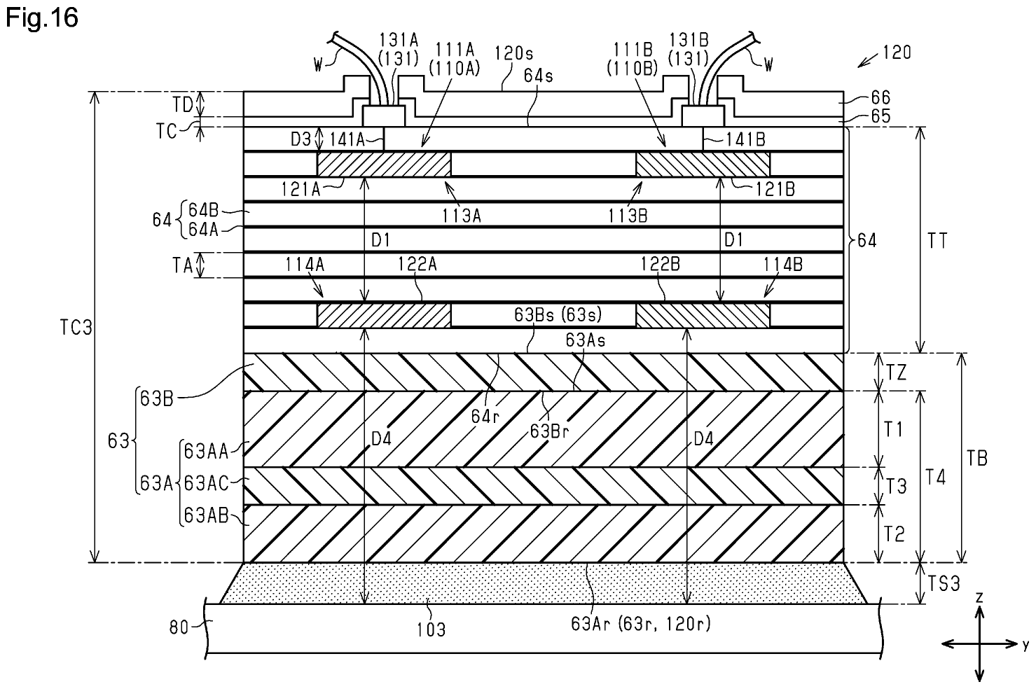

FIG. 14 is a schematic plan view showing a planar structure of the capacitor chip 120. FIG. 15 is a schematic cross-sectional view showing a cross-sectional internal structure of the capacitor chip 120 taken along the xy-plane. FIG. 15 does not show hatching for simplicity and clarity. FIGS. 16 to 19 show a cross-sectional structure of the capacitor chip 120 mounted on the secondary die pad 80. FIGS. 16 to 19 each show a schematic cross-sectional structure of the capacitor chip 120. The number of element insulation layers 64 that are stacked is not limited to those of the element insulation layers 64 shown in FIGS. 16 to 19. FIGS. 16 to 19 do not show the first ends 36.

As shown in FIG. 13, the capacitor chip 120 includes a chip main surface 120s and a chip back surface 120r facing opposite directions in the z-direction. The chip main surface 120s and the chip main surface 40s of the first chip 40 face in the same direction. The chip back surface 120r and the chip back surface 40r of the first chip 40 face in the same direction. In the following description, a direction from the chip back surface 120r of the capacitor chip 120 toward the chip main surface 120s is referred to as an upward direction, and a direction from the chip main surface 120s toward the chip back surface 120r is referred to as a downward direction.

As shown in FIGS. 14 and 15, the capacitor chip 120 includes the two capacitors 110A and 110B. More specifically, the two capacitors 110A and 110B are integrated in a single chip. That is, the capacitor chip 120 is separate from the first chip 40 and the second chip 50 and is dedicated to the two capacitors 110A and 110B.

The two capacitors 110A and 110B are separated from each other in the y-direction. As viewed in the z-direction, the first capacitor 111A of the capacitor 110A and the first capacitor 111B of the capacitor 110B are located closer to the first chip 40 (refer to FIG. 13) than the center of the capacitor chip 120 in the x-direction is. As viewed in the z-direction, the second capacitor 112A of the capacitor 110A and the second capacitor 112B of the capacitor 110B are located closer to the second chip 50 (refer to FIG. 13) than the center of the capacitor chip 120 in the x-direction is. The first capacitors 111A and 111B are aligned with each other in the x-direction and separated from each other in the y-direction. The second capacitors 112A and 112B are aligned with each other in the x-direction and separated from each other in the y-direction. The first capacitor 111A and the second capacitor 112A are aligned with each other in the y-direction and separated from each other in the x-direction. The first capacitor 111B and the second capacitor 112B are aligned with each other in the y-direction and separated from each other in the x-direction. In other words, the first capacitor 111A (111B) and the second capacitor 112A (112B) are separated from each other in the arrangement direction of the two die pads 70 and 80.

In accordance with the arrangement relationship of the capacitors 111A, 111B, 112A, and 112B described above, a first electrode plate 121A of the first capacitor 111A and a first electrode plate 123A of the second capacitor 112A are spaced apart from each other in the x-direction. In the same manner, a first electrode plate 121B of the first capacitor 111B and a first electrode plate 123B of the second capacitor 112B are spaced apart from each other in the x-direction. In other words, the first electrode plate 121A (121B) of the first capacitor 111A (111B) and the first electrode plate 123A (123B) of the second capacitor 112A (112B) are spaced apart from each other in the arrangement direction of the two die pads 70 and 80.

The first electrode plate 121A of the first capacitor 111A and the first electrode plate 121B of the first capacitor 111B are spaced apart from each other in the y-direction. The first electrode plate 123A of the second capacitor 112A and the first electrode plate 123B of the second capacitor 112B are spaced apart from each other in the y-direction. In other words, as viewed in the z-direction, the first electrode plate 121A of the first capacitor 111A and the first electrode plate 121B of the first capacitor 111B are spaced apart from each other in a direction orthogonal to the arrangement direction of the two die pads 70 and 80. Also, as viewed in the z-direction, the first electrode plate 123A of the second capacitor 112A and the first electrode plate 123B of the second capacitor 112B are spaced apart from each other in a direction orthogonal to the arrangement direction of the two die pads 70 and 80.

As shown in FIGS. 15, 17, and 18, the first electrode plates 121A, 121B, 123A, and 123B are aligned with each other in the z-direction. The first electrode plates 121A, 121B, 123A, and 123B are formed from one or more selected from Ti, TiN, Ta, TaN, Au, Ag, Cu, Al, and W (tungsten). In the present embodiment, the first electrode plates 121A, 121B, 123A, and 123B are formed from a material including Cu.

In the present embodiment, the first electrode plates 121A, 121B, 123A, and 123B are identical in shape. In an example, each of the first electrode plates 121A, 121B, 123A, and 123B has the shape of a plate having a thickness-wise direction that conforms to the z-direction. As viewed in the z-direction, each of the first electrode plates 121A, 121B, 123A, and 123B is rectangular so that the short sides extend in the x-direction and the long sides extend in the y-direction.

As shown in FIG. 14, the capacitor chip 120 includes multiple (in the present embodiment, two) first electrode pads 131 and multiple (in the present embodiment, two) second electrode pads 132.

The first electrode pads 131 are separately electrically connected to the first capacitors 111A and 111B. The first electrode pads 131 are separated from each other in the y-direction. In the following description, for the sake of convenience, the two first electrode pads 131 are referred to as first electrode pads 131A and 131B. The first electrode pads 131A and 131B correspond to a “first pad.”

As viewed in the z-direction, the first electrode pad 131A overlaps the first electrode plate 121A, and the first electrode pad 131B overlaps the first electrode plate 121B. In the present embodiment, as viewed in the z-direction, the first electrode pad 131A overlaps the center of the first electrode plate 121A in the x-direction and the y-direction. As viewed in the z-direction, the first electrode pad 131B overlaps the center of the first electrode plate 121B in the x-direction and the y-direction. The first electrode pad 131A is electrically connected to the first electrode plate 121A. The first electrode pad 131B is electrically connected to the first electrode plate 121B.

The second electrode pads 132 are separately electrically connected to the second capacitors 112A and 112B. The second electrode pads 132 are separated from each other in the y-direction. In the following description, for the sake of convenience, the two second electrode pads 132 are referred to as second electrode pads 132A and 132B. The second electrode pads 132A and 132B correspond to a “second pad.”

As viewed in the z-direction, the second electrode pad 132A overlaps the first electrode plate 123A, and the second electrode pad 132B overlaps the first electrode plate 123B. In the present embodiment, as viewed in the z-direction, the second electrode pad 132A overlaps the center of the first electrode plate 123A in the x-direction and the y-direction. As viewed in the z-direction, the second electrode pad 132B overlaps the center of the first electrode plate 123B in the x-direction and the y-direction. The second electrode pad 132A is electrically connected to the first electrode plate 123A. The second electrode pad 132B is electrically connected to the first electrode plate 123B.

As shown in FIGS. 14 and 15, as viewed in the z-direction, a second electrode plate 122A of the first capacitor 111A overlaps the first electrode plate 121A of the first capacitor 111A. As viewed in the z-direction, a second electrode plate 122B of the first capacitor 111B overlaps the first electrode plate 121B of the first capacitor 111B. As viewed in the z-direction, a second electrode plate 124A of the second capacitor 112A overlaps the first electrode plate 123A of the second capacitor 112A. As viewed in the z-direction, a second electrode plate 124B of the second capacitor 112B overlaps the first electrode plate 123B of the second capacitor 112B.

In accordance with the arrangement relationship of the electrode plates 121A to 124A and 121B to 124B described above, the second electrode plate 122A and the second electrode plate 124A are spaced apart from each other in the x-direction. Also, the second electrode plate 122B and the second electrode plate 124B are spaced apart from each other in the x-direction. In other words, the second electrode plate 122A (122B) of the first capacitor 111A (111B) and the second electrode plate 124A (124B) of the second capacitor 112A (112B) are spaced apart from each other in the arrangement direction of the two die pads 70 and 80.

The second electrode plate 122A and the second electrode plate 122B are spaced apart from each other in the y-direction. The second electrode plate 124A and the second electrode plate 124B are spaced apart from each other in the y-direction. In other words, as viewed in the z-direction, the second electrode plate 122A of the first capacitor 111A and the second electrode plate 122B of the first capacitor 111B are spaced apart from each other in a direction orthogonal to the arrangement direction of the two die pads 70 and 80. Also, as viewed in the z-direction, the second electrode plate 124A of the second capacitor 112A and the second electrode plate 124B of the second capacitor 112B are spaced apart from each other in a direction orthogonal to the arrangement direction of the two die pads 70 and 80.

The second electrode plate 122A and the second electrode plate 124A are electrically connected to each other. More specifically, the second electrode plate 122A and the second electrode plate 124A are connected by a connection line 140A. The connection line 140A is arranged between the second electrode plate 122A and the second electrode plate 124A in the x-direction and extends in the x-direction. The connection line 140A and the second electrode plates 122A and 124A are arranged in the same element insulation layer 64 among the element insulation layers 64.

The second electrode plate 122B and the second electrode plate 124B are electrically connected to each other. More specifically, the second electrode plate 122B and the second electrode plate 124B are connected by a connection line 140B. The connection line 140B is arranged between the second electrode plate 122B and the second electrode plate 124B in the x-direction and extends in the x-direction. The connection line 140B and the second electrode plates 122B and 124B are arranged in the same element insulation layer 64 among the element insulation layers 64. The connection lines 140A and 140B are formed from a material including, for example, Al. However, the material of the connection lines 140A and 140B is not limited to Al and may be any conductive material.

As shown in FIGS. 16 to 19, in the same manner as the transformer chip 60 of the first embodiment, the capacitor chip 120 includes the substrate 63 and the element insulation layers 64. The structures of the substrate 63 and the element insulation layers 64 are the same as those of the first embodiment. Also, in the same manner as the transformer chip 60 of the first embodiment, the capacitor chip 120 includes the protection film 65 and the passivation film 66. The structures of the protection film 65 and the passivation film 66 are the same as those in the first embodiment. In the same manner as the first embodiment, the first electrode pads 131 and the second electrode pads 132 are exposed from the protection film 65 and the passivation film 66 in the z-direction.

The first capacitors 111A and 111B and the second capacitors 112A and 112B are arranged in the element insulation layers 64. In other words, the first electrode plate 121A and the second electrode plate 122A of the first capacitor 111A, the first electrode plate 121B and the second electrode plate 122B of the first capacitor 111B, the first electrode plate 123A and the second electrode plate 124A of the second capacitor 112A, and the first electrode plate 123B and the second electrode plate 124B of the second capacitor 112B are arranged in the element insulation layers 64.

The first electrode plate 121A and the second electrode plate 122A of the first capacitor 111A are opposed to each other in the z-direction. The first electrode plate 121A and the second electrode plate 122A are separated from each other in the z-direction. One or more of the element insulation layers 64 are arranged between the first electrode plate 121A and the second electrode plate 122A. The first electrode plate 121A is located closer to the front surface 64s of the element insulation layers 64 than to the back surface 64r. The second electrode plate 122A is located closer to the back surface 64r of the element insulation layers 64 than to the front surface 64s. That is, the first electrode plate 121A is located closer to the front surface 64s than the second electrode plate 122A is in the element insulation layers 64. In other words, the second electrode plate 122A is located closer to the back surface 64r than the first electrode plate 121A is in the element insulation layers 64.

The first electrode plates 121A and 121B are aligned with each other in the z-direction. In other words, the first electrode plates 121A and 121B are arranged in the same element insulation layer 64 among the element insulation layers 64. The second electrode plates 122A and 122B are aligned with each other in the z-direction. In other words, the second electrode plates 122A and 122B are arranged in the same element insulation layer 64 among the element insulation layers 64. The second electrode plates 122A and 122B are separated from the back surface 64r of the element insulation layers 64 in the z-direction. In other words, one or more of the element insulation layers 64 are arranged between the back surface 64r of the element insulation layers 64 and the second electrode plates 122A and 122B.

The first electrode plates 121A and 121B extend through one of the element insulation layers 64 in the z-direction. That is, the first insulation film 64A and the second insulation film 64B of the one of the element insulation layers 64 include openings for formation of the first electrode plates 121A and 121B. The openings are filled with a conductive member formed from a material including Cu. Thus, the first electrode plates 121A and 121B are formed. The second electrode plates 122A and 122B are formed in the same manner as the first electrode plates 121A and 121B.

The first electrode plate 123A and the second electrode plate 124A of the second capacitor 112A are opposed to each other in the z-direction. The first electrode plate 123A and the second electrode plate 124A are separated from each other in the z-direction. One or more of the element insulation layers 64 are arranged between the first electrode plate 123A and the second electrode plate 124A in the z-direction. The first electrode plate 123A is located closer to the front surface 64s than to the back surface 64r in the element insulation layers 64. The second electrode plate 124A is located closer to the back surface 64r than to the front surface 64s in the element insulation layers 64. That is, the first electrode plate 123A is located closer to the front surface 64s than the second electrode plate 124A is in the element insulation layers 64. In other words, the second electrode plate 124A is located closer to the back surface 64r than the first electrode plate 123A is in the element insulation layers 64.

The first electrode plate 123B and the second electrode plate 124B of the second capacitor 112B are opposed to each other in the z-direction. The first electrode plate 123B and the second electrode plate 124B are separated from each other in the z-direction. One or more of the element insulation layers 64 are arranged between the first electrode plate 123B and the second electrode plate 124B in the z-direction. The first electrode plate 123B is located closer to the front surface 64s than to the back surface 64r in the element insulation layers 64. The second electrode plate 124B is located closer to the back surface 64r than to the front surface 64s in the element insulation layers 64. That is, the first electrode plate 123B is located closer to the front surface 64s than the second electrode plate 124B is, in the element insulation layers 64. In other words, the second electrode plate 124B is located closer to the back surface 64r than the first electrode plate 123B is, in the element insulation layers 64.

The first electrode plates 123A and 123B are aligned with each other in the z-direction. In other words, the first electrode plates 123A and 123B are arranged in the same element insulation layer 64 among the element insulation layers 64. The second electrode plates 124A and 124B are aligned with each other in the z-direction. In other words, the second electrode plates 124A and 124B are arranged in the same element insulation layer 64 among the element insulation layers 64. The second electrode plates 124A and 124B are separated from the back surface 64r of the element insulation layers 64 in the z-direction. In other words, one or more of the element insulation layers 64 are arranged between the back surface 64r of the element insulation layers 64 and the second electrode plates 124A and 124B.

The first electrode plates 123A and 123B and the first electrode plates 121A and 121B are aligned with each other in the z-direction. The second electrode plates 124A and 124B and the second electrode plates 122A and 122B are aligned with each other in the z-direction. The first electrode plates 123A and 123B and the second electrode plates 124A and 124B are formed in the same manner as the first electrode plates 121A and 121B and the second electrode plates 122A and 122B.

In the present embodiment, the first electrode plates 121A and 121B correspond to a “first frontward conductor” and a “first frontward electrode plate.” The second electrode plates 122A and 122B correspond to a “first backward conductor” and a “first backward electrode plate.” The first electrode plates 123A and 123B correspond to a “second frontward conductor” and a “second frontward electrode plate.” The second electrode plates 124A and 124B correspond to a “second backward conductor” and a “second backward electrode plate.”

The first electrode plate 121A and the first electrode pad 131A are connected by a connection line 141A. The first electrode plate 121B and the first electrode pad 131B are connected by a connection line 141B. The first electrode plate 123A and the second electrode pad 132A are connected by a connection line 142A. The first electrode plate 123B and the second electrode pad 132B are connected by a connection line 142B. The connection lines 141A, 141B, 142A, and 142B are vias extending through the element insulation layer 64 in the z-direction and are formed from one or more selected from, for example, Ti, TiN, Au, Ag, Cu, Al, and W (tungsten).

In the same manner as the transformer chip 60 of the first embodiment, the substrate 63 of the capacitor chip 120 includes the substrate insulation layer 63B arranged on the front surface 63As of the body 63A of the substrate 63. In addition, in the same manner as the transformer chip 60 of the first embodiment, the capacitor chip 120 is bonded to the secondary die pad 80 by the third bonding material 103. The dimensional relationship in the signal transmission device 10 of the present embodiment is the same as the dimensional relationship in the signal transmission device 10 of the first embodiment. In the present embodiment, the distance D1 corresponds to the distance between the first electrode plate 121A (121B) and the second electrode plate 122A (122B) in the z-direction and the distance between the first electrode plate 123A (123B) and the second electrode plate 124A (124A) in the z-direction. The distance D2 corresponds to the distance between the second electrode plate 122A (122B, 124A, 124B) and the back surface 64r of the element insulation layers 64 in the z-direction. The signal transmission device 10 having the structure described above obtains advantages similar to those of the first embodiment.

### MODIFIED EXAMPLES

The embodiments exemplify, without any intention to limit, applicable forms of a signal transmission device and an insulation chip according to the present disclosure. The signal transmission device and the insulation chip according to the present disclosure may be applicable to forms differing from the above embodiments. In an example of such a form, the structure of the embodiments is partially replaced, changed, or omitted, or a further structure is added to the embodiments. The modified examples described below may be combined with one another as long as there is no technical inconsistency. In the modified examples, the same reference characters are given to those components that are the same as the corresponding components of the above embodiments. Such components will not be described in detail.

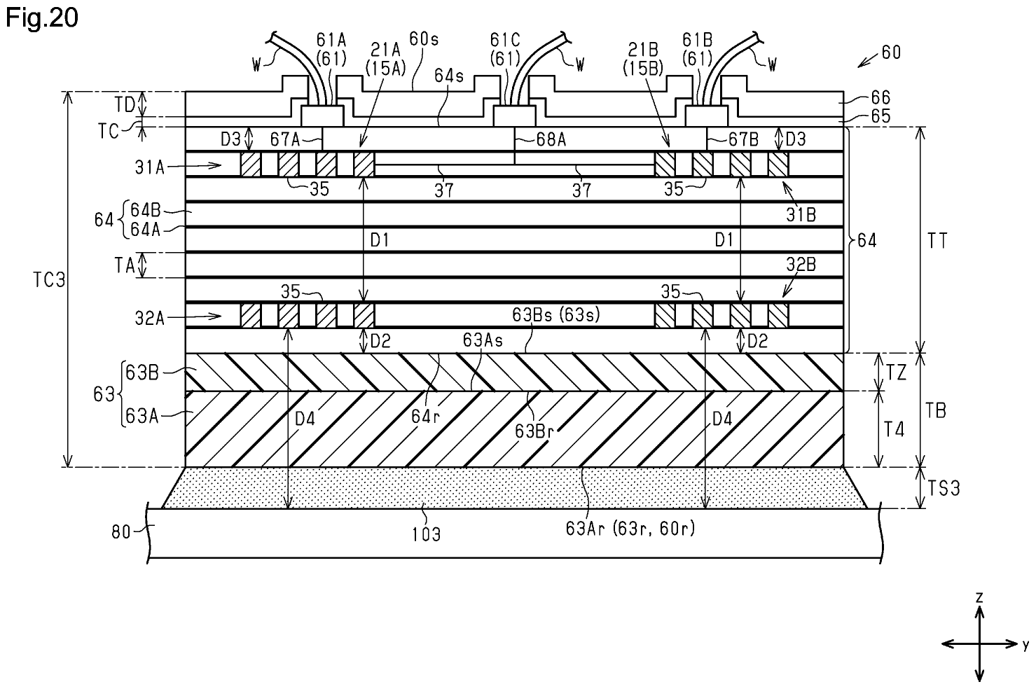

In the first embodiment, the structure of the substrate 63 of the transformer chip 60 may be changed in any manner. In an example, as shown in FIG. 20, the body 63A of the substrate 63 may be a single-layer semiconductor substrate instead of an SOI substrate. The thickness TZ of the substrate insulation layer 63B is smaller than a thickness T4 of the body 63A.

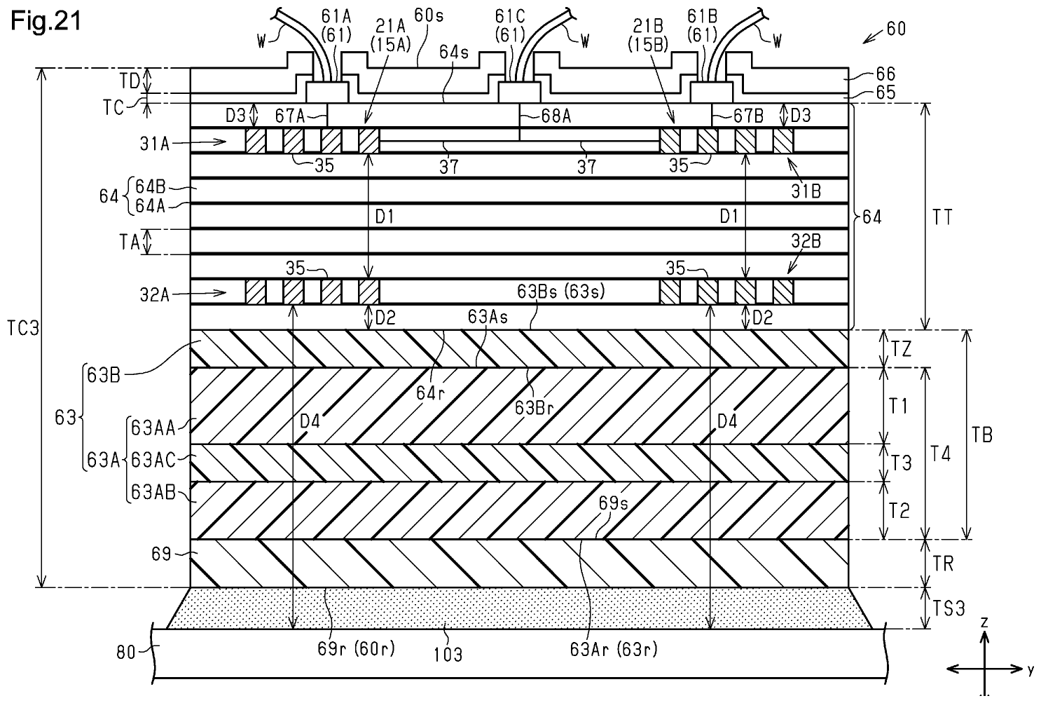

In the first embodiment, as shown in FIG. 21, the transformer chip 60 may include a back surface insulation layer 69 arranged on the back surface 63Ar of the body 63A of the substrate 63 (surface of the second semiconductor layer 63AB opposite from the oxide film 63AC in the z-direction). In the present embodiment, the back surface insulation layer 69 is formed on the entirety of the back surface 63Ar of the body 63A. The back surface insulation layer 69 includes a front surface 69s and a back surface 69r facing opposite directions in the z-direction. The front surface 69s of the back surface insulation layer 69 is in contact with the back surface 63Ar of the body 63A. The back surface 69r of the back surface insulation layer 69 includes the chip back surface 60r of the transformer chip 60.

The back surface insulation layer 69 is formed from an electrically-insulative material. In the present embodiment, the back surface insulation layer 69 is formed of a layer including, for example, SiO. The back surface insulation layer 69 is formed by, for example, applying an organic thermosetting siloxane polymer solution having a siloxane bond (Si—O—Si) in the main chain to the substrate back surface 63r and solidifying the solution. Alternatively, the back surface insulation layer 69 may be formed of a layer, for example, including resin. Examples of the resin include an epoxy resin, a phenol resin, and a polyimide resin.

The transformer chip 60 is bonded to the secondary die pad 80 by a third bonding material 103. More specifically, the third bonding material 103 is located between the back surface 69r of the back surface insulation layer 69 (the chip back surface 60r) and the secondary die pad 80. The third bonding material 103 bonds the back surface 69r of the back surface insulation layer 69 (the chip back surface 60r) and the secondary die pad 80. In the present embodiment, the third bonding material 103 is in contact with the entirety of the back surface 69r of the back surface insulation layer 69 (the chip back surface 60r).

The thickness TR of the back surface insulation layer 69 is greater than the thickness TA of a single element insulation layer 64 and is smaller than the thickness TT of the element insulation layers 64. The thickness TR of the back surface insulation layer 69 is the distance between the front surface 69s and the back surface 69r of the back surface insulation layer 69 in the z-direction. The thickness TA of the single element insulation layer 64 is equal to the thickness of each of the coils 31A to 34A and 31B to 34B. Therefore, the thickness TR of the back surface insulation layer 69 is greater than the thickness of each of the coils 31A to 34A and 31B to 34B.

The thickness TR of the back surface insulation layer 69 is greater than the distance D2 between the second coil 32A (32B) and the back surface 64r of the element insulation layers 64 in the z-direction. The thickness TR of the back surface insulation layer 69 is greater than the distance D3 between the first coil 31A (31B) and the front surface 64s of the element insulation layers 64 in the z-direction. The thickness TR of the back surface insulation layer 69 is smaller than the distance D1 between the first coil 31A (31B) and the second coil 32A (32B) in the z-direction. The thickness TR of the back surface insulation layer 69 is smaller than the thickness T4 of the substrate 63.

The thickness TR of the back surface insulation layer 69 is greater than the thickness TC of the protection film 65. The thickness TR of the back surface insulation layer 69 is also greater than a thickness TD of the passivation film 66. The thickness TC of the protection film 65 is the distance between a front surface and a back surface of the protection film 65 in the z-direction. The front surface of the protection film 65 is in contact with the passivation film 66. The back surface of the protection film 65 is in contact with the element insulation layer 64. The thickness TD of the passivation film 66 is the distance between a front surface and a back surface of the passivation film 66 in the z-direction. The front surface of the passivation film 66 includes the chip main surface 60s of the transformer chip 60. The back surface of the passivation film 66 is in contact with the protection film 65. In the present embodiment, the thickness TR of the back surface insulation layer 69 is greater than the thickness TS3 of the third bonding material 103. In an example, the thickness TR of the back surface insulation layer 69 is in a range of 5 μm to 100 μm. Since the thickness TS3 of the third bonding material 103 is equal to the thickness TS1 of the first bonding material 101 and the thickness TS2 of the second bonding material 102, the thickness TR of the back surface insulation layer 69 is greater than the thickness TS1 of the first bonding material 101, and the thickness TR of the back surface insulation layer 69 is greater than the thickness TS2 of the second bonding material 102.

In this structure, the distance between the second coil 32A (32B) and the secondary die pad 80 in the z-direction is increased as compared to a transformer chip that does not include the back surface insulation layer 69. This improves the insulation voltage between the transformer chip 60 and the secondary die pad 80, thereby improving the dielectric strength of the signal transmission device 10. In the same manner, in the modified example shown in FIG. 20, the transformer chip 60 may include the back surface insulation layer 69 arranged on the back surface 63Ar of the body 63A of the substrate 63.

In the first embodiment, as viewed in the z-direction, the positions of the first electrode pads 61A and 61B in the transformer chip 60 may be changed in any manner. In an example, the first electrode pad 61A may be located outside the coil portion 35 of the first coil 31A. In this case, as viewed in the y-direction, the first electrode pad 61A may overlap the coil portion 35 of the first coil 31A in the x-direction. As viewed in the z-direction, the first electrode pad 61A may be located closer to the first chip 40 or the second chip 50 than the coil portion 35 of the first coil 31A is in the x-direction. In other words, as viewed in the z-direction, the first electrode pad 61A and the first coil 33A may be located at opposite sides of the first coil 31A in the x-direction. The first electrode pad 61B may be located outside the coil portion 35 of the first coil 31B. In this case, as viewed in the y-direction, the first electrode pad 61B may overlap the coil portion 35 of the first coil 31B in the x-direction. As viewed in the z-direction, the first electrode pad 61B may be located closer to the first chip 40 or the second chip 50 than the coil portion 35 of the first coil 31B is in the x-direction. In other words, as viewed in the z-direction, the first electrode pad 61B and the first coil 33B may be located at opposite sides of the first coil 31B in the x-direction.

In an example, as viewed in the z-direction, the first electrode pad 61A may overlap the coil portion 35 of the first coil 31A. As viewed in the z-direction, the first electrode pad 61B may overlap the coil portion 35 of the first coil 31B.

In an example, as viewed in the z-direction, the first electrode pad 61A may overlap the center of the first coil 31A. As viewed in the z-direction, the first electrode pad 61B may overlap the center of the first coil 31B.

In the first embodiment, as viewed in the z-direction, the positions of the second electrode pads 62A and 62B in the transformer chip 60 may be changed in any manner. In an example, the second electrode pad 62A may be located outside the coil portion 35 of the first coil 33A. In this case, as viewed in the y-direction, the second electrode pad 62A may overlap the coil portion 35 of the first coil 33A in the x-direction. As viewed in the z-direction, the second electrode pad 62A may be located closer to the first chip 40 or the second chip 50 than the coil portion 35 of the first coil 33A is in the x-direction. In other words, as viewed in the z-direction, the second electrode pad 62A and the first coil 31A may be located at opposite sides of the first coil 33A in the x-direction. The second electrode pad 62B may be located outside the coil portion 35 of the first coil 33B. In this case, as viewed in the y-direction, the second electrode pad 62B may overlap the coil portion 35 of the first coil 33B in the x-direction. As viewed in the z-direction, the second electrode pad 62B may be located closer to the first chip 40 or the second chip 50 than the coil portion 35 of the first coil 33B is in the x-direction. In other words, as viewed in the z-direction, the second electrode pad 62B and the first coil 31B may be located at opposite sides of the first coil 33B in the x-direction.

In an example, as viewed in the z-direction, the second electrode pad 62A may overlap the coil portion 35 of the first coil 33A. As viewed in the z-direction, the second electrode pad 62B may overlap the coil portion 35 of the first coil 33B.

In an example, as viewed in the z-direction, the second electrode pad 62A may overlap the center of the first coil 33A. As viewed in the z-direction, the second electrode pad 62B may overlap the center of the first coil 33B.

In the first embodiment, the shapes of the first coils 31A, 31B, 33A, and 33B as viewed in the z-direction may be changed in any manner. In an example, as viewed in the z-direction, at least one of the coil portions 35 of the first coils 31A, 31B, 33A, and 33B may be annular.

In the first embodiment, the shapes of the second coils 32A, 32B, 34A, and 34B as viewed in the z-direction may be changed in any manner.

In an example, as viewed in the z-direction, at least one of the coil portions 35 of the second coils 32A, 32B, 34A, and 34B may be annular.

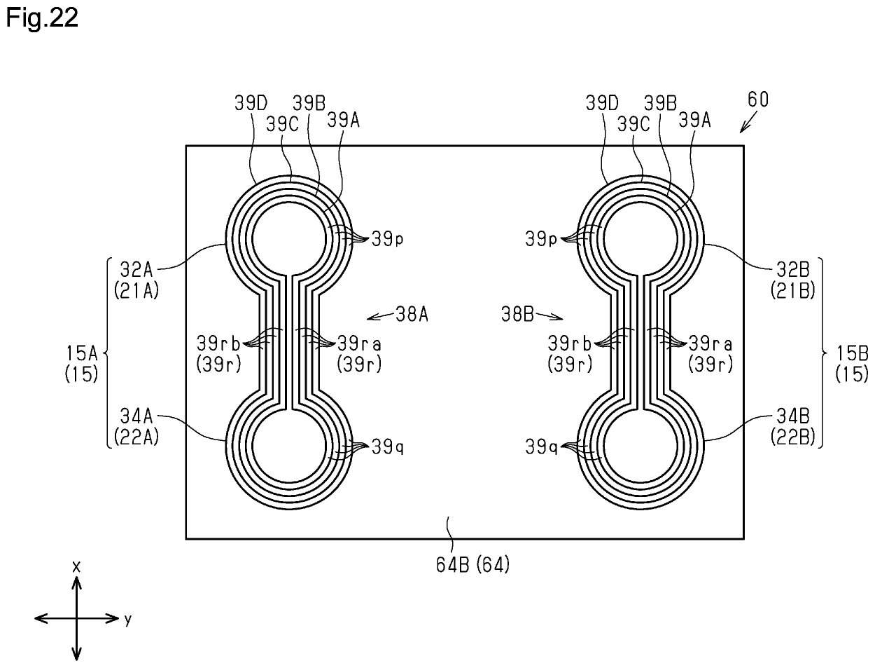

In another example, the second coil 32A and the second coil 34A may be formed integrally. More specifically, as shown in FIG. 22, the second coil 32A and the second coil 34A are formed integrally with each other as a first coil 38A. More specifically, the first coil 38A includes a first loop conductor 39A, a second loop conductor 39B, a third loop conductor 39C, and a fourth loop conductor 39D. The first loop conductor 39A, the second loop conductor 39B, the third loop conductor 39C, and the fourth loop conductor 39D have geometrical similarity with each other. The second loop conductor 39B surrounds the first loop conductor 39A. The third loop conductor 39C surrounds the second loop conductor 39B. The fourth loop conductor 39D surrounds the third loop conductor 39C. In the present embodiment, the number of loop conductors, which are the first to fourth loop conductors 39A to 39D, is four. However, there is no limit to such a configuration. The number of loop conductors may be changed in any manner.

The first loop conductor 39A includes a first opposing part 39p, a second opposing part 39q, and joint parts 39r. The first opposing part 39p, the second opposing part 39q, and the joint parts 39r are formed integrally. When integrally formed, the first opposing part 39p, the second opposing part 39q, and the joint parts 39r form a loop. The first opposing part 39p and the second opposing part 39q are aligned with each other in the y-direction and separated apart from each other in the x-direction.

The first opposing part 39p is opposed to the first coil 31A in the z-direction and forms the second coil 32A. The shape of the first opposing part 39p as viewed in the z-direction is annular and is open toward the second opposing part 39q in the x-direction.

The second opposing part 39q is opposed to the first coil 33A in the z-direction and forms the second coil 34A. The shape of the second opposing part 39q as viewed in the z-direction is annular and is open toward the first opposing part 39p in the x-direction. Thus, as viewed in the z-direction, the annular first opposing part 39p and the annular second opposing part 39q are open toward each other.

The joint parts 39r join the first opposing part 39p and the second opposing part 39q. The joint parts 39r include a first joint part 39ra and a second joint part 39rb. The first joint part 39ra joins a first end of the open-annular first opposing part 39p, defining a first open end thereof, and a first end of the open-annular second opposing part 39q, defining a first open end thereof. The second joint part 39rb joints a second end of the open-annular first opposing part 39p, defining a second open end thereof, and a second end of the open-annular second opposing part 39q, defining a second open end thereof. That is, the joint parts 39r join the open ends of the two opposing parts 39p and 39q. The joint parts 39ra and 39rb each extend linearly in the x-direction. In the same manner, the second to fourth loop conductors 39B to 39D include the first opposing part 39p, the second opposing part 39q, and the joint parts 39r.

The second coil 32B and the second coil 34B are formed integrally with each other as a second coil 38B. The second coil 38B and the first coil 38A are identical in shape. Thus, the second coil 38B will not be described in detail. The second coils 32A, 32B, 34A, and 34B are formed from one or more selected from Ti, TiN, Ta, TaN, Au, Ag, Cu, Al, and W. In the present embodiment, the second coils 32A, 32B, 34A, and 34B are formed from a material including Al.

In the present embodiment, the number of windings in the first coil 31A is the same as the number of windings in the second coil 32A (the number of first opposing parts 39p). In the present embodiment, the outer diameter of the coil portion 35 of the first coil 31A is equal to the outer diameter of the second coil 32A. The outer diameter of the second coil 32A is the outer diameter of the first opposing part 39p (refer to FIG. 4) of the fourth loop conductor 39D. The relationship of the first coil 31B and the second coil 32B is the same as the relationship of the first coil 31A and the second coil 32A.

In this structure, the second coil 32A (32B) and the second coil 34A (34B) are connected to each other and are aligned with each other in the z-direction. This allows the second coil 32A (32B) and the second coil 34A (34B), connected to each other, to be readily formed in the element insulation layers 64.

In the same manner, in the second embodiment, the second electrode plate 122A and the second electrode plate 124A may be formed integrally. In the same manner, the second electrode plate 122B and the second electrode plate 124B may be formed integrally.

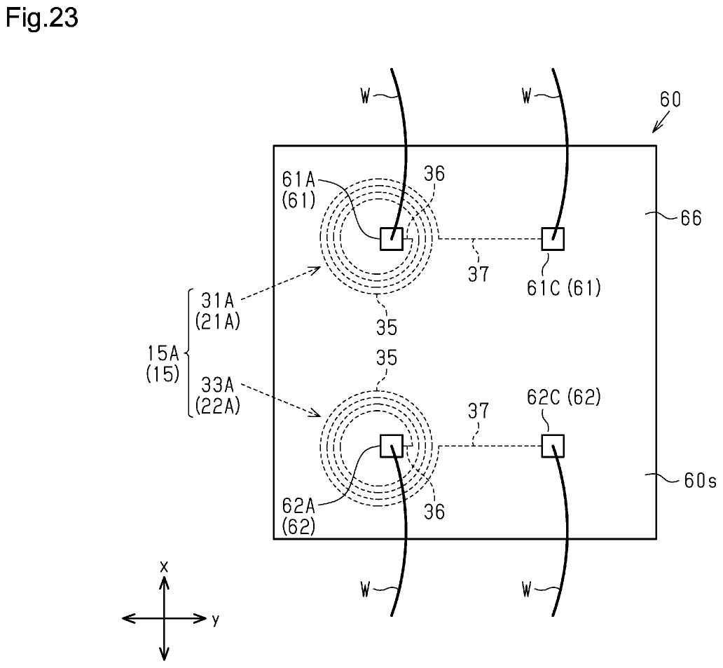

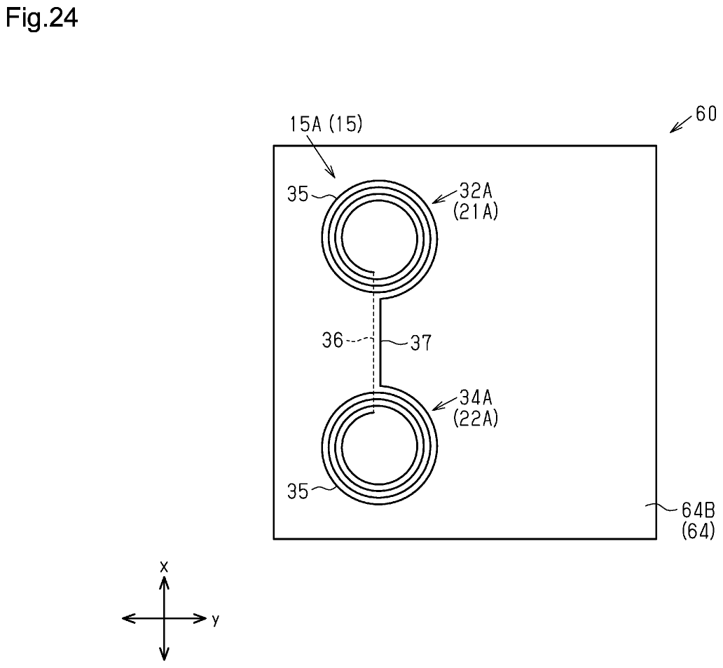

In the first embodiment, one of a signal path that transmits the first signal from the primary circuit 13 to the secondary circuit 14 and a signal path that transmits the second signal from the primary circuit 13 to the secondary circuit 14 may be omitted. FIGS. 23 and 24 show an example of the transformer chip 60 that does not include the signal path transmitting the second signal from the primary circuit 13 to the secondary circuit 14.

As shown in FIGS. 23 and 24, the transformer 15A is integrated in a single chip, that is, the transformer chip 60. More specifically, the first coil 31A and the second coil 32A of the first transformer 21A and the first coil 33A and the second coil 34A of the second transformer 22A are embedded in the element insulation layers 64 of the transformer chip 60.

As shown in FIG. 23, the first coil 31A of the first transformer 21A and the first coil 33A of the second transformer 22A are aligned with each other in the y-direction and separated from each other in the x-direction as viewed in the z-direction. The first coil 31A and the first coil 33A are aligned with each other in the z-direction. As shown in FIGS. 23 and 24, the layout of the coils 31A to 34A is the same as the first embodiment.

As shown in FIG. 23, the transformer chip 60 includes the two first electrode pads 61A and 61C and the two second electrode pads 62A and 62C. The first electrode pad 61A is located inside the coil portion 35 of the first coil 31A. The first electrode pad 61C is located outside the coil portion 35 of the first coil 31A. The first electrode pad 61A is connected to the first end 36 of the first coil 31A. The first electrode pad 61C is connected to the second end 37 of the first coil 31A. The second electrode pad 62A is located inside the coil portion 35 of the first coil 33A. The second electrode pad 62C is located outside the coil portion 35 of the first coil 33A. The second electrode pad 62A is connected to the first end 36 of the first coil 33A. The second electrode pad 62C is connected to the second end 37 of the first coil 33A. The second embodiment may be changed in the same manner.

In the modified example shown in FIG. 24, the second coils 32A and 34A may be changed to the first coil 38A shown in FIG. 22.

In the first embodiment, the transformer chip 60 may include a dummy pattern. In an example, the dummy pattern includes an annular first dummy pattern surrounding the second coils 32A and 34A and an annular second dummy pattern surrounding the second coils 32B and 34B as viewed in the z-direction. In another example, the dummy pattern includes a third dummy pattern that surrounds the first coil 33A (33B) as viewed in the z-direction.

In the first and second embodiments, the first coils 31A, 31B, 33A, and 33B may be formed from a material including Cu. The second coils 32A, 32B, 34A, and 34B may be formed from a material including Al.

In this structure, a relatively large current flows to the first coils 31A, 31B, 33A, and 33B, which are formed from the material including Cu. Thus, the current smoothly flows through the first coils 31A, 31B, 33A, and 33B. The second coils 32A, 32B, 34A, and 34B are formed from the material including Al. Thus, the second coils 32A, 32B, 34A, and 34B are formed at a lower cost than when the second coils 32A, 32B, 34A, and 34B are formed from a material including Cu.

In the second embodiment, as viewed in the z-direction, the positions of the first electrode pads 131 in the capacitor chip 120 may be changed in any manner. In an example, as viewed in the z-direction, the first electrode pad 131A may be arranged so as not to overlap the first electrode plate 121A. As viewed in the z-direction, the first electrode pad 131B may be arranged so as not to overlap the first electrode plate 121B.

In the second embodiment, as viewed in the z-direction, the positions of the second electrode pads 132 in the capacitor chip 120 may be changed in any manner. In an example, as viewed in the z-direction, the second electrode pad 132A may be arranged so as not to overlap the first electrode plate 123A. As viewed in the z-direction, the second electrode pad 132B may be arranged so as not to overlap the first electrode plate 123B.

In each embodiment, the thickness TZ of the substrate insulation layer 63B may be changed in any manner.

In an example, the thickness TZ of the substrate insulation layer 63B may be greater than or equal to the thickness T4 of the body 63A. The thickness TZ of the substrate insulation layer 63B may be greater than the thickness T3 of the oxide film 63AC of the body 63A. The thickness TZ of the substrate insulation layer 63B may be greater than or equal to the thickness T2 of the second semiconductor layer 63AB of the body 63A. The thickness TZ of the substrate insulation layer 63B may be greater than or equal to the thickness T1 of the first semiconductor layer 63AA of the body 63A.

In an example, the thickness TZ of the substrate insulation layer 63B may be smaller than the distance D2 between the back surface 64r of the element insulation layers 64 and each of the second coils 32A (32B) and 34A (34B) in the z-direction. The thickness TZ of the substrate insulation layer 63B may be smaller than the distance D2 between each of the second electrode plates 122A (122B) and 124A (124B) and the back surface 64r of the element insulation layers 64 in the z-direction.

In an example, the thickness TZ of the substrate insulation layer 63B may be greater than or equal to the thickness TS3 of the third bonding material 103. The thickness TZ of the substrate insulation layer 63B may be greater than or equal to the thickness TS1 of the first bonding material 101. The thickness TZ of the substrate insulation layer 63B may be greater than or equal to the thickness TS2 of the second bonding material 102.

In an example, the thickness TZ of the substrate insulation layer 63B may be greater than or equal to the distance D1 between the first coil 31A (31B) and the second coil 32A (32B) in the z-direction. The thickness TZ of the substrate insulation layer 63B may be greater than or equal to the distance D1 between the first coil 33A (33B) and the second coil 34A (34B) in the z-direction. The thickness TZ of the substrate insulation layer 63B may be greater than or equal to the distance D1 between the first electrode plate 121A (121B) and the second electrode plate 122A (122B) in the z-direction. The thickness TZ of the substrate insulation layer 63B may be greater than or equal to the distance D1 between the first electrode plate 123A (123B) and the second electrode plate 124A (124B) in the z-direction.

In each embodiment, the thickness-wise relationship of the first semiconductor layer 63AA, the second semiconductor layer 63AB, and the oxide film 63AC in the body 63A may be changed in any manner. In an example, the thickness T1 of the first semiconductor layer 63AA may be less than or equal to the thickness T2 of the second semiconductor layer 63AB. The thickness T2 of the second semiconductor layer 63AB may be less than or equal to the thickness T3 of the oxide film 63AC.

In each embodiment, at least one of the protection film 65 and the passivation film 66 may be omitted.

In each embodiment, the third bonding material 103 may be changed in any manner. In an example, the third bonding material 103 may be a conductive bonding material such as the first bonding material 101 and the second bonding material 102.

In each embodiment, the transformer chip 60 (the capacitor chip 120) may be mounted on the primary die pad 70. In this case, the transformer chip 60 (the capacitor chip 120) is bonded to the primary die pad 70 by the third bonding material 103.

In each embodiment, the transformer chip 60 (the capacitor chip 120) may be mounted on an intermediate die pad that differs from the primary die pad 70 and the secondary die pad 80. The intermediate die pad is arranged between the primary die pad 70 and the secondary die pad 80 in the x-direction. In this case, the transformer chip 60 (the capacitor chip 120) is bonded to the intermediate die pad by the third bonding material 103.

In the embodiments, the encapsulation resin 90 may be omitted from the signal transmission device 10.

In the embodiments, the element insulation layers 64 in the transformer chip 60 (the capacitor chip 120) may include a single resin layer or multiple resin layers. The resin layers may include a material including any one of polyimide resin, phenol resin, and epoxy resin.

The transformer chip 60 (the capacitor chip 120) may be applied to a device other than the signal transmission device 10.

In an example, the transformer chip 60 (the capacitor chip 120) may be applied to a primary circuit module. The primary circuit module includes the first chip 40, the transformer chip 60 (the capacitor chip 120), and an encapsulation resin encapsulating the chips 40 and 60 (120). The primary circuit module further includes the primary die pad 70 on which the first chip 40 and the transformer chip 60 (the capacitor chip 120) are both mounted. The first chip 40 is bonded to the primary die pad 70 by the first bonding material 101. The transformer chip 60 (the capacitor chip 120) is bonded to the primary die pad 70 by the third bonding material 103. In this case, the primary circuit 13 (refer to FIG. 1) included in the first chip 40 corresponds to a “signal transmission circuit.” The first chip 40 corresponds to a “circuit chip.” The primary circuit module corresponds to an “isolation module.”

In an example, the transformer chip 60 (the capacitor chip 120) may be applied to a secondary circuit module. The secondary circuit module includes the second chip 50, the transformer chip 60 (the capacitor chip 120), and an encapsulation resin encapsulating the chips 50 and 60 (120). The secondary circuit module further includes the secondary die pad 80 on which the second chip 50 and the transformer chip 60 (the capacitor chip 120) are mounted. The second chip 50 is bonded to the secondary die pad 80 by the second bonding material 102. The transformer chip 60 (the capacitor chip 120) is bonded to the secondary die pad 80 by the third bonding material 103. In this case, the secondary circuit 14 (refer to FIG. 1) included in the second chip 50 corresponds to a “signal transmission circuit.” The second chip 50 corresponds to a “circuit chip.” The secondary circuit module corresponds to an “isolation module.”

In each embodiment, the structure of the signal transmission device 10 may be changed in any manner.

In an example, the signal transmission device 10 may include the primary circuit module and the second chip 50. In this case, the second chip 50 may be mounted on the secondary die pad 80, and the secondary die pad 80 and the second chip 50 may be encapsulated by an encapsulation resin to form a module.

In an example, the signal transmission device 10 may include the secondary circuit module and the first chip 40. In this case, the first chip 40 may be mounted on the primary die pad 70, and the primary die pad 70 and the first chip 40 may be encapsulated by an encapsulation resin to form a module.

In the embodiments, the direction of a signal transmitted in the signal transmission device 10 may be changed in any manner. In an example, the signal transmission device 10 may be configured to transmit a signal from the secondary circuit 14 to the primary circuit 13 through the transformer 15. More specifically, when the secondary terminals 12 receive a signal (e.g., feedback signal) from the drive circuit, which is electrically connected to the secondary circuit 14 through the secondary terminals 12, the secondary circuit 14 transmits a signal to the primary circuit 13 through the transformer 15. Then, the signal is output from the primary circuit 13 to the controller, which is electrically connected to the primary circuit 13 through the primary terminals 11. In another example, the signal transmission device 10 may be configured to bidirectionally transmit a signal between the primary circuit 13 and the secondary circuit 14. More specifically, the signal transmission device 10 may include the primary circuit 13 and the secondary circuit 14, which is configured to perform at least one of transmission of a signal and reception of a signal with the primary circuit 13 through the transformer 15.

In the present disclosure, the term “on” includes the meaning of “above” in addition to the meaning of “on” unless otherwise clearly indicated in the context. Thus, the phrase “A is formed on B” is intended to mean that A may be disposed directly on B in contact with B in the embodiments and also that A may be disposed above B without contacting B in a modified example. In other words, the term “on” does not exclude a structure in which another member is formed between A and B.

The z-direction as referred to in the present disclosure does not necessarily have to be the vertical direction and does not necessarily have to fully conform to the vertical direction. In the structures according to the present disclosure, “upward” and “downward” in the z-direction as referred to in the present description are not limited to “upward” and “downward” in the vertical direction. In an example, the x-direction may conform to the vertical direction. In another example, the y-direction may conform to the vertical direction.

In this specification, “at least one of A and B” should be understood to mean “only A, only B, or both A and B.”

### CLAUSES

The technical aspects that are understood from the embodiments and the modified examples will be described below. The reference signs of the elements in the embodiments are given to the corresponding elements in clauses with parentheses. The reference signs are used as examples to facilitate understanding, and the elements in each clause are not limited to those elements given with the reference signs.

### [Clause 1]

A signal transmission device (10), including:
a first chip (40) including a first circuit (13);
a first die pad (70) on which the first chip (40) is mounted;
an insulation chip (60);
a second chip (50) including a second circuit (14) configured to perform at least one of reception of a signal and transmission of a signal with the first circuit (13) through the insulation chip (60); and
a second die pad (80) on which the second chip (50) is mounted, in which
the insulation chip (60) includes
   a substrate (63),
   an element insulation layer (64) including a front surface (64s) and a back surface (64r) opposite to the front surface (64s), the back surface (64r) being located closer to the substrate (63) than the front surface (64s) is, and
a first isolation element (21A, 21B) and a second isolation element (22A, 22B) arranged in the element insulation layer (64) and configured to transmit the signal,
the first isolation element (21A, 21B) includes
   a first frontward conductor (31A, 31B) arranged in the element insulation layer (64) at a position closer to the front surface (64s) than to the back surface (64r), and
   a first backward conductor (32A, 32B) arranged in the element insulation layer (64) at a position closer to the back surface (64r) than to the front surface (64s), the first backward conductor (32A, 32B) being opposed to the first frontward conductor (31A, 31B) in a thickness-wise direction (z-direction) of the element insulation layer (64),
the second isolation element (22A, 22B) includes
   a second frontward conductor (33A, 33B) arranged in the element insulation layer (64) at a position closer to the front surface (64s) than to the back surface (64r), and
   a second backward conductor (34A, 34B) arranged in the element insulation layer (64) at a position closer to the back surface (64r) than to the front surface (64s), the second backward conductor (34A, 34B) being opposed to the second frontward conductor (33A, 33B) in the thickness-wise direction (z-direction) of the element insulation layer (64),
the first backward conductor (32A, 32B) is electrically connected to the second backward conductor (34A, 34B), and
the substrate (63) includes
   a body (63A), and
   a substrate insulation layer (63B) formed on a front surface (63As) of the body (63A), and
the element insulation layer (64) is stacked on a front surface (63Bs) of the substrate insulation layer (63B).

### [Clause 2]

The signal transmission device according to clause 1, in which the substrate insulation layer (63B) includes an oxide film.

### [Clause 3]

The signal transmission device according to clause 2, in which the oxide film includes a TEOS oxide film.

### [Clause 4]

The signal transmission device according to any one of clauses 1 to 3, in which a thickness (TZ) of the substrate insulation layer (63B) is smaller than a thickness (T4) of the body (63A).

### [Clause 5]

The signal transmission device according to any one of clauses 1 to 4, in which the body (63A) includes an SOI substrate including
a first semiconductor layer (63AA) in contact with the element insulation layer (63B),
an oxide film (63AC) arranged on a side of the first semiconductor layer (63AA) opposite from the element insulation layer (63B), and
a second semiconductor layer (63AB) arranged on a side of the oxide film (63AC) opposite from the first semiconductor layer (63AA).

### [Clause 6]

The signal transmission device according to clause 5, in which
a thickness (T1) of the first semiconductor layer (63AA) is greater than a thickness (T3) of the oxide film (63AC) and a thickness (T2) of the second semiconductor layer (63AB), and
a thickness (TZ) of the substrate insulation layer (63B) is smaller than the thickness (T1) of the first semiconductor layer (63AA).

### [Clause 7]

The signal transmission device according to clause 6, in which
the thickness (T2) of the second semiconductor layer (63AB) is greater than the thickness (T3) of the oxide film (63AC), and
the thickness (TZ) of the substrate insulation layer (63B) is smaller than the thickness (T2) of the second semiconductor layer (63AB).

### [Clause 8]

The signal transmission device according to clause 7, in which the thickness (TZ) of the substrate insulation layer (63B) is equal to the thickness (T3) of the oxide film (63AC).

### [Clause 9]

The signal transmission device according to any one of clauses 1 to 8, in which
the first backward conductor (32A, 32B) and the second backward conductor (34A, 34B) are each separated from the back surface (64r) of the element insulation layer (64) in the thickness-wise direction (z-direction) of the element insulation layer (64), and
a thickness (TZ) of the substrate insulation layer (63B) is greater than or equal to a distance (D2) between the first backward conductor (32A, 32B) and the back surface (64r) of the element insulation layer (64) in the thickness-wise direction (z-direction) of the element insulation layer (64).

### [Clause 10]

The signal transmission device according to any one of clauses 1 to 9, in which
the insulation chip (60) is bonded to the first die pad (70) or the second die pad (80) by a bonding material (103), and
a thickness (TZ) of the substrate insulation layer (63B) is smaller than a thickness (TS3) of the bonding material (103).

### [Clause 11]

The signal transmission device according to clause 10, in which the bonding material (103) includes an insulative bonding material.

### [Clause 12]

The signal transmission device according to clause 10 or 11, in which
the first chip (40) is bonded to the first die pad (70) by a first conductive bonding material (101), and
the second chip (50) is bonded to the second die pad (80) by a second conductive bonding material (102).

### [Clause 13]

The signal transmission device according to clause 12, in which the thickness (TZ) of the substrate insulation layer (63B) is smaller than a thickness (TS1) of the first conductive bonding material (101).

### [Clause 14]

The signal transmission device according to clause 12 or 13, in which the thickness (TZ) of the substrate insulation layer (63B) is smaller than a thickness (TS2) of the second conductive bonding material (102).

### [Clause 15]

The signal transmission device according to any one of clauses 1 to 14, in which a thickness (TZ) of the substrate insulation layer (63B) is in a range of 2 μm to 4 μm.

### [Clause 16]

The signal transmission device according to any one of clauses 1 to 15, in which a thickness (TZ) of the substrate insulation layer (63B) is smaller than a distance (D1) between the first frontward conductor (31A, 31B) and the first backward conductor (32A, 32B) in the thickness-wise direction (z-direction) of the element insulation layer (63).

### [Clause 17]

The signal transmission device according to any one of clauses 1 to 16, in which
the first frontward conductor includes a first frontward coil (31A, 31B) having a spiral or annular shape,
the first backward conductor includes a first backward coil (32A, 32B) having a spiral or annular shape,
the second frontward conductor includes a second frontward coil (33A, 33B) having a spiral or annular shape, and
the second backward conductor includes a second backward coil (34A, 34B) having a spiral or annular shape.

### [Clause 18]

The signal transmission device according to clause 17, in which
the signal transmission device (10) is configured to transmit a signal from the first circuit (13) toward the second circuit (14) through a transformer (15A, 15B) including the first isolation element (21A, 21B) and the second isolation element (22A, 22B),
the transformer includes a first signal transformer (15A) and a second signal transformer (15B),
the signal transmitted through the transformer (15A, 15B) includes a first signal and a second signal,
the first signal is transmitted from the first circuit (13) toward the second circuit (14) through the first signal transformer (15A), and
the second signal is transmitted from the first circuit (13) toward the second circuit (14) through the second signal transformer (15B).

### [Clause 19]

The signal transmission device according to any one of clauses 1 to 16, in which
the first frontward conductor includes a first frontward electrode plate (121A, 121B) having a flat shape,
the first backward conductor includes a first backward electrode plate (122A, 122B) having a flat shape,
the second frontward conductor includes a second frontward electrode plate (123A, 123B) having a flat shape, and
the second backward conductor includes a second backward electrode plate (124A, 124B) having a flat shape.

### [Clause 20]

An insulation chip (60), including:
a substrate (63);
an element insulation layer (64) including a front surface (64s) and a back surface (64r) opposite to the front surface (64s), the back surface (64r) being located closer to the substrate (63) than the front surface (64s) is; and
a first isolation element (21A, 21B) and a second isolation element (22A, 22B) arranged in the element insulation layer (64), in which
the first isolation element (21A, 21B) includes
   a first frontward conductor (31A, 31B) arranged in the element insulation layer (64) at a position closer to the front surface (64s) than to the back surface (64r), and
   a first backward conductor (32A, 32B) arranged in the element insulation layer (64) at a position closer to the back surface (64r) than to the front surface (64s), the first backward conductor (32A, 32B) being opposed to the first frontward conductor (31A, 31B) in a thickness-wise direction (z-direction) of the element insulation layer (64),
the second isolation element (22A, 22B) includes
   a second frontward conductor (33A, 33B) arranged in the element insulation layer (64) at a position closer to the front surface (64s) than to the back surface (64r), and
   a second backward conductor (34A, 34B) arranged in the element insulation layer (64) at a position closer to the back surface (64r) than to the front surface (64s), the second backward conductor (34A, 34B) being opposed to the second frontward conductor (33A, 33B) in the thickness-wise direction (z-direction) of the element insulation layer (64),
the first backward conductor (32A, 32B) is electrically connected to the second backward conductor (34A, 34B), and
the substrate (63) includes
   a body (63A), and
   a substrate insulation layer (63B) formed on a front surface (63As) of the body (63A),
the element insulation layer (64) is stacked on a front surface (63Bs) of the substrate insulation layer (63B).

### [Clause 21]

The signal transmission device according to any one of clauses 1 to 19, in which a back surface insulation layer (69) is arranged on a side of the substrate (63) opposite from the substrate insulation layer (63B).

### [Clause 22]

The signal transmission device according to clause 21, in which a thickness (TR) of the back surface insulation layer (69) is greater than the thickness (TZ) of the substrate insulation layer (63B).

### [Clause 23]

The signal transmission device according to clause 21 or 22, in which a thickness (TR) of the back surface insulation layer (69) is smaller than a thickness (TB) of the substrate (63).

### [Clause 24]

The signal transmission device according to any one of clauses 21 to 23, in which the back surface insulation layer (69) includes a resin.

### [Clause 25]

The signal transmission device according to clause 17, in which
a first pad (61A, 61B) and a second pad (62A, 62B) are arranged on the front surface (64s) of the element insulation layer (64),
the first pad (61A, 61B) is shifted from a center of the first frontward coil (31A, 31B) as viewed in the thickness-wise direction (z-direction) of the element insulation layer (64), and
the second pad (62A, 63B) is shifted from a center of the second frontward coil (33A, 33B) as viewed in the thickness-wise direction (z-direction) of the element insulation layer (64).

### [Clause 26]

The signal transmission device according to clause 25, in which
the first pad (61A, 61B) is located at an inner side of the first frontward coil (31A, 31B) as viewed in the thickness-wise direction (z-direction) of the element insulation layer (64), and
the second pad (62A, 62B) is located at an inner side of the second frontward coil (33A, 33B) as viewed in the thickness-wise direction (z-direction) of the element insulation layer (64).

### [Clause 27]

The signal transmission device according to clause 17, in which
the first backward coil (32A, 32B) and the second backward coil (34A, 34B) are located at the same position in the thickness-wise direction (z-direction) of the element insulation layer (64),
the insulation chip (60) includes a first loop conductor (39A) and a second loop conductor (39B) arranged in the element insulation layer (64),
the first loop conductor (39A) includes
   an annular first opposing part (39p) and an annular second opposing part (39q) that are open toward each other, and
   joint parts (39r) joining open ends of the of the two opposing parts (39p, 39q) to each other, the joint parts (39r) and the two opposing parts (39p, 39q)
forming a loop structure of the first loop conductor (39A),
the first opposing part (39p) is opposed to the first frontward coil (31A, 31B) in the thickness-wise direction (z-direction) of the element insulation layer (64) to form the first backward coil (32A, 32B),
the second opposing part (39q) is opposed to the second frontward coil (33A, 33B) in the thickness-wise direction (z-direction) of the element insulation layer (64) to form the second backward coil (34A, 34B), and
the second loop conductor (39B) has geometrical similarity with the first loop conductor (39A) and surrounds the first loop conductor (39A) as viewed in the thickness-wise direction (z-direction) of the element insulation layer (64).

### [Clause 28]

The signal transmission device according to clause 17, in which
the first frontward coil (31A, 31B) and the second frontward coil (33A, 33B) are each formed from a material including copper, and
the first backward coil (32A, 32B) and the second backward coil (34A, 34B) are each formed from a material including aluminum.

### [Clause 29]

The signal transmission device according to clause 18, in which
the first die pad (70) and the second die pad (80) are spaced apart from each other by a gap as viewed in the thickness-wise direction (z-direction) of the element insulation layer (64),
the first chip (40), the second chip (50), and the insulation chip (60) are spaced apart from each other by a gap in a first direction (x-direction) that is a direction in which the first die pad (70) and the second die pad (80) are arranged,
the first frontward coil (31A, 31B) and the second frontward coil (33A, 33B) are spaced apart from each other by a gap in the first direction (x-direction), the first backward coil (32A, 32B) and the second backward coil (34A, 34B) are spaced apart from each other by a gap in the first direction (x-direction),
the first frontward coil (31A) of the first signal transformer (15A) and the first frontward coil (31B) of the second signal transformer (15B) are spaced apart from each other by a gap in a second direction (y-direction) that is orthogonal to the first direction (x-direction) as viewed in the thickness-wise direction (z-direction) of the element insulation layer (64),
the second frontward coil (33A) of the first signal transformer (15A) and the second frontward coil (33B) of the second signal transformer (15B) are spaced apart from each other by a gap in the second direction (y-direction),
the first backward coil (32A) of the first signal transformer (15A) and the first backward coil (32B) of the second signal transformer (15B) are spaced apart from each other by a gap in the second direction (y-direction), and
the second backward coil (34A) of the first signal transformer (15A) and the second backward coil (34B) of the second signal transformer (15B) are spaced apart from each other by a gap in the second direction (y-direction).

### [Clause 30]

The signal transmission device according to clause 29, in which
a third pad (61C) and a fourth pad (62C) are formed on the front surface (64s) of the element insulation layer (64),
the third pad (61C) is arranged between the first frontward coil (31A) of the first signal transformer (15A) and the first frontward coil (31B) of the second signal transformer (15B) as viewed in the thickness-wise direction (z-direction) of the element insulation layer (64) and is electrically connected to the first frontward coil (31A) of the first signal transformer (15A) and the first frontward coil (31B) of the second signal transformer (15B), and
the fourth pad (62C) is arranged between the second frontward coil (33A) of the first signal transformer (15A) and the second frontward coil (33B) of the second signal transformer (15B) as viewed in the thickness-wise direction (z-direction) of the element insulation layer (64) and is electrically connected to the second frontward coil (33A) of the first signal transformer (15A) and the second frontward coil (33B) of the second signal transformer (15B).

### [Clause 31]

The signal transmission device according to clause 19, in which
the signal transmission device (10) is configured to transmit a signal from the first circuit (13) toward the second circuit (14) through a capacitor (110A, 110B) that includes the first isolation element (111A, 111B) and the second isolation element (112A, 112B),
the capacitor includes a first signal capacitor (110A) and a second signal capacitor (110B),
the signal transmitted through the capacitor (110A, 110B) includes a first signal and a second signal,
the first signal is transmitted from the first circuit (13) toward the second circuit (14) through the first signal capacitor (110A), and
the second signal is transmitted from the first circuit (13) toward the second circuit (14) through the second signal capacitor (110B).

### [Clause 32]

The signal transmission device according to clause 31, in which
the first die pad (70) and the second die pad (80) are spaced apart from each other by a gap as viewed in the thickness-wise direction (z-direction) of the element insulation layer (64),
the first chip (40), the second chip (50), and the insulation chip (120) are spaced apart from each other by a gap in a first direction (x-direction) that is a direction in which the first die pad (70) and the second die pad (80) are arranged,
the first frontward electrode plate (131A, 131B) and the second frontward electrode plate (133A, 133B) are spaced apart from each other by a gap in the first direction (x-direction),
the first backward electrode plate (132A, 132B) and the second backward electrode plate (134A, 134B) are spaced apart from each other by a gap in the first direction (x-direction),
the first frontward electrode plate (131A) of the first signal capacitor (110A) and the first frontward electrode plate (131B) of the second signal capacitor (110B) are spaced apart from each other by a gap in a second direction (y-direction) that is orthogonal to the first direction (x-direction) as viewed in the thickness-wise direction (z-direction) of the element insulation layer (64),
the second frontward electrode plate (133A) of the first signal capacitor (110A) and the second frontward electrode plate (133B) of the second signal capacitor (110B) are spaced apart from each other by a gap in the second direction (y-direction),
the first backward electrode plate (132A) of the first signal capacitor (110A) and the first backward electrode plate (132B) of the second signal capacitor (110B) are spaced apart from each other by a gap in the second direction (y-direction), and
the second backward electrode plate (134A) of the first signal capacitor (110A) and the second backward electrode plate (134B) of the second signal capacitor (110B) are spaced apart from each other by a gap in the second direction (y-direction).

### [Clause 33]

The signal transmission device according to clause 32, in which
a first pad (131A, 131B) and a second pad (132A, 132B) are arranged on the front surface (64s) of the element insulation layer (64),
as viewed in the second direction (y-direction), the first pad (131A, 131B) overlaps the first frontward electrode plate (121A) of the first signal capacitor (110A) and the first frontward electrode plate (121B) of the second signal capacitor (110B), and
as viewed in the second direction (y-direction), the second pad (132A, 132B) overlaps the second frontward electrode plate (123A) of the first signal capacitor (110A) and the second frontward electrode plate (123B) of the second signal capacitor (110B).

### [Clause 34]

An insulation module, including:
the insulation chip (60) according to clause 20; and
a circuit chip (40/50) including a signal transmission circuit (13/14) electrically connected to the insulation chip (60).

### [Clause 35]

A method for manufacturing an insulation chip (60) including
a substrate (63) including a body (63A),
an element insulation layer (64) including a front surface (64s) and a back surface (64r) opposite to the front surface (64s), the back surface (64r) being located closer to the substrate (63) than the front surface (64s) is, and
a first isolation element (21A, 21B) and a second isolation element (22A, 22B) arranged in the element insulation layer (64), in which
the first isolation element (21A, 21B) includes
   a first frontward conductor (31A, 31B) arranged in the element insulation layer (64) at a position closer to the front surface (64s) than to the back surface (64r), and
a first backward conductor (32A, 32B) arranged in the element insulation layer (64) at a position closer to the back surface (64r) than to the front surface (64s), the first backward conductor (32A, 32B) being opposed to the first frontward conductor (31A, 31B) in a thickness-wise direction (z-direction) of the element insulation layer (64),
the second isolation element (22A, 22B) includes
   a second frontward conductor (33A, 33B) arranged in the element insulation layer (64) at a position closer to the front surface (64s) than to the back surface (64r), and
   a second backward conductor (34A, 34B) arranged in the element insulation layer (64) at a position closer to the back surface (64r) than to the front surface (64s), the second backward conductor (34A, 34B) being opposed to the second frontward conductor (33A, 33B) in the thickness-wise direction (z-direction) of the element insulation layer (64), and
the first backward conductor (32A, 32B) is electrically connected to the second backward conductor (34A, 34B), the method comprising:
a substrate insulation layer forming step that forms a substrate insulation layer (631) on a surface (630s) of a semiconductor wafer (630) including the body (63A); and

a step of stacking the element insulation layer (640) including the two isolation elements (21A, 21B, 22A, 22B) on a front surface of the substrate insulation layer (631).

### [Clause 36]

The method according to clause 35, in which the substrate insulation layer forming step includes a step of forming the substrate insulation layer (631) on opposite surfaces (630s, 630r) of the semiconductor wafer (630).

### [Clause 37]

The method according to clause 36, in which the substrate insulation layer forming step includes a step of removing the substrate insulation layer (631) from a back surface (630r) of the semiconductor wafer (630) after stacking the element insulation layer (640).

### [Clause 38]

The method according to any one of clauses 35 to 37, in which in the step of stacking the element insulation layer (640) and the step of forming the substrate insulation layer (631), a formation process of the element insulation layer (640) differs from a formation direction of the substrate insulation layer (631).

### [Clause 39]

The method according to clause 38, in which in the step of stacking the element insulation layer (640), the element insulation layer (640) is formed by a plasma CVD process.

### [Clause 40]

The method according to clause 38 or 39, in which in the step of forming the substrate insulation layer (631) on opposite surfaces (630s, 630r) of the semiconductor wafer (630), the substrate insulation layer (631) is formed by thermally oxidizing the semiconductor wafer (630).

### [Clause 41]

The method according to clause 38 or 39, in which in the step of forming the substrate insulation layer (631) on opposite surfaces (630s, 630r) of the semiconductor wafer (630), the substrate insulation layer (631) is formed by a low pressure CVD process using a TEOS gas.

### [Clause 42]

The method according to any one of clauses 35 to 41, further including a step of singulating into multiple insulation chips (60) by cutting the semiconductor wafer (630) including the element insulation layer (640).

### [Clause 43]

The method according to any one of clauses 35 to 42, in which the semiconductor wafer (630) includes an SOI wafer.

The description above illustrates examples. One skilled in the art may recognize further possible combinations and replacements of the elements and methods (manufacturing processes) in addition to those listed for purposes of describing the techniques of the present disclosure. The present disclosure is intended to include any substitute, modification, changes included in the scope of the disclosure including the claims and the clauses.

1. A signal transmission device, comprising:
a first chip including a first circuit;
a first die pad on which the first chip is mounted;
an insulation chip;
a second chip including a second circuit configured to perform at least one of reception of a signal and transmission of a signal with the first circuit through the insulation chip; and
a second die pad on which the second chip is mounted, wherein
the insulation chip includes
a substrate,
an element insulation layer including a front surface and a back surface opposite to the front surface, the back surface being located closer to the substrate than the front surface is, and
a first isolation element and a second isolation element arranged in the element insulation layer and configured to transmit the signal,
the first isolation element includes
a first frontward conductor arranged in the element insulation layer at a position closer to the front surface than to the back surface, and
a first backward conductor arranged in the element insulation layer at a position closer to the back surface than to the front surface, the first backward conductor being opposed to the first frontward conductor in a thickness-wise direction of the element insulation layer,
the second isolation element includes
a second frontward conductor arranged in the element insulation layer at a position closer to the front surface than to the back surface, and
a second backward conductor arranged in the element insulation layer at a position closer to the back surface than to the front surface, the second backward conductor being opposed to the second frontward conductor in the thickness-wise direction of the element insulation layer,
the first backward conductor is electrically connected to the second backward conductor, and
the substrate includes
a body, and
a substrate insulation layer formed on a front surface of the body, and
the element insulation layer is stacked on a front surface of the substrate insulation layer.

2. The signal transmission device according to claim 1, wherein the substrate insulation layer includes an oxide film.

3. The signal transmission device according to claim 2, wherein the oxide film includes a TEOS oxide film.

4. The signal transmission device according to claim 1, wherein a thickness of the substrate insulation layer is smaller than a thickness of the body.

5. The signal transmission device according to claim 1, wherein the body includes an SOI substrate including
a first semiconductor layer in contact with the element insulation layer,
an oxide film arranged on a side of the first semiconductor layer opposite from the element insulation layer, and
a second semiconductor layer arranged on a side of the oxide film opposite from the first semiconductor layer.

6. The signal transmission device according to claim 5, wherein
a thickness of the first semiconductor layer is greater than a thickness of the oxide film and a thickness of the second semiconductor layer, and
a thickness of the substrate insulation layer is smaller than the thickness of the first semiconductor layer.

7. The signal transmission device according to claim 6, wherein
the thickness of the second semiconductor layer is greater than the thickness of the oxide film, and
the thickness of the substrate insulation layer is smaller than the thickness of the second semiconductor layer.

8. The signal transmission device according to claim 7, wherein the thickness of the substrate insulation layer is equal to the thickness of the oxide film.

9. The signal transmission device according to claim 1, wherein
the first backward conductor and the second backward conductor are each separated from the back surface of the element insulation layer in the thickness-wise direction of the element insulation layer, and
a thickness of the substrate insulation layer is greater than or equal to a distance between the first backward conductor and the back surface of the element insulation layer in the thickness-wise direction of the element insulation layer.

10. The signal transmission device according to claim 1, wherein
the insulation chip is bonded to the first die pad or the second die pad by a bonding material, and
a thickness of the substrate insulation layer is smaller than a thickness of the bonding material.

11. The signal transmission device according to claim 10, wherein the bonding material includes an insulative bonding material.

12. The signal transmission device according to claim 10, wherein
the first chip is bonded to the first die pad by a first conductive bonding material, and
the second chip is bonded to the second die pad by a second conductive bonding material.

13. The signal transmission device according to claim 12, wherein the thickness of the substrate insulation layer is smaller than a thickness of the first conductive bonding material.

14. The signal transmission device according to claim 12, wherein the thickness of the substrate insulation layer is smaller than a thickness of the second conductive bonding material.

15. The signal transmission device according to claim 1, wherein a thickness of the substrate insulation layer is in a range of 2 μm to 4 μm.

16. The signal transmission device according to claim 1, wherein a thickness of the substrate insulation layer is smaller than a distance between the first frontward conductor and the first backward conductor in the thickness-wise direction of the element insulation layer.

17. The signal transmission device according to claim 1, wherein
the first frontward conductor includes a first frontward coil having a spiral or annular shape,
the first backward conductor includes a first backward coil having a spiral or annular shape,
the second frontward conductor includes a second frontward coil having a spiral or annular shape, and
the second backward conductor includes a second backward coil having a spiral or annular shape.

18. The signal transmission device according to claim 17, wherein
the signal transmission device is configured to transmit a signal from the first circuit toward the second circuit through a transformer including the first isolation element and the second isolation element,
the transformer includes a first signal transformer and a second signal transformer,
the signal transmitted through the transformer includes a first signal and a second signal,
the first signal is transmitted from the first circuit toward the second circuit through the first signal transformer, and
the second signal is transmitted from the first circuit toward the second circuit through the second signal transformer.

19. The signal transmission device according to claim 1, wherein
the first frontward conductor includes a first frontward electrode plate having a flat shape,
the first backward conductor includes a first backward electrode plate having a flat shape,
the second frontward conductor includes a second frontward electrode plate having a flat shape, and
the second backward conductor includes a second backward electrode plate having a flat shape.

20. An insulation chip, comprising:
a substrate;
an element insulation layer including a front surface and a back surface opposite to the front surface, the back surface being located closer to the substrate than the front surface is; and
a first isolation element and a second isolation element arranged in the element insulation layer, wherein
the first isolation element includes
a first frontward conductor arranged in the element insulation layer at a position closer to the front surface than to the back surface, and
a first backward conductor arranged in the element insulation layer at a position closer to the back surface than to the front surface, the first backward conductor being opposed to the first frontward conductor in a thickness-wise direction of the element insulation layer,
the second isolation element includes
a second frontward conductor arranged in the element insulation layer at a position closer to the front surface than to the back surface, and
a second backward conductor arranged in the element insulation layer at a position closer to the back surface than to the front surface, the second backward conductor being opposed to the second frontward conductor in the thickness-wise direction of the element insulation layer,
the first backward conductor is electrically connected to the second backward conductor, and
the substrate includes
a body, and
a substrate insulation layer formed on a front surface of the body,
the element insulation layer is stacked on a front surface of the substrate insulation layer.
